(19) United States
(12) Patent Application Publication
(10) Pub. No.: US 2018/0358393 A1
(43) Pub. Date: Dec. 13, 2018

(54) SOLID-STATE IMAGING ELEMENT AND MANUFACTURING METHOD THEREOF

(71) Applicant: RENESAS ELECTRONICS CORPORATION, Tokyo (JP)

(72) Inventors: Hidenori SATO, Ibaraki (JP); Tatsuya KUNIKIYO, Tokyo (JP); Yotaro GOTO, Ibaraki (JP)

(21) Appl. No.: 15/937,162

(22) Filed: Mar. 27, 2018

(30) Foreign Application Priority Data
Jun. 13, 2017 (JP) 2017-116281

(51) Int. Cl. H01L 27/146; H04N 5/378; H04N 5/341

(52) U.S. Cl. CPC H01L 27/1463; H01L 27/14645; H01L 27/14621; H01L 27/14627; H01L 27/14629; H04N 5/341; H01L 27/14636; H01L 27/14685; H01L 27/14687; H01L 27/1469; H04N 5/378; H01L 27/14634

(57) ABSTRACT

In a solid-state imaging element having two or more photodiodes stacked in a vertical direction in each of pixels, electrons are prevented from moving between the respective photodiodes of the pixels adjacent to each other. The solid-state imaging element is formed by joining together a back surface of a first semiconductor wafer including one of the photodiodes and a wiring layer and a back surface of a second semiconductor wafer including another of the photodiodes and a wiring layer. By forming a first isolation region extending through a first semiconductor substrate forming the first semiconductor wafer and a second isolation region extending through a second semiconductor substrate forming the second semiconductor wafer, the photodiodes of one of the pixels are isolated from another of the pixels.

### CROSS-REFERENCE TO RELATED APPLICATIONS

The disclosure of Japanese Patent Application No. 2017-116281 filed on Jun. 13, 2017 including the specification, drawings and abstract is incorporated herein by reference in its entirety.

### BACKGROUND

The present invention relates to a solid-state imaging element and a manufacturing method thereof, and particularly to a technique which is effective when applied to a solid-state imaging element in which two or more photoelectric conversion portions are stacked in a vertical direction.

As a solid-state imaging element (solid-state imaging device, image element, or image sensor) used in a digital camera or the like, a device in which a photodiode as a light receiving element (photoelectric conversion portion) is provided in the main surface of a semiconductor substrate is known.

Patent Document 1 (Japanese Unexamined Patent Application Publication No. 2016-167530) describes a solid-state imaging element in which, in each of pixels, a plurality of photoelectric conversion portions are stacked in a vertical direction and describes the formation of an optical interference film between the photoelectric conversion portions stacked in the vertical direction.

### RELATED ART DOCUMENT

### Patent Document

[Patent Document 1] Japanese Unexamined Patent Application Publication No. 2016-167530

### SUMMARY

Patent Document 1 describes a method of manufacturing the solid-state imaging element in which, over an epitaxial layer, another epitaxial layer is formed, and then elements are formed in each of the epitaxial layers. Patent Document 1 also describes a manufacturing method in which, onto a first substrate including an epitaxial layer, a second substrate including another epitaxial layer is bonded, and then elements are formed in each of these epitaxial layers. In the case of forming the solid-state imaging element in accordance with each of these manufacturing methods, a plurality of steps of re-bonding supporting substrates are needed when, e.g., the elements are formed in each of the upper and lower epitaxial layers. This results in the problem of increased manufacturing cost of the solid-state imaging element.

When pixels adjacent to each other in a lateral direction are isolated from each other by a second-conductivity-type semiconductor region different from a first-conductivity-type semiconductor layer forming the major part of each of photodiodes, and no insulating film is used for the isolation between the pixels, electrons move between the pixels. This results in the problem of the degradation of the imaging performance of the solid-state imaging element.

Other objects and novel features of the present invention will become apparent from a statement in the present specification and the accompanying drawings.

The following is a brief description of the outline of a representative one of the embodiments disclosed in the present application.

A solid-state imaging element in an embodiment includes a first semiconductor substrate and a second semiconductor substrate which are stacked via an insulating film, a pixel including a first photoelectric conversion portion formed in the first semiconductor substrate and a second photoelectric conversion portion formed in the second semiconductor substrate, a first isolation region extending through the first semiconductor substrate, and a second isolation region extending through the second semiconductor substrate.

A method of manufacturing a solid-state imaging element in another embodiment includes providing a first semiconductor substrate including a first photoelectric conversion portion and a wiring layer over the first photoelectric conversion portion and a second semiconductor substrate including a second photoelectric conversion portion and a wiring layer over the second photoelectric conversion portion and joining together a back surface of the first semiconductor substrate and a back surface of the second semiconductor substrate via an insulating film.

According to the embodiment disclosed in the present application, it is possible to improve the performance of the solid-state imaging element.

Also, according to the embodiment disclosed in the present application, it is possible to reduce the manufacturing cost of the solid-state imaging element.

### BRIEF DESCRIPTION OF THE DRAWINGS

FIG. 1 is a plan view showing a solid-state imaging element in a first embodiment of the present invention;

FIG. 2 is a plan view showing the solid-state imaging element in the first embodiment of the present invention;

FIG. 3 is an equivalent circuit diagram of each of pixels included in the solid-state imaging element in the first embodiment of the present invention;

FIG. 4 is a cross-sectional view showing the solid-state imaging element in the first embodiment of the present invention;

FIG. 5 is a cross-sectional view of the solid-state imaging element in the first embodiment of the present invention during the manufacturing process thereof;

FIG. 6 is a cross-sectional view of the solid-state imaging element during the manufacturing process thereof, which is subsequent to FIG. 5;

FIG. 7 is a cross-sectional view of the solid-state imaging element during the manufacturing process thereof, which is subsequent to FIG. 6;

FIG. 8 is a cross-sectional view of the solid-state imaging element during the manufacturing process thereof, which is subsequent to FIG. 7;

FIG. 9 is a cross-sectional view of the solid-state imaging element during the manufacturing process thereof, which is subsequent to FIG. 8;

FIG. 10 is a cross-sectional view of the solid-state imaging element during the manufacturing process thereof, which is subsequent to FIG. 9;

FIG. 11 is a cross-sectional view of the solid-state imaging element during the manufacturing process thereof, which is subsequent to FIG. 10;

FIG. 12 is a cross-sectional view of the solid-state imaging element during the manufacturing process thereof, which is subsequent to FIG. 11;

FIG. 13 is a plan view showing a solid-state imaging element in a first modification of the first embodiment of the present invention;

FIG. 14 is a cross-sectional view showing a solid-state imaging element in a second modification of the first embodiment of the present invention;

FIG. 15 is a cross-sectional view of the solid-state imaging element in the second modification of the first embodiment of the present invention during the manufacturing process thereof;

FIG. 16 is a cross-sectional view of the solid-state imaging element during the manufacturing process thereof, which is subsequent to FIG. 15;

FIG. 17 is a cross-sectional view of the solid-state imaging element during the manufacturing process thereof, which is subsequent to FIG. 16;

FIG. 18 is a cross-sectional view of a solid-state imaging element in a third modification of the first embodiment of the present invention during the manufacturing process thereof;

FIG. 19 is a cross-sectional view of the solid-state imaging element during the manufacturing process thereof, which is subsequent to FIG. 18;

FIG. 20 is a cross-sectional view of the solid-state imaging element during the manufacturing process thereof, which is subsequent to FIG. 19;

FIG. 21 is a cross-sectional view of the solid-state imaging element during the manufacturing process thereof, which is subsequent to FIG. 20;

FIG. 22 is a cross-sectional view showing a solid-state imaging element in a second embodiment of the present invention;

FIG. 23 is a cross-sectional view of the solid-state imaging element in the second embodiment of the present invention during the manufacturing process thereof;

FIG. 24 is a cross-sectional view showing a solid-state imaging element in a first modification of the second embodiment of the present invention;

FIG. 25 is a cross-sectional view of a solid-state imaging element in the first modification of the second embodiment of the present invention;

FIG. 26 is a cross-sectional view showing a solid-state imaging element in a second modification of the second embodiment of the present invention;

FIG. 27 is a cross-sectional view of the solid-state imaging element in the second modification of the second embodiment of the present invention during the manufacturing process thereof;

FIG. 28 is a cross-sectional view of the solid-state imaging element in the second modification of the second embodiment of the present invention during the manufacturing process thereof;

FIG. 29 is a cross-sectional view showing a solid-state imaging element in a third modification of the second embodiment of the present invention;

FIG. 30 is a cross-sectional view of the solid-state imaging element in the third modification of the second embodiment of the present invention during the manufacturing process thereof;

FIG. 31 is a cross-sectional view showing a solid-state imaging element in a third embodiment of the present invention;

FIG. 32 is plan view showing the solid-state imaging element in the third embodiment of the present invention;

FIG. 33 is a graph showing the relationship between the wavelength of light and the transmittances of color filters;

FIG. 34 is a cross-sectional view of the solid-state imaging element in the third embodiment of the present invention during the manufacturing process thereof;

FIG. 35 is a cross-sectional view showing a solid-state imaging element in a first modification of the third embodiment of the present invention;

FIG. 36 is a cross-sectional view of the solid-state imaging element in the first modification of the third embodiment of the present invention during the manufacturing process thereof;

FIG. 37 is a cross-sectional view showing a solid-state imaging element in a second modification of the third embodiment of the present invention;

FIG. 38 is a cross-sectional view of the solid-state imaging element in the second modification of the third embodiment of the present invention during the manufacturing process thereof;

FIG. 39 is a cross-sectional view showing a solid-state imaging element in a third modification of the third embodiment of the present invention;

FIG. 40 is a cross-sectional view showing a solid-state imaging element in a fourth modification of the third embodiment of the present invention;

FIG. 41 is a cross-sectional view showing a solid-state imaging element in a comparative example;

FIG. 42 is a cross-sectional view of the solid-state imaging element in the comparative example during the manufacturing process thereof; and

FIG. 43 is a cross-sectional view of the solid-state imaging element in the comparative example during the manufacturing process thereof.

### DETAILED DESCRIPTION

In each of the following embodiments, if necessary for the sake of convenience, the embodiment will be described by being divided into a plurality of sections or embodiments. However, they are by no means irrelevant to each other unless particularly explicitly described otherwise, but are in relations such that one of the sections or embodiments is a modification, details, supplementary explanation, and so forth of part or the whole of the others. Also, in the following embodiments, when the number and the like (including the number, numerical value, amount, range, and the like) of elements are mentioned, they are not limited to the mentioned numbers unless particularly explicitly described otherwise or unless they are obviously limited to specific numbers in principle. The number and the like of the elements may be not less than or not more than the mentioned numbers.

Also, in the following embodiments, it goes without saying that the components thereof (including also elements, steps, and the like) are not necessarily indispensable unless particularly explicitly described otherwise or unless the components are considered to be obviously indispensable in principle. Likewise, if the shapes, positional relationships, and the like of the components and the like are referred to in the following embodiments, the shapes and the like are assumed to include those substantially proximate or similar thereto and the like unless particularly explicitly described otherwise or unless it can be considered that they obviously do not in principle. The same shall apply in regard to the foregoing numerical value and range.

The following will describe the embodiments in detail on the basis of the drawings. Note that, throughout all the drawings for illustrating the embodiments, members having the same functions are designated by the same reference numerals, and a repeated description thereof is omitted. In the following embodiments, a description of the same or like parts will not be repeated in principle unless particularly necessary.

Note that the superscript signs “−” and “+” represent the relative concentrations of impurities each having an n⁻ type conductivity type or a p-type conductivity type. For example, in the case of an n-type impurity, and “n⁺” show increasingly higher impurity concentrations.

### First Embodiment

A solid-state imaging element in the present first embodiment has a structure in which a plurality of photodiodes as light receiving elements (photoelectric conversion portions or photoelectric conversion elements) are provided in a vertical direction, i.e., a direction (perpendicular direction, right-angle direction, or up-down direction) perpendicular to the main surface of a semiconductor substrate. By particularly isolating the photodiodes adjacent to each other in the perpendicular direction and in a horizontal direction using insulating films, electrons are prevented from moving between the photodiodes. The solid-state imaging element in the present first embodiment having the photodiodes stacked in the vertical direction can be formed by providing two semiconductor wafers including the photodiodes and bonding together the respective back surfaces of the semiconductor wafers.

<Structure of Solid-State Imaging Element and Operation of Pixel>

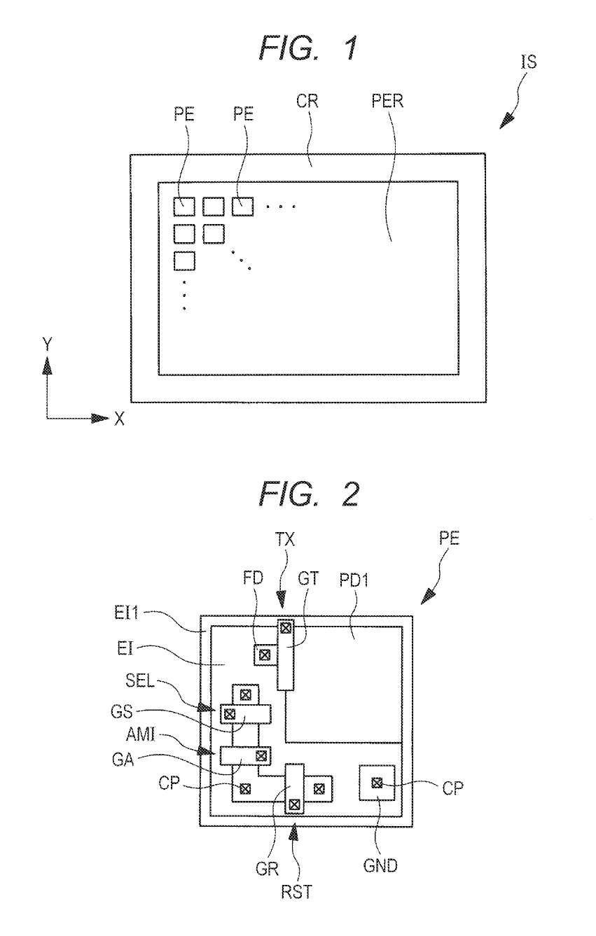

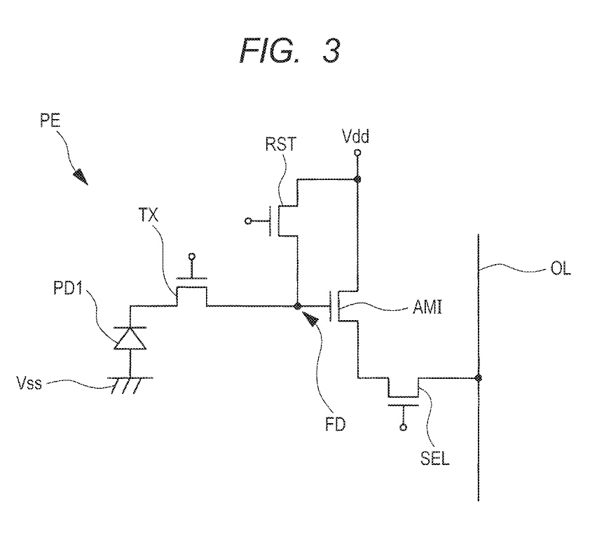

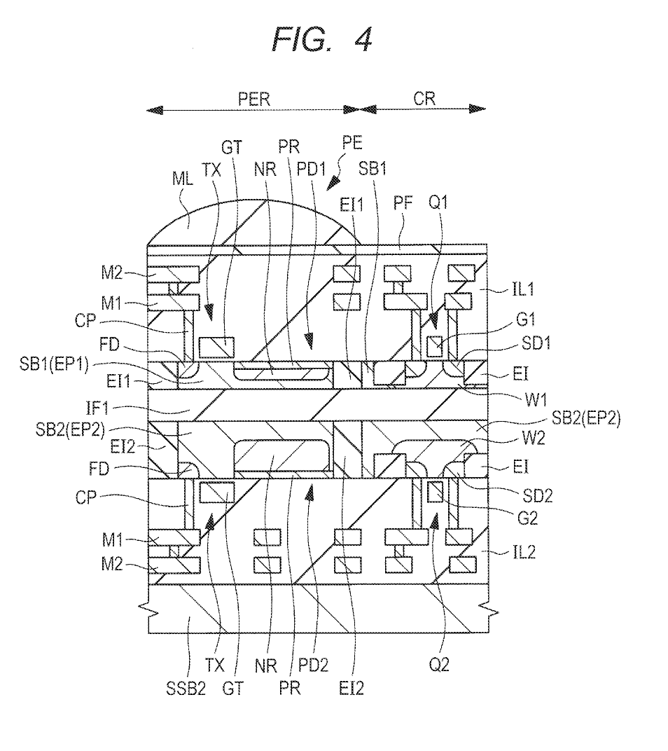

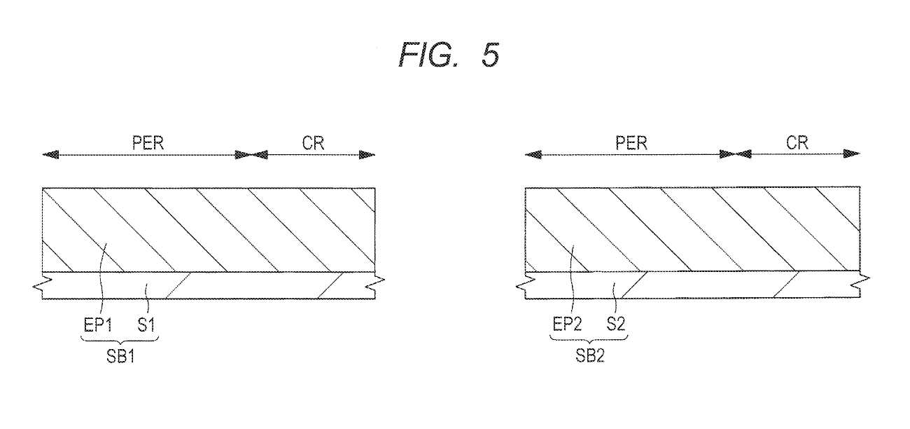

Using FIGS. 1 to 4, the following will describe a structure of the solid-state imaging element in the present first embodiment and the operation of each of the pixels included in the solid-state imaging element. FIGS. 1 and 2 are plan views each showing a configuration of the solid-state imaging element in the present first embodiment. FIG. 3 is an equivalent circuit diagram showing the solid-state imaging element in the present first embodiment. FIG. 4 is a cross-sectional view showing the solid-state imaging element in the present first embodiment.

FIG. 1 shows a schematic two-dimensional structure of the entire solid-state imaging element (semiconductor chip). FIG. 2 shows a plan view of each of the pixels. FIG. 3 shows the equivalent circuit diagram including one of photoelectric conversion portions and the peripheral transistors of the photoelectric conversion portion. FIG. 4 successively shows a pixel region PER and a peripheral circuit region CR in a left to right direction. In the pixel region PER, only one of the pixels is shown.

In the description given herein, as an example of each of the pixels, a 4-transistor pixel used as a circuit implementing a pixel in a CMOS imaging sensor is assumed, but the pixel is not limited thereto. That is, each of the pixels includes the plurality of stacked photoelectric conversion portions and, around a light reception region including a photodiode as one of the photoelectric conversion portions, a transfer transistor and three transistors as peripheral transistors are disposed. The peripheral transistors mentioned herein indicate a reset transistor, an amplification transistor, and a selection transistor.

A solid-state imaging element as the solid-state imaging element in the present first embodiment is a CMOS (Complementary Metal Oxide Semiconductor) image sensor. As shown in FIG. 1, a solid-state imaging element IS has a pixel region (pixel array region) PER and a peripheral circuit region CR surrounding the periphery of the pixel region PER in plan view. In the pixel region PER, a plurality of pixels PE are arranged in rows and columns. That is, over the upper surface of the semiconductor substrate included in the solid-state imaging element IS, the plurality of pixels PE are arranged in the form of an array in an X-direction and a Y-direction along the main surface of the semiconductor substrate included in the solid-state imaging element IS. The X-direction shown in FIG. 1 is the direction along a row direction in which the pixels PE are arranged. On the other hand, the Y-direction orthogonal to the X-direction is the direction along a column direction in which the pixels PE are arranged.

In plan view, the major part of the area of each of the pixels PE shown in FIG. 1 is occupied by the photodiodes as light receiving portions (light receiving elements). Each of the pixel region PER, the pixel PE, and the photodiode has a rectangular shape in plan view. The peripheral circuit region CR includes, e.g., a pixel read circuit, an output circuit, a row selection circuit, a control circuit, and the like.

Each of the plurality of pixels PE is a portion which generates a signal in accordance with the intensity of light illuminating the pixel PE. Each of the pixels PE has the plurality of photoelectric conversion portions stacked in the vertical direction. The row selection circuit selects the plurality of pixels PE on a per row basis. The pixels PE selected by the row selection circuit output generated signals to an output line. The read circuit reads the signals output from the pixels PE and outputs the read signals into the output circuit. The read circuit reads out the signals from the plurality of pixels PE. The output circuit outputs the signals read out of the pixels PE by the read circuit to the outside of the solid-state imaging element IS. The control circuit systematically manages the operation of the entire solid-stage imaging element IS and controls the operation of each of the other components of the solid-state imaging element IS.

In the present first embodiment, each of the pixels PE includes the respective photodiodes formed in a first semiconductor substrate and a second semiconductor substrate which are stacked in the vertical direction. Briefly, each of the pixels PE has the two stacked photodiodes. To each of the stacked photodiodes, peripheral transistors and the like are coupled. FIG. 2 shows the photodiode formed in the vicinity of the main surface (first main surface) of the first semiconductor substrate, and transistors and isolation regions around the photodiode. FIG. 3 shows a circuit including these elements. The layout and circuit configuration of the elements formed in the second semiconductor substrate are the same as the layout and circuit configuration of the elements formed in the first semiconductor substrate. Accordingly, the illustration of the layout and circuit of the elements formed in the main surface (second main surface) of the second semiconductor substrate, such as the photodiode and the peripheral transistors, is omitted herein.

As shown in FIG. 2, each of the pixels PE has a photodiode PD1 and the plurality of peripheral transistors in the main surface of the first semiconductor substrate. In plan view, the periphery of the photodiode PD1 is surrounded by isolation regions EI and EI1. In plan view, the photodiode PD1 has a rectangular shape. Note that the active region where the photodiode PD1 is formed has a portion partly protruding from one of the sides of the rectangular shape in plan view, and a transfer transistor TX is formed in the vicinity of the protruding portion.

The transfer transistor TX includes a floating diffusion capacitive portion (floating diffusion region) FD formed in the protruding portion and an n-type semiconductor region formed in the foregoing rectangular portion and included in the photodiode PD1 as source/drain regions. The transfer transistor TX includes a gate electrode GT formed between the source/drain regions in plan view.

In the inner region of each of the pixels PE which is adjacent to the photodiode PD1, a grounded region GND, a reset transistor RST, an amplification transistor AMI, and a selection transistor SEL are formed. In the present application, each of the reset transistor RST, the amplification transistor AMI, and the selection transistor SEL is referred to as the peripheral transistor. The photodiode PD1 and the transfer transistor TX, the reset transistor RST, the amplification transistor AMI, and the selection transistor SEL, and the grounded region GND are formed in different active regions defined by the isolation region EI. The amplification transistor AMI and the selection transistor SEL are formed in the same active region and share one of the respective source/drain regions thereof in the active region.

The selection transistor SEL includes a gate electrode GS. The amplification transistor AMI includes a gate electrode GA. The reset transistor RST includes a gate electrode GR. Each of the gate electrodes GT, GS, GA, and GR is formed over the first semiconductor substrate via a gate insulating film. To the floating diffusion capacitive portion FD, the grounded region GND, and the gate electrodes GT, GS, GA, and GR, respective contact plugs CP formed over the main surface (first main surface) of the first semiconductor substrate are electrically coupled. To the source/drain regions of the selection transistor SEL, the amplification transistor AMI, and the reset transistor RST which are other than the source/drain regions thereof shared by the selection transistor SEL and the amplification transistor AMI, the contact plugs CP are electrically coupled. Note that the contact plug CP is not coupled to the photodiode PD1.

In plan view, in the main surface of the first semiconductor substrate of each of the pixels PE, the isolation region EI1 is formed in an annular shape along the peripheral edge portion of the pixel PE. That is, the isolation region EI1 has a rectangular frame shape in plan view. Each of the photodiode PD1, the transfer transistor TX, the peripheral transistors, and the isolation region EI is surrounded by the isolation region EI1. In the main surface of the second semiconductor substrate, a photodiode PD2 (see FIG. 4), peripheral transistors, and the like are formed similarly to the photodiode PD1, the peripheral transistors, and the like shown in FIG. 2, though the illustration thereof is omitted.

FIG. 3 shows a circuit including one of the two photoelectric conversion portions (photodiodes) stacked in each of the pixels. That is, the pixel includes the two circuits shown in FIG. 3. Each of the plurality of pixels includes the two circuits shown in FIG. 3. A description is given herein of the circuit including the photodiode PD1 formed in the first semiconductor substrate, and a description of the circuit formed in the second semiconductor substrate is omitted herein.

As shown in FIG. 3, each of the pixels includes the photodiode PD1 which performs photoelectric conversion and the transfer transistor TX which transfers the charge generated in the photodiode. The pixel also includes the floating diffusion capacitive portion FD which stores the charge transferred from the transfer transistor TX and the amplification transistor AMI which amplifies a potential in the floating diffusion capacitive portion FD. The pixel further includes the selection transistor SEL which selectively determines whether or not the potential amplified in the amplification transistor AMI is to be output to an output line OL coupled to the read circuit (not shown) and the reset transistor RST which initializes each of respective potentials in the cathode of the photodiode PD1 and the floating diffusion capacitive portion FD to a predetermined value.

Each of the transfer transistor TX, the reset transistor RST, the amplification transistor AMI, and the selection transistor SEL is, e.g., an n-type MOSFET. To the anode of the photodiode PD1, a ground potential as a negative-side power supply potential Vss is applied. The cathode of the photodiode PD1 is coupled to the source of the transfer transistor TX. The floating diffusion capacitive portion FD is coupled to the drain of the transfer transistor TX, to the source of the reset transistor RST, and to the gate of the amplification transistor AMI. To the drain of the reset transistor RST and to the drain of the amplification transistor AMI, a positive-side power supply potential Vdd is applied. The source of the amplification transistor AMI is coupled to the drain of the selection transistor SEL. The source of the selection transistor SEL is coupled to the output line OL.

Next, a description will be given of the operation of each of the pixels. First, a predetermined potential is applied to the gate electrode of each of the transfer transistor TX and the reset transistor RST to bring each of the transfer transistor TX and the reset transistor RST into an ON state. As a result, each of the charge remaining in the photodiode PD1 and the charge stored in the floating diffusion capacitive portion FD flows toward the positive-side power supply potential Vdd to initialize the charge in each of the photodiode PD1 and the floating diffusion capacitive portion FD. Then, the reset transistor RST is brought into an OFF state.

Next, incident light illuminates the PN junction of the photodiode PD1 to cause photoelectric conversion in the photodiode PD1. Consequently, charge is generated in the photodiode PD1. The charge is entirely transferred by the transfer transistor TX to the floating diffusion capacitive portion FD. The floating diffusion capacitive portion FD stores the transferred charge. This changes the potential in the floating diffusion capacitive portion FD.

Next, when the selection transistor SEL is brought into the ON state, the changed potential in the floating diffusion capacitive portion FD is amplified by the amplification transistor AMI and then output to the output line OL. Then, the read circuit reads the potential out of the output line OL. Thus, it is possible to read charge information from each of the plurality of pixels formed in the pixel array portion and obtain the image sensed by the imaging element.

Next, using FIG. 4, a description will be given of a cross-sectional structure of the solid-state imaging element in the present first embodiment. In the present application, a substrate made of a semiconductor and an epitaxial layer (epitaxially grown layer or semiconductor layer) formed over the substrate may be collectively referred to as a semiconductor substrate. However, even when the substrate is removed from the semiconductor substrate formed by stacking the substrate and the epitaxial layer, the remaining epitaxial layer is referred to as the semiconductor substrate.

The foregoing photodiode is formed in the upper surface of the semiconductor substrate including the epitaxial layer. The source/drain regions and the channels of the field effect transistors included in the various circuits described above are formed in the upper surface of the semiconductor substrate including the epitaxial layer.

A description is given herein of the solid-state imaging element formed by providing the first semiconductor substrate having the first main surface and a first back surface opposite to the first main surface and the second semiconductor substrate having the second main surface and a second back surface opposite to the second main surface, flipping over the second semiconductor substrate, and then joining the second back surface to the first back surface. The vertically inverted second semiconductor substrate will be described on the assumption that the second main surface faces downward and the second back surface faces upward. Briefly, over the second back surface of the second semiconductor substrate, the first semiconductor substrate is located.

Note that the main surface of the semiconductor substrate mentioned herein indicates the one of the surfaces of the semiconductor substrate where semiconductor elements such as the photodiode and the transistors are formed. The surface opposite to the main surface is referred to herein as the back surface of the semiconductor substrate.

FIG. 4 shows a cross section of the solid-state imaging element including the pixel region PER and the peripheral circuit region CR. In the pixel region PER, the photodiodes PD1 and PD2 are shown while, in the peripheral circuit region CR, transistors Q1 and Q2 are shown. The transistors (field effect transistors) Q1 and Q2 are elements different from the transfer transistor TX and the peripheral transistors which are included in the pixel and described using FIGS. 2 and 3, and are not included in the pixel PE. The transistors Q1 and Q2 are included in the pixel read circuit, the output circuit, the row selection circuit, the control circuit, or the like described above using FIG. 1. However, the peripheral transistors included in each of the pixels PE have the same structures as those of the transistors Q1 and Q2 and are defined by the isolation region EI formed relatively shallower, similarly to the transistors Q1 and Q2.

As shown in FIG. 4, the solid-state imaging element has a p⁻-type semiconductor substrate SB1 as the first semiconductor substrate and a p⁻-type semiconductor substrate SB2 as the second semiconductor substrate. The semiconductor substrate SB1 is made of an epitaxial layer EP1, while the semiconductor substrate SB2 is made of an epitaxial layer EP2. In the solid-state imaging element shown in FIG. 4, the semiconductor substrate SB1 indicates the epitaxial layer EP1, while the semiconductor substrate SB2 indicates the epitaxial layer EP2. The semiconductor substrate SB1 includes the first main surface and the first back surface opposite to the first main surface. The semiconductor substrate SB2 includes the second main surface and the second back surface opposite to the second main surface. The semiconductor substrate SB1 and the semiconductor substrate SB2 are joined together via an insulating film (oxide insulating film) IF1.

The semiconductor substrate SB2 is vertically inverted so that the second back surface thereof faces upward. Consequently, the first back surface of the semiconductor substrate SB1 and the second back surface of the semiconductor substrate SB2 face each other with the insulating film IF1 being interposed therebetween. Each of the semiconductor substrates SB1 and SB2 is made of an epitaxially grown layer (semiconductor layer), e.g., a Si (silicon) layer. The insulating film IF1 is made of, e.g., a silicon oxide film. In the drawing, the insulating film IF1 is shown as a single-layer film, but actually has a multi-layer structure in which two silicon oxide films are bonded together. That is, between the semiconductor substrates SB1 and SB2, the two silicon oxide films are formed in vertically stacked relation. The semiconductor substrate SB2 has a vertical thickness larger than that of the semiconductor substrate SB1.

In the pixel region PER, the plurality of pixels PE are arranged in a lateral direction. FIG. 4 shows one of the pixels PE. In the pixel PE, in the upper surface (first main surface) of the first semiconductor substrate SB1, the isolation regions (isolation portions or isolation films) EI and EI1 are formed to isolate the elements from each other. However, the isolation region EI formed in the pixel PE is not shown herein. The isolation region EI is formed of an insulating film such as a silicon oxide film embedded in the trench formed in the upper surface of the semiconductor substrate SB1. On the other hand, the isolation region EI1 is formed of an insulating film such as a silicon oxide film embedded in the through hole extending through the semiconductor substrate SB1. In the pixel region PER, to isolate the adjacent pixels PE from each other, the isolation region EI1 is provided in each of the end portions of each of the pixels PE in the lateral direction. The lateral direction (horizontal direction) mentioned herein is, e.g., a direction along the first main surface of the semiconductor substrate SB1.

The isolation region EI1 extends through the semiconductor substrate SB1. That is, the isolation region EI1 is formed to extend from the upper surface (first main surface) of the semiconductor substrate SB1 to the lower surface (first back surface) thereof. The lower surface of the isolation region EI1 is in contact with the insulating film IF1. The respective upper surfaces of the isolation regions EI and EI1 are in contact with the lower surface of an interlayer insulating film IL1 described later. The heights of the respective upper surfaces of the isolation regions EI and EI1 are generally the same as the height of the upper surface of the semiconductor substrate SB1. Each of the isolation regions EI and EI1 has a STI (Shallow Trench Isolation) structure.

The depth of the isolation region EI is larger than the depth of the isolation region EI1. That is, the lower surface of the isolation region EI is located at a point midway of the depth of the semiconductor substrate SB1 and spaced apart from the insulating film IF1. The depth mentioned herein, i.e., the depth of each of the trench, the isolation regions, and the semiconductor regions which are formed in the first main surface of the semiconductor substrate SB1 indicates the distance from the first main surface of the semiconductor substrate SB1 in a downward direction extending from the first main surface of the semiconductor substrate SB1 toward the first back surface of the semiconductor substrate SB1.

As shown in FIG. 2, the isolation region EI1 is formed in the annular shape along the peripheral edge portion of the pixel PE and formed in each of the plurality of pixels PE. Accordingly, the isolation region EI1 is formed also between the pixel region PER and the peripheral circuit region CR. This can prevent electrons from moving between the pixel region PER and the peripheral circuit region CR.

In the pixel PE, in the upper surface (active region) of the region of the semiconductor substrate SB1 which is exposed from the isolation regions EI and EI1, the photodiode PD1 is formed. The photodiode PD1 includes a p⁺-type semiconductor region PR formed in the upper surface of the semiconductor substrate SB1 and an n-type semiconductor region NR formed in the semiconductor substrate SB1 located under the p⁺-type semiconductor region PR in contact relation with the bottom surface of the p⁺-type semiconductor region PR. That is, the photodiode PD1 is formed of the PN junction between the p⁺-type semiconductor region PR and the n-type semiconductor region NR. The concentration of an n-type impurity (e.g., P (phosphorus) or As (arsenic)) is higher than the impurity concentration in the semiconductor substrate SB1.

The p⁺-type semiconductor region PR has the function of fixing the surface potential of the semiconductor substrate SB1 to the ground potential (GND) and thus allowing easier complete depletion (charge transfer) of the n-type semiconductor region NR included in the photodiode PD1. In addition, since the p⁺-type semiconductor region PR is formed, the level of a silicon surface as the surface of the semiconductor substrate SB1 is covered with the higher-concentration p-type impurity layer. This covers the silicon surface with holes, and can thus suppress the generation of a dark current.

In the pixel PE, in the first main surface of the semiconductor substrate SB1 located in the active region where the photodiode PD1 is formed, the floating diffusion capacitive portion FD as an n-type semiconductor region is formed to be spaced apart from the photodiode PD1. The depth of the floating diffusion capacitive portion FD is smaller than the depth of the n-type semiconductor region NR. In addition, immediately above the first main surface of the semiconductor substrate SB1 located between the floating diffusion capacitive portion FD and the n-type semiconductor region NR which are adjacent to each other in the first main surface, the gate electrode GT is formed via the gate insulating film. The gate electrode GT, the floating diffusion capacitive portion FD, and the n-type semiconductor region NR are included in the transfer transistor TX. The n-type semiconductor region NR forms the source region of the transfer transistor TX, while the floating diffusion capacitive portion FD forms the drain region of the transfer transistor TX.

In the vicinity of the first main surface of the semiconductor substrate SB1 in each of the pixels PE, in addition to the photodiode PD1 and the transfer transistor TX, the reset transistor, the amplification transistor, and the selection transistor as the peripheral transistors are formed, though not illustrated herein. When the solid-state imaging element senses an image, charge is generated as a signal in the photodiode PD1 that has received light. The charge is transferred by the transfer transistor TX to the floating diffusion capacitive portion FD coupled to the drain region of the transfer transistor TX. The signal is amplified by the amplification transistor and output by the selection transistor to the foregoing output line. Thus, the signal obtained by sensing the image can be read out. Note that the reset transistor is used to reset the charge accumulated in the floating diffusion capacitive portion FD.

In the peripheral circuit region CR, the transistor Q1 having a channel region is formed in the upper surface of the semiconductor substrate SB1. In the description given herein, the transistor Q1 is assumed to be an n-channel MISFET (Metal Insulator Semiconductor Field Effect Transistor), but the transistor Q1 may also be a p-channel MISFET. The transistor Q1 has a gate electrode G1 formed over the upper surface of the semiconductor substrate SB1 located in the active region defined by the isolation region EI via a gate insulating film. Over the upper surface of the semiconductor substrate SB1 located lateral to the gate electrode G1, source/drain regions SD1 are formed such that the gate electrode G1 is interposed therebetween in plan view. The transistor Q1 includes the gate electrode G1 and the source/drain regions SD1.

In the peripheral circuit region CR, a well W1 as a p-type semiconductor region where a p-type impurity (e.g., B (boron)) is introduced in the first main surface of the semiconductor substrate SB1 in which the transistor Q1 is formed is formed. The depth of the well W1 is larger than that of each of the source/drain regions SD1. Also, in the peripheral circuit region CR, the plurality of transistors Q1 and semiconductor elements of other types are formed. These elements are isolated from each other by the isolation region EI. The isolation region EI has the same configuration and the same depth as those of the isolation region EI (not shown) formed in each of the pixels PE. That is, the depths of the isolation regions EI formed in the pixel region PER and the peripheral circuit region CR are smaller than the depth of the isolation region EI1.

The respective gate insulating films of the transfer transistor TX and the transistor Q1 are made of, e.g., a silicon oxide film. The gate electrodes GT and G1 of the transfer transistor TX and the transistor Q1 are made of, e.g., a polysilicon film. The source/drain regions SD1 are made of n-type semiconductor regions where an n-type impurity (e.g., P (phosphorus) or As (arsenic)) is introduced in the upper surface of the semiconductor substrate SB1. When the transistor Q1 operates, the channel is formed in the upper surface of the semiconductor substrate SB1 located between the source/drain regions SD1. The respective upper surfaces of the source/drain regions SD1 and the gate electrode G1 are covered with silicide layers made of CoSi (cobalt silicide) or the like, though the illustration thereof is omitted.

Over the semiconductor substrate SB1, the interlayer insulating film IL1 is formed so as to cover the isolation regions EI and EI1, the photodiode PD1, and the transistor Q1. The interlayer insulating film IL1 includes respective interlayer insulating films included in a contact layer and a plurality of wiring layers which are stacked in this order over the first main surface of the semiconductor substrate SB1. That is, the interlayer insulating film IL1 includes the plurality of interlayer insulating films stacked over the first main surface of the semiconductor substrate SB1. In the drawing, the respective gate insulating films of the transfer transistor TX and the transistor Q1 and the interlayer insulating film IL1 are integrally illustrated.

The interlayer insulating film included in the contact layer includes a liner film (etching stopper film) made of a silicon nitride film deposited over the semiconductor substrate SB1 and a silicon oxide film deposited over the liner film. The upper surface of each of the interlayer insulating films included in the interlayer insulating film IL1 is planarized, though not illustrated. The plurality of wiring layers include, e.g., a first wiring layer and a second wiring layer which are stacked in this order over the first main surface of the semiconductor substrate SB1. The number of the stacked wiring layers may also be larger or smaller than 2.

The first wiring layer includes wires M1, while the second wiring layer includes wires M2 disposed over the wires M1. The wires M1 and M2 are made mainly of, e.g., Cu (copper), Al (aluminum), or the like. In a plurality of contact holes extending through the interlayer insulating film serving as the contact layer in the vertical direction, the contact plugs CP are embedded. The contact plugs CP are made mainly of, e.g., W (tungsten). The contact plugs CP electrically couple the wires M1 to the semiconductor elements formed in the first main surface of the first semiconductor substrate.

FIG. 4 shows the contact plugs CP coupled to the floating diffusion capacitive portion FD and to the source/drain regions SD1. The wires M1 and M2 are electrically coupled to each other through the vias extending through the interlayer insulating film IL1 located therebetween. The vias are made mainly of, e.g., Cu (copper). The interlayer insulating film IL1 covers the wires M1 and M2, and the upper surface of the interlayer insulating film IL1 is planar. To prevent the light illuminating the photodiode PD1 and the photodiode PD2 described later from being blocked by the individual wires, the wires M1 and M2 are not formed immediately above the photodiode PD1.

In the pixel region PER and the peripheral circuit region CR, under the semiconductor substrate SB1, the same structure as the structure including the elements and the wires each described above is formed in vertically inverted relation. That is, in the second main surface of the semiconductor substrate SB2 formed under the semiconductor substrate SB1 via the insulating film IF1, the photodiode PD2, the transfer transistor TX, and the transistor Q2 are formed.

That is, in the pixel PE, in the lower surface (second main surface) of the semiconductor substrate SB2, the photodiode PD2 and the floating diffusion capacitive portion FD are formed. The gate electrode GT formed under the second main surface of the semiconductor substrate SB2 via the gate insulating film, the photodiode PD2, and the floating diffusion capacitive portion FD are included in the transfer transistor TX. The floating diffusion capacitive portion FD is an n-type semiconductor region. The photodiode PD2 includes the p⁺-type semiconductor region PR formed in the second main surface of the semiconductor substrate SB2 and the n-type semiconductor region NR formed in the semiconductor substrate SB2 located over the p⁺-type semiconductor region PR in contact relation with the upper surface of the p⁺-type semiconductor region PR. In the second main surface of the semiconductor substrate SB2 included in each of the pixels PE, peripheral transistors are also formed, though not illustrated.

In the peripheral circuit region CR, a gate electrode G2 formed under the second main surface of the semiconductor substrate SB2 via a gate insulating film and source/drain regions SD2 as n-type semiconductor regions formed in the second main surface of the semiconductor substrate SB2 are included in the transistor Q2. In the second main surface of the semiconductor substrate SB2 located in the peripheral circuit region CR, a well W2 as a p-type semiconductor region is formed.

In each of the pixels PE in the pixel region PER, the photodiode PD2, the transfer transistor TX, and the peripheral transistors (not shown) are surrounded by an isolation region EI2 formed to extend from the second main surface of the semiconductor substrate SB2 to the second back surface thereof. That is, the photodiode PD2, the transfer transistor TX, and the peripheral transistors (not shown) which are included in each of the pixels PE are isolated from the elements of the other pixels PE by the isolation region EI2.

In each of the pixels PE, the photodiode PD2, the transfer transistor TX, and the peripheral transistors (not shown) are isolated from each other by the isolation region EI (not shown) formed in the second main surface of the semiconductor substrate SB2. Also, the plurality of elements formed in the peripheral circuit region CR and including the transistor Q2 are isolated from each other by the isolation region EI. The depth of the isolation region EI2 is larger than the depth of each of the isolation regions EI formed in the semiconductor substrates SB1 and SB2. The isolation region EI2 is formed immediately below the isolation region EI1. The photodiode PD2 is formed immediately below the photodiode PD1. The depth mentioned herein, i.e., the depth of each of the trench, the isolation regions, and the semiconductor regions which are formed in the second main surface of the semiconductor substrate SB2 indicates the distance from the second main surface of the semiconductor substrate SB2 in an upward direction extending from the second main surface of the semiconductor substrate SB2 toward the second back surface of the semiconductor substrate SB2. Each of the isolation regions EI1 and EI2 mentioned herein has a structure in which the insulating film is embedded in the deep trench. However, it may also be possible that a void is present in each of the isolation regions EI1 and EI2.

Since the thickness of the semiconductor substrate SB2 is larger than the thickness of the semiconductor substrate SB1, the thickness of the isolation region EI2 is larger than the thickness of the isolation region EI1. Also, the depth of the photodiode PD2 is larger than the depth of the photodiode PD1. This is because the photodiode PD2 detects light at a wavelength longer than that of the light detected by the photodiode PD1. That is, since the photodiode PD2 having a large vertical length is formed in the semiconductor substrate SB2, the thickness of the semiconductor substrate SB2 is larger than the thickness of the semiconductor substrate SB1. Note that the respective depths of the p⁺-type semiconductor region PR formed in the semiconductor substrate SB1 and the p⁺-type semiconductor region PR formed in the semiconductor substrate SB2 may be the same as or different from each other. However, the depth of the n-type semiconductor region NR formed in the semiconductor substrate SB2 is larger than the depth of the n-type semiconductor region NR formed in the semiconductor substrate SB1. Each of the thicknesses mentioned in the present application indicates the vertical dimension of a film, a layer, a substrate, or the like.

Under the semiconductor substrate SB2, an interlayer insulating film IL2 is formed so as to cover the isolation regions EI and EI2, the photodiode PD2, and the transistor Q2. The interlayer insulating film IL2 includes respective interlayer insulating films included in a contact layer and a plurality of wiring layers which are stacked in this order over the second main surface of the semiconductor substrate SB2. In the interlayer insulating film IL2, in the same manner as in the structure over the semiconductor substrate SB1, the plurality of contact plugs CP and the wires M1 and M2 are formed. However, since the photodiode PD2 is a photoelectric conversion portion (light receiving element) which detects light incident on the second main surface of the semiconductor substrate SB2 from above the second back surface of the semiconductor substrate SB2, the wires M1 and M2 may also be disposed immediately below the photodiode PD2.

The lower surface of the interlayer insulating film IL2 is planar. To the lower surface, a supporting substrate SSB2 is joined. The supporting substrate SSB2 is made of, e.g., a Si (silicon) substrate and has the function of preventing deformation of a structure over the supporting substrate SSB2 or the like.

Over the upper surface of the interlayer insulating film IL1 formed over the semiconductor substrate SB1, a passivation film PF as a surface protection film is formed. The passivation film PF is formed of, e.g., a silicon oxide film and a silicon nitride film disposed over the silicon oxide film. In the pixel region PER, over the passivation film PF, a microlens ML is formed. The microlens ML is made of a hemispherical film having a curved upper surface, and is formed for each of the pixels PE on a one-to-one basis. The microlens ML is formed immediately above each of the photodiodes PD1 and PD2.

During imaging, the light illuminating the imaging element passes through the microlens ML and the individual wiring layers in this order to reach the photodiode PD1 or PD2. The illumination of the PN junction of the photodiode PD1 with the incident light causes photoelectric conversion in each of the photodiode PD1 and the semiconductor substrate SB1 located below the photodiode PD1. Also, the illumination of the PN junction of the photodiode PD2 with the incident light causes photoelectric conversion in each of the photodiode PD2 and the semiconductor substrate SB2 located above the photodiode PD2. As a result, electrons are generated and accumulated as charge in each of the respective n-type semiconductor regions NR of the photodiodes PD1 and PD2. Thus, each of the photodiodes PD1 and PD2 is the light receiving element which internally generates signal charge corresponding to the amount of the incident light, i.e., photoelectric conversion element.

The photodiode PD1 mentioned herein is the light receiving element which detects light at a relatively short wavelength, while the photodiode PD2 mentioned herein is a light receiving element which detects light at a relatively long wavelength. For example, the photodiode PD1 detects blue light, while the photodiode PD2 detects red light. Since the photodiode PD2 detects light at a wavelength longer than that of the light detected by the photodiode PD1, the photodiode PD2 has a depth larger than that of the photodiode PD1.

Note that the electrons generated in each of the semiconductor substrates SB1 and SB2 by photoelectric conversion come together at the n-type semiconductor region NR where electrons are likely to be accumulated to be stored as charge in the n-type semiconductor region NR. The PN junction between the n-type semiconductor region NR and the semiconductor substrate SB1 forms the photodiode PD1, while the PN junction between the n-type semiconductor region NR and the semiconductor substrate SB2 also forms the photodiode PD2. In the description given herein, the higher-concentration p⁺-type semiconductor regions PR are formed in the first main surface of the semiconductor substrate SB1 and the second main surface of the semiconductor substrate SB2. However, each of the photodiodes PD1 and PD2 need not necessarily have the p⁺-type semiconductor region PR. That is, it may also be possible that the photodiode PD1 includes only the n-type semiconductor region NR and the semiconductor substrate SB1, and the photodiode PD2 includes only the n-type semiconductor region NR and the semiconductor substrate SB2.

One of the main characteristic features of the solid-state imaging element in the present first embodiment is that the photodiodes PD1 and PD2 of each of the pixels PE are each surrounded by the insulating films in the vertical direction and in the lateral direction and are isolated from the elements of another pixel PE by the isolation regions EI1 and EI2. Specifically, the photodiode PD1 is surrounded by the isolation region EI1, the interlayer insulating film IL1, and the insulating film IF1, while the photodiode PD2 is surrounded by the isolation region EI2, the interlayer insulating film IL2, and the insulating film IF1. Consequently, the isolation region EI1 extends through the semiconductor substrate SB1 to come in contact with the interlayer insulating film IL1 and the insulating film IF1, while the isolation region EI2 extends through the semiconductor substrate SB2 to come in contact with the interlayer insulating film IL2 and the insulating film IF1.

Another of the main characteristic features of the solid-state imaging element in the present first embodiment is that the respective thicknesses of the semiconductor substrate SB2 and the isolation region EI2 are larger than the respective thicknesses of the semiconductor substrate SB1 and the isolation region EI1.

<Manufacturing Method of Solid-State Imaging Element>

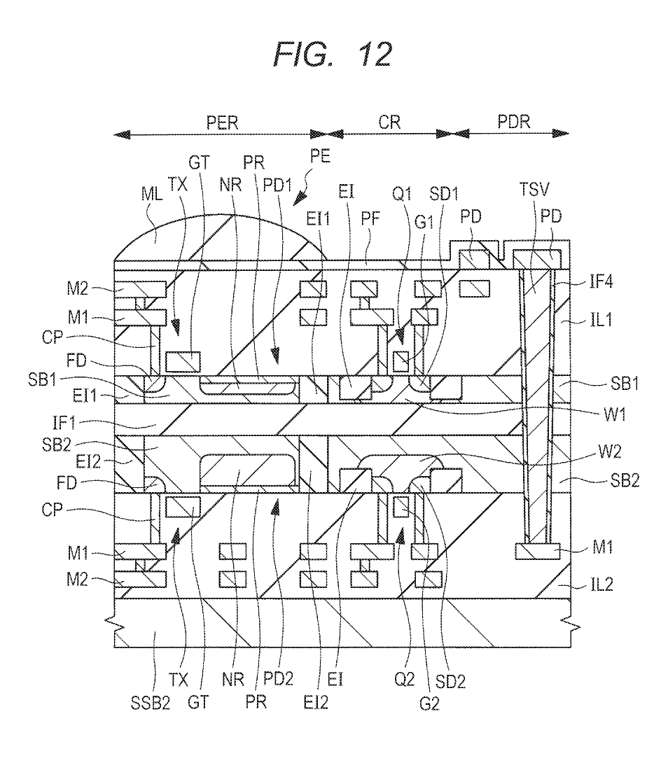

Using FIGS. 5 to 12, the following will describe a method of manufacturing the solid-state imaging element in the present first embodiment. FIGS. 5 to 12 are cross-sectional views of the solid-state imaging element in the present first embodiment during the manufacturing process thereof. In each of the drawings of FIGS. 5 to 12, the pixel region PER and the peripheral circuit region CR are shown in this order in a left-to-right direction. In FIG. 12, on the right side of the peripheral circuit region CR, a pad region PDR is shown.

In the manufacturing process of the solid-state imaging element, first, as shown in FIG. 5, the p-type semiconductor substrates (semiconductor wafers) SB1 and SB2 made of, e.g., monocrystalline silicon (Si) are provided. The semiconductor substrate SB1 includes the first main surface where semiconductor elements, such as a photodiode and transistors, are formed in the subsequent steps and the first back surface opposite thereto. The semiconductor substrate SB2 has the second main surface where semiconductor elements, such as a photodiode and transistors, are formed in the subsequent steps and the second back surface opposite thereto.

The semiconductor substrate SB1 includes a substrate S1 made of monocrystalline silicon and the epitaxial layer EP1 formed over the substrate S1 by an epitaxial growth method, and thus has a multi-layer structure. The semiconductor substrate SB2 includes a substrate S2 made of monocrystalline silicon and the epitaxial layer EP2 formed over the substrate S2 by an epitaxial growth method, and thus has a multi-layer structure.

A semiconductor substrate before being cut by dicing is referred to herein as a semiconductor wafer. Also, the semiconductor substrate inclusive of the elements, the wiring layers, and the like which are formed over the semiconductor substrate in the manufacturing process is referred to as the semiconductor wafer. The semiconductor substrate SB1 is the first semiconductor wafer, while the semiconductor substrate SB2 is the second semiconductor wafer.

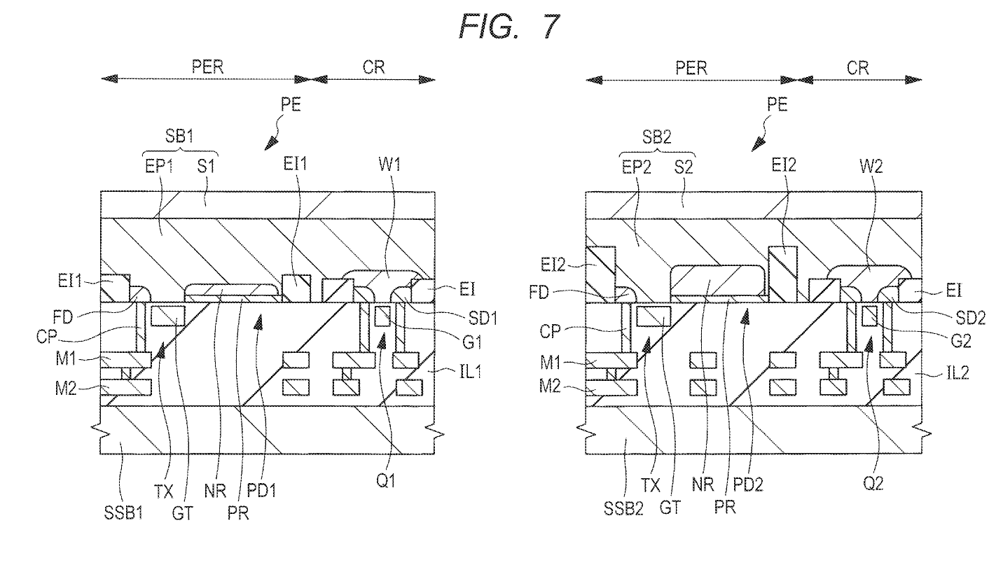

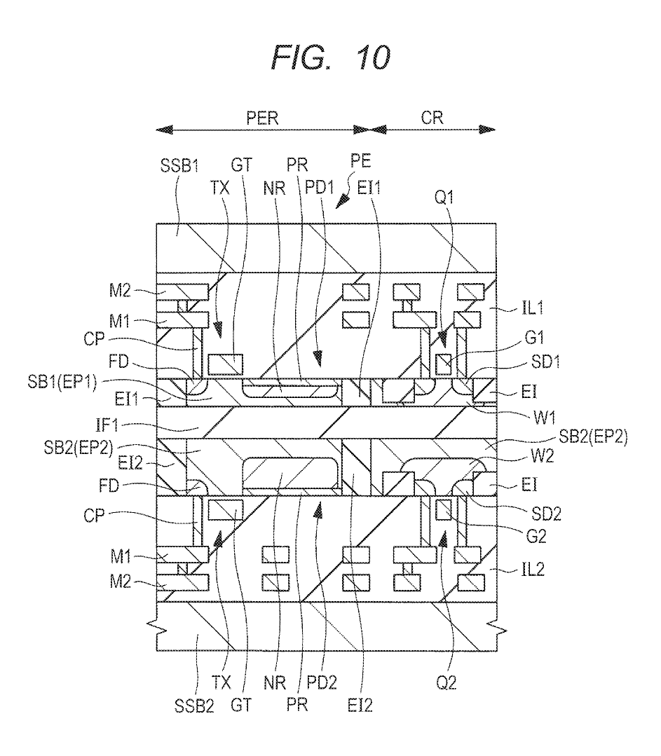

In the manufacturing process of the solid-state imaging element in the present first embodiment, in the step described using, e.g., FIG. 7, each of the first semiconductor wafer and the second semiconductor wafer is vertically inverted. In the steps including and subsequent to the step described using FIG. 10, only the second semiconductor wafer is in a vertically inverted state. That is, the back surface of the inverted semiconductor wafer faces upward, while the main surface thereof faces downward. When the main surface of the semiconductor wafer faces upward, a direction vertically extending toward the main surface of the semiconductor wafer is referred to herein as an upward direction, while a direction vertically extending toward the back surface of the semiconductor wafer is referred to herein as a downward direction. On the other hand, when the back surface of the semiconductor wafer faces upward, a direction vertically extending toward the back surface of the semiconductor wafer is referred to as the upward direction, while a direction vertically extending toward the main surface of the semiconductor wafer is referred to as the downward direction.

Note that the semiconductor substrates SB1 and SB2 are different semiconductor wafers, and a description is given herein of the case where similar steps performed on the semiconductor substrates SB1 and SB2 are performed with the same timing. However, the semiconductor substrates SB1 and SB2 need not simultaneously be processed. For example, it may also be possible to perform the steps described using FIGS. 5 to 9 on the semiconductor substrate SB1, and then perform the steps described using FIGS. 5 to 9 on the semiconductor substrate SB2. That is, before the step (see FIG. 10) of joining together the first semiconductor wafer and the second semiconductor wafer is performed, steps such as the formation of the elements, the formation of the wiring layers, the polishing of the back surface, and the formation of an insulating film covering the back surface may also be performed preferentially on either one of the first semiconductor wafer and the second semiconductor wafer.

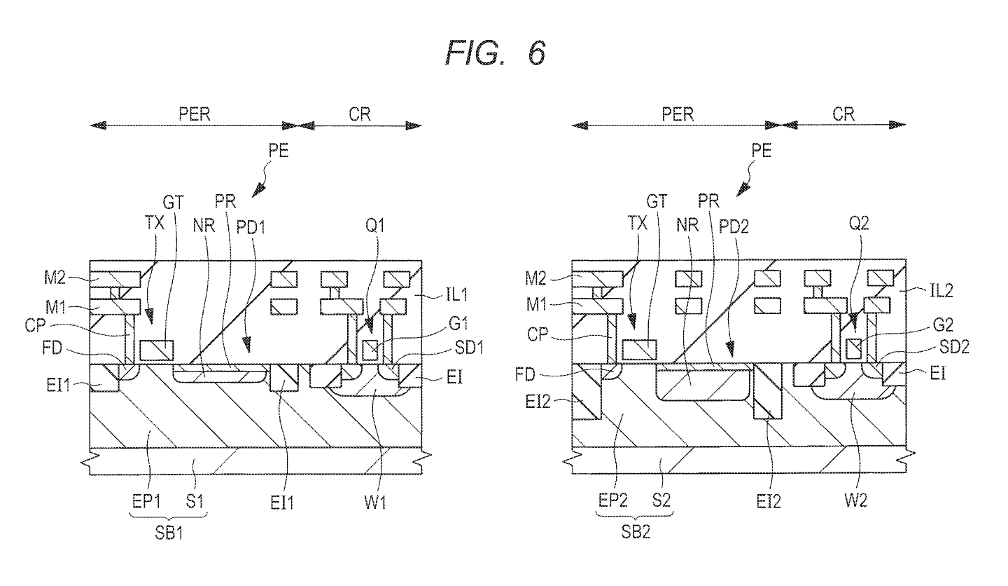

Next, as shown in FIG. 6, in the first main surface of the semiconductor substrate SB1, trenches of two depths are formed. Specifically, in each of the pixel region PER and the peripheral circuit region CR of the first main surface of the semiconductor substrate SB1, a relatively shallow trench is formed while, in the pixel region PER of the first main surface of the semiconductor substrate SB1, a relatively deep trench is formed. Thus, in the first main surface of the pixel region PER of the semiconductor substrate SB1, the shallower trenches and the trench deeper than the shallower trenches are formed. These trenches can be formed by performing etching using a pattern made of an insulating film formed over the semiconductor substrate SB1 as a mask (hard mask). In the second main surface of the semiconductor substrate SB2 also, shallower trenches and a deeper trench are similarly formed. However, the deeper trench in the second main surface of the semiconductor substrate SB2 is formed deeper than the deeper trench in the first main surface of the semiconductor substrate SB1.

Subsequently, in the trenches formed in the foregoing step, insulating films are embedded using, e.g., a CVD (Chemical Vapor Deposition) method. Then, using a CMP (Chemical Mechanical Polishing) method, the respective insulating films over the first main surface of the semiconductor substrate SB1 and the second main surface of the semiconductor substrate SB2 are removed. As a result, the insulating films left in the shallower trenches form the isolation regions EI. On the other hand, the insulating film left in the deeper trench of the first main surface of the semiconductor substrate SB1 forms the isolation region EI1, while the insulating film left in the deeper trench of the second main surface of the semiconductor substrate SB2 forms the isolation region EI2. The depth of the isolation region EI2 is larger than the depth of the isolation region EI1.

The isolation regions EI, EI1, and EI2 are formed herein by a STI (Shallower Trench Isolation) method. The step of embedding the insulating films in the shallower trenches to form the isolation regions EI and the step of embedding the insulating films in the deeper trenches to form the isolation regions EI1 or EI2 may also be performed separately and individually. Each of the isolation regions EI, EI1, and EI2 is made of, e.g., a silicon oxide film. Note that the depth of the isolation region EI in the first main surface of the semiconductor substrate SB1 may be the same as the depth of the isolation region EI1, and the depth of the isolation region EI in the second main surface of the semiconductor substrate SB2 may be the same as the depth of the isolation region EI2.

Subsequently, using a photolithographic technique and an ion implantation method, in the first main surface of the peripheral circuit region CR of the semiconductor substrate SB1, the p-type well W1 is formed and, in the second main surface of the peripheral circuit region CR of the semiconductor substrate SB2, the p-type well W2 is formed. In the ion implantation, a p-type impurity (e.g., B (boron)) is implanted. Note that, in the description given in the present first embodiment, n-channel transistors are formed in the peripheral circuit regions CR. However, in the areas of the peripheral circuit regions CR which are not shown, p-channel transistors are also formed. In the areas where the p-channel transistors are formed, the conductivity type of each of the impurity regions formed in the semiconductor substrates SB1 and SB2 during the formation of the n-channel transistors are inverted.

Subsequently, using a photolithographic technique and an ion implantation method, in the main surface of the pixel region PER of the semiconductor substrate SB1, the photodiode PD1 is formed. Into the upper surface of the pixel region PER of the semiconductor substrate SB1, an n-type impurity (e.g., P (phosphorus) or As (arsenic)) is implanted herein by, e.g., an ion implantation method to form the n-type semiconductor region NR. Also, into the upper surface of the pixel region PER of the semiconductor substrate SB1, a p-type impurity (e.g., B (boron)) is implanted by, e.g., an ion implantation method to form the p⁺-type semiconductor region PR. The depth of the p⁺-type semiconductor region PR is smaller than that of the n-type semiconductor region NR. The photodiode PD1 is made mainly of the n-type semiconductor region NR. The photodiode PD1 is formed herein to include the p⁺-type semiconductor region PR and the p-type semiconductor region which is the semiconductor substrate SB1 around the n-type semiconductor region NR. That is, the photodiode PD1 is formed of the PN junction between the n-type semiconductor region and the p-type semiconductor region.

Also, in the second main surface of the pixel region PER of the semiconductor substrate SB2, the photodiode PD2 is similarly formed. However, the depth of the n-type semiconductor region NR included in the photodiode PD2 is larger than the depth of the n-type semiconductor region NR included in the photodiode PD1.

In the pixel region PER of the semiconductor substrate SB1, the plurality of photodiodes PD1 are formed side by side in plan view. Each of the photodiodes PD1 is formed in the active region defined by the isolation regions EI and EI1. Each of the respective regions of the first main surface of the semiconductor substrate SB1 where the plurality of photodiodes PD1 are formed serves as one of the pixels PE. In other words, the one pixel PE has the one photodiode PD1. In the semiconductor substrate SB2 also, the one pixel PE similarly has the one photodiode PD2. However, since the semiconductor substrates SB1 and SB2 are bonded together in the subsequent step, the one pixel PE eventually has the photodiodes PD1 and PD2 as the two light receiving elements (photoelectric conversion portions).

Subsequently, over the semiconductor substrate SB1, the transfer transistor TX, the transistor Q1, and a multi-layer wiring layer including the plurality of wiring layers each covering the transfer transistor TX, the transistor Q1, and the photodiode PD1 are formed. The main characteristic feature of the method of manufacturing the solid-state imaging element in the present first embodiment does not lie in the steps of forming the transistors and the wiring layers. Accordingly, a specific description of the forming steps is omitted herein. The transfer transistor TX as an n-channel MISFET is formed in the pixel region PER, while the transistor Q1 as the n-channel MISFET is formed in the peripheral circuit region CR. The n-type semiconductor region NR forms the source region of the transfer transistor TX. Additionally, in the area of the pixel region PER which is not shown, the peripheral transistors are formed.

The transfer transistor TX, the peripheral transistors, and the photodiode PD1 are surrounded by the isolation region EI1 in plan view. The transfer transistor TX includes the floating diffusion capacitive portion FD formed in the first main surface of the semiconductor substrate SB1 and the gate electrode GT over the first main surface. The transistor Q1 includes the source/drain regions SD1 formed in the first main surface of the semiconductor substrate SB1 and the gate electrode G1 over the first main surface. The active region where the transistor Q1 is formed is defined by the isolation region EI.

Over the semiconductor substrate SB2 also, the transfer transistor TX, the transistor Q2, and the multi-layer wiring layer including the plurality of wiring layers each covering the transfer transistor TX, the transistor Q2, and the photodiode PD2 are similarly formed. The transfer transistor TX over the semiconductor substrate SB2 includes the floating diffusion capacitive portion FD formed in the second main surface of the semiconductor substrate SB2 and the gate electrode GT over the second main surface. The transistor Q2 includes the source/drain regions SD2 formed in the second main surface of the semiconductor substrate SB2 and the gate electrode G2 over the second main surface. The active region where the transistor Q2 is formed is defined by the isolation region EI.

The wires M1 and M2 in the interlayer insulating film IL1 over the semiconductor substrate SB1 are not formed immediately above the photodiode PD1. However, the wires M1 and M2 in the interlayer insulating film IL2 over the semiconductor substrate SB2 may also be formed immediately above the photodiode PD2. The wires M1 are electrically coupled to elements such as the photodiodes PD1 and PD2, the transfer transistors TX, and the transistors Q1 and Q2 via the contact plugs CP. The wires M1 and the wires M2 over the wires M1 are electrically coupled to each other through the vias. The upper surface of the multi-layer wiring layer over the semiconductor substrate SB1 is formed of the interlayer insulating film IL1. The upper surface of the multi-layer wiring layer over the semiconductor substrate SB2 is formed of the interlayer insulating film IL2.

Next, as shown in FIG. 7, to the main surface of the first semiconductor wafer, i.e., to the upper surface of the interlayer insulating film IL1, a supporting substrate SSB1 is bonded. The supporting substrate SSB1 has the function of preventing deformation of a structure over the supporting substrate SSB1 which includes the wiring layers and the semiconductor substrate SB1 or the like. Likewise, to the main surface of the second semiconductor wafer, i.e., to the upper surface of the interlayer insulating film IL2, the supporting substrate SSB2 is bonded. Each of the supporting substrates SSB1 and SSB2 is made of, e.g., a Si (silicon) substrate.

Subsequently, the semiconductor substrate SB1, i.e., the first semiconductor wafer is vertically inverted. Also, the semiconductor substrate SB2, i.e., the second semiconductor wafer is vertically inverted. That is, each of the first back surface of the semiconductor substrate SB1 and the second back surface of the semiconductor substrate SB2 is caused to face upward.

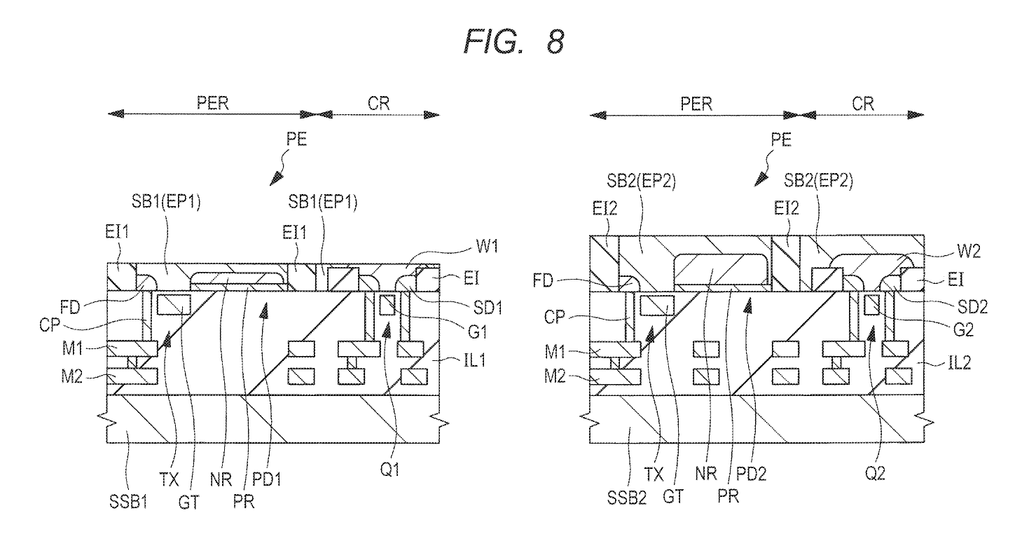

Next, as shown in FIG. 8, the first back surface of the semiconductor substrate SB1 is polished (ground) by, e.g., a CMP method, and the second back surface of the semiconductor substrate SB2 is polished (ground) by, e.g., a CMP method. Thus, the first back surface and second back surface are retreated to expose the isolation regions EI1 and EI2. By this step, each of the substrates S1 and S2 is entirely removed. The back surface of the epitaxial layer EP1 as the first back surface of the semiconductor substrate SB1 is retreated to the upper surface of the isolation region EI1. The back surface of the epitaxial layer EP2 as the second back surface of the semiconductor substrate SB2 is retreated to the upper surface of the isolation region EI2.

As a result, the depth of the isolation region EI2 is larger than the depth of the isolation region EI1. Accordingly, the thickness of the semiconductor substrate SB2 after the polishing step is larger than the thickness of the semiconductor substrate SB1 after the polishing step. The respective n-type semiconductor regions NR of the semiconductor substrates SB1 and SB2 are not exposed at the first back surface and the second back surface.

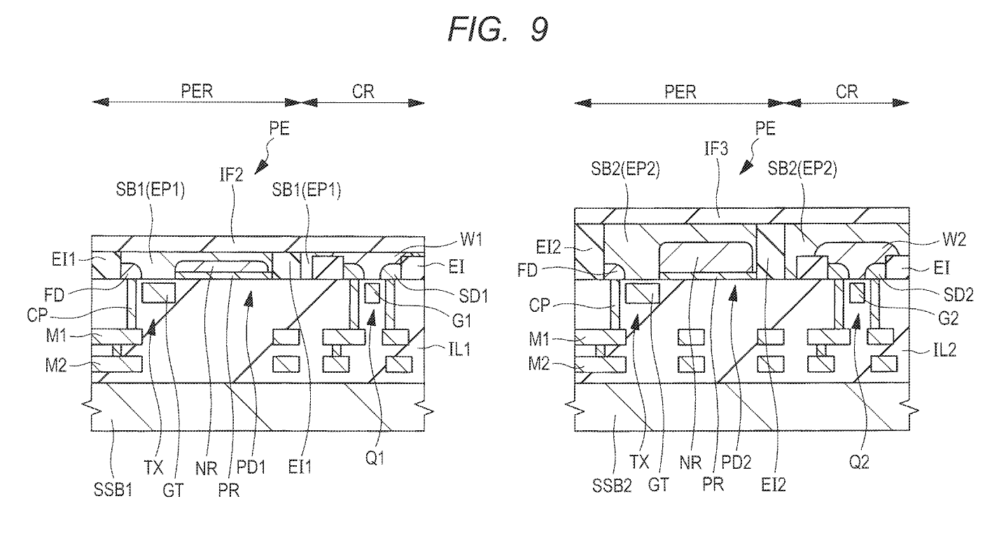

Next, as shown in FIG. 9, using, e.g., a plasma CVD method, an insulating film (oxide insulating film) IF2 is formed (deposited) to cover the back surface of the first semiconductor wafer, i.e., the first back surface of the semiconductor substrate SB1. Also, using, e.g., a plasma CVD method, an insulating film (oxide insulating film) IF3 is formed (deposited) to cover the back surface of the second semiconductor wafer, i.e., the second back surface of the semiconductor substrate SB2. The insulating film IF2 covers the upper surface of the isolation region EI1 in contact relation therewith. The insulating film IF3 covers the upper surface of the isolation region EI2 in contact relation therewith. Each of the insulating films IF2 and IF3 is made of, e.g., a silicon oxide film. Each of the insulating films IF2 and IF3 may also be formed of an insulating film formed by a plasma CVD method such as, e.g., a SiN (silicon nitride) film, a SiCN (silicon carbonitride) film, or a SiC (silicon carbide) film.

It can be considered to use, e.g., a thermal oxidation method as a method for forming the insulating films IF2 and IF3. However, when the thermal oxidation method is used, the wires M1 and M2, the vias, and the like which are already formed undergo a heat load. Accordingly, the insulating films IF2 and IF3 are formed using the plasma CVD method as a deposition method in which each of the semiconductor substrates SB1 and SB2 shows a small temperature rise.

Next, as shown in FIG. 10, the back surface of the first semiconductor wafer and the back surface of the second semiconductor wafer are joined together. That is, the upper surface of the insulating film IF2 shown in FIG. 9 and the upper surface of the insulating film IF3 shown in FIG. 9 are bonded and joined together. Thus, with the first back surface of the semiconductor substrate SB1 and the second back surface of the semiconductor substrate SB2 facing each other, a multi-layer wafer including the first semiconductor wafer and the second semiconductor wafer is formed. FIG. 10 shows the insulating film IF1 formed by integrating the insulating films IF2 and IF3 shown in FIG. 9 with each other. Briefly, the insulating film IF1 actually has a multi-layer structure including the insulating films IF2 and IF3. By joining together the epitaxial layer the first semiconductor wafer and the second semiconductor wafer, the photodiodes PD1 and PD2 face each other in the vertical direction via the insulating film IF1. In other words, the first semiconductor wafer and the second semiconductor wafer are joined together herein such that the photodiode PD1 and the photodiode PD2 overlap each other in plan view.

Subsequently, after the insulating film IF2 exposed at the back surface of the first semiconductor wafer and the insulating film IF3 exposed at the back surface of the second semiconductor wafer are bonded together, heat treatment is performed at 400° C. to enhance joint strength therebetween. When the heat treatment is performed, an elimination reaction which removes moisture from the respective surfaces of the insulating films IF2 and IF3 occurs. As a result, at the boundary between the insulating films IF2 and IF3 made of, e.g., SiO (silicon oxide), the insulating film IF2 and the insulating film IF3 share oxygen atoms. Consequently, the insulating film IF2 and the insulating film IF3 are covalently bonded to each other so that the first semiconductor wafer and the second semiconductor wafer are securely joined together.

As described above, in the present first embodiment, the first semiconductor wafer in which the semiconductor elements and the wiring layers are already formed and the second semiconductor wafer in which the semiconductor elements and the wiring layers are already formed are joined together via the insulating film IF1. As a result, as shown in FIG. 10, the multi-layer wafer is formed in which the multi-layer wiring layer, the semiconductor substrate SB2, the insulating film IF1, the semiconductor substrate SB1, the multi-layer wiring layer, and the supporting substrate SSB1 are disposed over the supporting substrate SSB2.

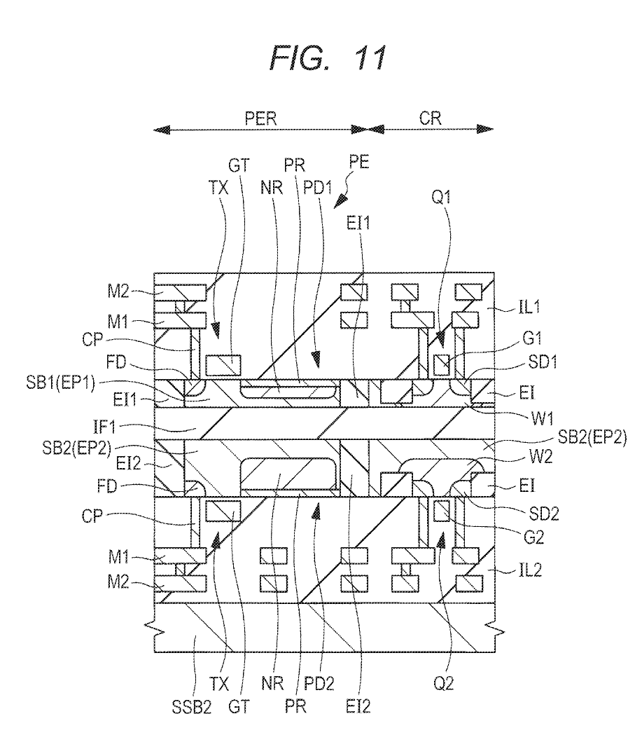

Next, as shown in FIG. 11, the supporting substrate SSB1 is removed from the upper surface of the interlayer insulating film IL1. Thus, the supporting substrate SSB1 is removed from the multi-layer wafer to expose the upper surface of the interlayer insulating film IL1.

Next, as shown in FIG. 12, a through via (vertical chip conductive coupling portion or Through Silicon Via) TSV is formed to extend through the interlayer insulating film IL1, the semiconductor substrate SB1, the insulating film IF1, and the semiconductor substrate SB2 and reach a point midway of the depth of the interlayer insulating film IL2. In FIG. 12, the pad region PDR is shown adjacent to the peripheral circuit region CR. The pad region PDR is the region where bonding pads or the like are formed over the interlayer insulating film IL1. In the drawing, the peripheral circuit region CR and the pad region PDR are separately shown, but it may also be possible to consider that the pad region PDR is a portion of the inside of the peripheral circuit region CR. The through via TSV is formed herein in the pad region PDR. The upper surface of the through via TSV is planarized at the same height as that of the position of the upper surface of the interlayer insulating film IL1. The bottom surface of the through via TSV is electrically coupled to the wire M1 in the interlayer insulating film IL2.

When the through via TSV is formed, using a photolithographic technique and a dry etching method, a through hole (coupling hole) is formed to extend through the interlayer insulating film IL1, the semiconductor substrate SB1, the insulating film IF1, and the semiconductor substrate SB2 and reach a point midway of the depth of the interlayer insulating film IL2. Thus, at the bottom portion of the through hole, the upper surface of the wire M1 in the interlayer insulating film IL2 is exposed. Subsequently, an insulating film IF4 made of, e.g., a silicon oxide film is deposited over the interlayer insulating film IL1 by a CVD method or the like, and then dry etching is performed to remove the insulating film IF4 over the upper surface of the interlayer insulating film Ill and the insulating film IF4 covering the bottom surface of the through hole. Thus, the insulating film IF4 is left only over the side surface of the through hole to expose, at the bottom portion of the through hole, the upper surface of the wire M1 in the interlayer insulating film IL2.

Subsequently, a barrier conductor film containing, e.g., Ta (tantalum) and a thin seed film made of, e.g., Cu (copper) are formed so as to cover the side and bottom surfaces of the through hole. Then, using a plating method, over the seed film, a main conductor film made of, e.g., Cu (copper) is formed to thus completely fill the through hole. Then, by, e.g., a CMP method, the extra barrier conductor film, the extra seed film, and the extra main conductor film over the interlayer insulating film IL1 are removed therefrom to expose the upper surface of the interlayer insulating film IL1. In this manner, the through via TSV including the barrier conductor film, the seed film, and the main conductor film which are embedded in the through hole is formed. In the drawing, the through via TSV is shown as a single-layer film without distinguishing the barrier conductor film, the seed film, and the main conductor film from each other.

After the though via TSV is formed as described above, pads PD are formed over the interlayer insulating film IL1. Subsequently, the passivation film PF covering the upper surface of the interlayer insulating film IL1 and pads PD is formed. The pads PD are a pattern made of a conductor film formed over the interlayer insulating film IL1. The bottom surface of one of the pads PD is electrically coupled to the upper surface of the through via TSV. That is, the pad PD is electrically coupled to the wires and the elements which are formed in the second semiconductor wafer through the through via TSV. The bottom of another of the pads PD is electrically coupled to the wires and the elements which are formed in the first semiconductor wafer through a via (not shown). The pads PD are formed by processing a metal film (e.g., an Al (aluminum) film) formed over the interlayer insulating film IL1 by, e.g., a sputtering method using a photolithographic technique and an etching method.

The passivation film PF can be formed by stacking a silicon oxide film and a silicon nitride film in this order over the isolation region EI1 and the pads PD by, e.g., a CVD method. The passivation film PF functions also as an antireflection film. That is, the passivation film PF has the function of preventing light incident on the photodiodes PD1 and PD2 from over the first main surface of the semiconductor substrate SB1 from being reflected by the upper surface of the isolation region EI1. Subsequently, using a photolithographic technique and an etching method, a portion of the passivation film PF is removed to expose a portion of the upper surface of the pad PD. Note that the region where the passivation film PF is opened by this step is not shown in the drawings. The exposed pad PD is used as a bonding pad to which a bonding wire is to be bonded.

Subsequently, in the pixel region PER, the microlens ML is formed over the passivation film PF. The microlens ML is made of a hemispherical insulating film formed in a circular shape in plan view. The one microlens ML is formed herein for the one pixel PE. The microlens ML is formed immediately above each of the photodiodes PD1 and PD2. In other words, the center of the microlens ML in plan view overlaps the photodiodes PD1 and PD2 in plan view. The microlens ML is formed by, e.g., processing a film formed over the passivation film PF into a circular pattern in plan view, performing, e.g., heating of the film to round the surface of the film including the upper and side surfaces thereof, and thus processing the film into a lens shape.

Then, the multi-layer wafer including the first semiconductor wafer and the second semiconductor wafer is cut by dicing to be singulated. Thus, the solid-state imaging elements (see FIG. 1) as the plurality of semiconductor chips are obtained. By the foregoing steps, the solid-state imaging elements in the present first embodiment are generally completed.

### Effects of First Embodiment

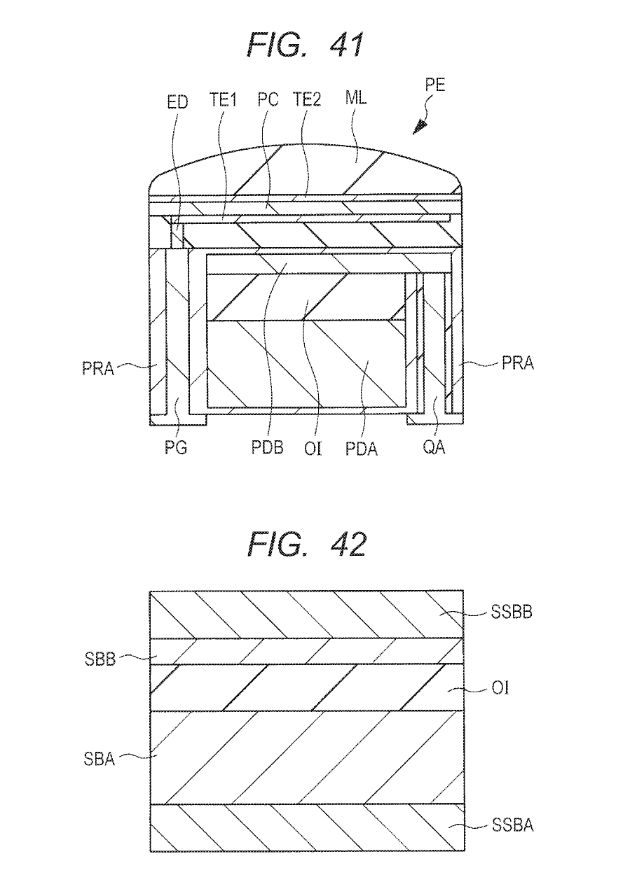

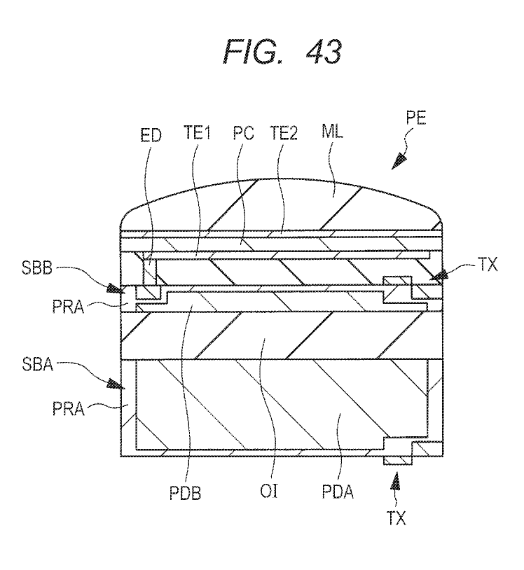

The following will describe the effects of the method of manufacturing the solid-state imaging element in the present first embodiment using a comparative example shown in FIGS. 41 to 43. FIG. 41 is a cross-sectional view of a solid-state imaging element in the comparative example. FIGS. 42 and 43 are cross-sectional views of the solid-state imaging element in the comparative example during the manufacturing process thereof.

The solid-state imaging element in the comparative example shown in FIG. 41 has a photodiode PDA, a photodiode PDB formed over the photodiode PDA, and a photoelectric conversion element formed of a photoelectric conversion film PC formed over the photodiode PDB in each of the pixels PE. That is, in the solid-state imaging element in the comparative example, the three photoelectric conversion portions are disposed to be arranged in the vertical direction in the pixel PE.

Between the photodiode PDA made mainly of an n-type semiconductor region and the photodiode PDB made mainly of an n-type semiconductor region, an optical interference film OI is interposed. The optical interference film OI has a structure in which, e.g., a silicon oxide film, a silicon film, and a silicon oxide film are stacked. The periphery of each of the photodiodes PDA and PDB is surrounded by a p-type semiconductor region PRA. The p-type semiconductor region PRA has the function of isolating the plurality of pixels arranged in the form of an array in a pixel region from each other. At a position adjacent to a multi-layer film including the photodiode PDA and the optical interference film OI, a vertical transistor QA is formed. The vertical transistor QA extends through the p-type semiconductor region PRA to be coupled to the lower surface of the photodiode PDB. The vertical transistor QA has the function of reading out the charge (information) stored in the photodiode PDB.

At a position adjacent to a multi-layer film including the photodiode PDA, the optical interference film OI, and the photodiode PDB, a plug PG is formed to extend through the p-type semiconductor region PRA. The plug PG is electrically coupled to the photoelectric conversion film PC via an electrode ED coupled to the upper surface of the plug PG and a transparent electrode TE1 covering the lower surface of the photoelectric conversion film PC. The lower surface of the photoelectric conversion film PC is in contact with the transparent electrode TE1, while the upper surface of the photoelectric conversion film PC is covered with a transparent electrode TE2. Immediately above the photodiodes PDA and PDB, the photoelectric conversion film PC, and the transparent electrode TE2, the microlens ML is formed.

In the manufacturing process of the solid-state imaging element in the comparative example shown in FIG. 41, first, a substrate including a first supporting substrate and a p-type silicon substrate over the first supporting substrate is provided. The silicon substrate is the substrate where the photodiode PDA is to be formed in the subsequent step. Subsequently, over the silicon substrate, a pattern of the optical interference film OI is formed. A portion of the upper surface of the silicon substrate is exposed herein from the optical interference film OI.

Subsequently, using an epitaxial growth method, over the silicon substrate and the optical interference film OI, a p-type epitaxial layer is formed. The p-type epitaxial layer is exposed herein lateral to the optical interference film OI. From the upper surface of the silicon substrate, the epitaxial layer continues to grow. The epitaxial layer thus formed covers the entire upper surface of the optical interference film OI. The epitaxial layer is the layer where the photodiode PDB is to be formed later.

Subsequently, a second supporting substrate is bonded to the upper surface of the epitaxial layer. Then, the first supporting substrate is removed to thus expose the lower surface of the silicon substrate. Subsequently, at a position not overlapping the optical interference film OI in plan view, the vertical transistor QA is formed to extend from the lower surface of the silicon substrate through the silicon substrate and reach a point midway of the depth of the epitaxial layer. Subsequently, an n-type impurity is introduced into the silicon substrate immediately below the optical interference film OI to thus form the photodiode PDA. Then, in the lower surface of the silicon substrate, a circuit including another transistor and the like is formed.

Subsequently, a third supporting substrate is bonded to the lower surface of the silicon substrate. Then, the second supporting substrate is removed to thus expose the upper surface of the epitaxial layer. Subsequently, into the epitaxial layer immediately above the optical interference film OI, an n-type impurity is introduced to form the photodiode PDB. Then, at a position not overlapping the photodiodes PDA and PDB and the optical interference film OI in plan view, the plug PG is formed to extend through the silicon substrate and the epitaxial layer.

Subsequently, over the epitaxial layer, an insulating film is formed, and then the electrode ED is formed to extend through the insulating film. Then, after the transparent electrode TE1, the photoelectric conversion film PC, the transparent electrode TE2, and the microlens ML are formed in this order over the insulating film, the third supporting substrate is removed. In this manner, the solid-state imaging element shown in FIG. 41 is formed. The optical interference film OI is provided so as to improve the optical color separation performance of each of the upper photodiode PDA and the lower photodiode PDB.

In the solid-state imaging element in the comparative example thus formed, the p-type semiconductor region PRA isolates the pixels PE adjacent to each other in a lateral direction from each other. This results in the problem that the movement of electrons between the adjacent pixels PE (electron crosstalk) cannot sufficiently be prevented. In this case, when imaging is performed, a problem arises in that an accurate image cannot be obtained, and the performance of the solid-state imaging element deteriorates.

In the manufacturing process in the comparative example described above, after the substrate including the silicon substrate as the region where the lower-layer photodiode PDA is formed and the epitaxial layer as the region where the upper-layer photodiode PDB is formed is formed, the photodiode PDA, the photodiode PDB, the vertical transistor QA, and other transistors are formed. That is, after the substrate including the silicon substrate and the epitaxial layer is provided, the elements are successively formed herein in each of the upper and lower surfaces of the substrate. In such a case, the step of re-bonding the supporting substrate and the step of removing the supporting substrate are repeatedly performed, resulting in a larger number of steps. As a result, a problem arises in that the manufacturing process of the solid-state imaging element is complicated to increase the manufacturing cost of the solid-state imaging element.

Next, using FIGS. 42 and 43, a description will be given of the manufacturing process of a solid-state imaging element in another comparative example. The solid-state imaging element in the comparative example has a structure in which two photoelectric conversion portions made of photodiodes and a photoelectric conversion portion made of a photoelectric conversion film are stacked in a vertical direction in each of pixels, in the same manner as in the solid-state imaging element in the comparative example described using FIG. 41.

As shown in FIG. 42, first, a substrate including a first supporting substrate SSBA and a silicon substrate SBA formed over the supporting substrate SSBA is provided. Subsequently, over the silicon substrate SBA, the optical interference film CI made of a multi-layer film including a silicon oxide film, a silicon nitride film, and a silicon oxide film are stacked in this order is formed. Subsequently, a substrate including a second supporting substrate SSBB and a silicon substrate SBB formed over the supporting substrate SSBB is provided. Subsequently, the main surface of the substrate including the supporting substrate SSBB and the silicon substrate SBB is joined to the upper surface of the optical interference film OI. Thus, the structure shown in FIG. 42 is obtained.

Next, the supporting substrate SSBA is removed to thus expose the lower surface of the silicon substrate SBA, though the illustration thereof is omitted. Subsequently, in the vicinity of the lower surface of the silicon substrate SBA, the photodiode PDA is formed and, at a position on the lower surface of the silicon substrate SBA which is adjacent to the photodiode PDA, the transfer transistor TX is formed. Also, peripheral transistors not illustrated herein, transistors in a peripheral circuit region, and the like are also formed in the lower surface of the silicon substrate SBA.

Next, a third supporting substrate is bonded to the back surface of the silicon substrate SBA, and then the supporting substrate SSBB is removed to thus expose the upper surface of the silicon substrate SBB, though the illustration thereof is omitted. Subsequently, in the vicinity of the upper surface of the silicon substrate SBB, the photodiode PDB is formed and, at a position on the upper surface of the silicon substrate SBB which is adjacent to the photodiode PDB, the transfer transistor TX is formed. Also, peripheral transistors not illustrated herein, transistors in the peripheral circuit region, and the like are also formed in the upper surface of the silicon substrate SBB.

Next, as shown in FIG. 43, an insulating film is formed over the silicon substrate SBB. Then, the electrode ED is formed to extend through the insulating film. Subsequently, over the insulating film, the transparent electrode TE1, the photoelectric conversion film PC, the transparent electrode TE2, and the microlens ML are formed in this order, and then the third supporting substrate is removed. In this manner, the solid-state imaging element is formed. The optical interference film OI is provided so as to improve the optical color separation performance of each of the upper photodiode PDA and the lower photodiode PDB.

In the solid-state imaging element in the comparative example thus formed, in the same manner as in the solid-state imaging element in the comparative example shown in FIG. 41, the p-type semiconductor region PRA isolates the pixels PE adjacent to each other in the lateral direction from each other. This results in the problem that the movement of elements between the adjacent pixels PE (electron crosstalk) cannot sufficiently be prevented.

In the manufacturing process of the solid-state imaging element in the comparative example described using FIGS. 42 and 43, after the silicon substrates SBA and SBB in each of which the elements and the wiring layers are formed are joined together, the photodiode PDA, the photodiode PDB, the transfer transistor TX, and other transistors are formed. In such a case, the step of bonding a supporting substrate and the step of removing the supporting substrate are repeatedly performed, resulting in a larger number of steps. As a result, a problem arises in that the manufacturing process of the solid-state imaging element is complicated to increase the manufacturing cost of the solid-state imaging element.

It can be considered that, in the solid-state imaging element shown in FIGS. 41 and 43, wiring layers including wires electrically coupled to elements such as transistors are formed under the photodiode PDA and over the photodiodes PDB. In this case, since each of the wires undergoes a load resulting from the heat generated during the formation of the elements, it is necessary to perform the step of forming the wiring layers after forming elements such as the photodiode PDA and transistors in the vicinity of the lower surface of the lower silicon substrate and forming elements such as the photodiode PDB and transistors in the vicinity of the lower surface of the upper silicon substrate.

In that case, e.g., after the photodiodes PDA and PDB are formed, the wiring layers are formed over the photodiode PDB. Subsequently, a fourth supporting substrate is bonded onto the photodiode PDB, and the supporting substrate under the photodiode PDA is removed. Then, under the photodiode PDA, the wiring layers are formed and, subsequently, the fourth supporting substrate is removed. Then, to the lower surface of the photodiode PDA, a fifth supporting substrate is bonded, and then the transparent electrode TE1, the photoelectric conversion film PC, the transparent electrode TE2, and the microlens ML are formed over the photodiode PDB via the foregoing wiring layers. When the wiring layers coupled to the elements are thus formed at upper and lower positions, the steps of bonding and removing the supporting substrates are further added to increase the manufacturing cost of the solid-state imaging element. Such a problem arises since, after a multi-layer substrate including a silicon layer (silicon substrate) in which the lower photodiode PDA is formed and a silicon layer (epitaxial layer or silicon substrate) in which the upper photodiode PDB is formed is provided, the elements are formed in each of the silicon layers.

As shown in FIG. 4, in the solid-state imaging element in the present first embodiment, each of the pixels PE includes the lower photodiode PD2 and the upper photodiode PD1 over the photodiode PD2 and can photoelectrically convert light at different wavelengths. That is, the photodiode PD1 can perform photoelectric conversion and detection of light at a shorter wavelength, while the photodiode PD2 can perform photoelectric conversion and detection of light at a longer wavelength. Accordingly, compared to the case where a pixel which photoelectrically converts light at a shorter wavelength and a pixel which photoelectrically converts light at a lower wavelength are formed side by side in plan view, it is possible to more reliably prevent reductions in the number of the pixels and the area occupied by the pixels and further miniaturize the solid-state imaging element. In other words, when the area occupied by the solid-state imaging element is the same, it is possible to increase the number of the pixels and, when the number of the pixels is the same, it is possible to improve sensitivity. Consequently, the increased number of the pixels and the increased area occupied by the pixels facilitate an improvement in the performance of the solid-state imaging element.

In the present first embodiment, the periphery of the photodiode PD1 is surrounded by the isolation region EI1 in plan view, while the periphery of the photodiode PD2 is surrounded by the isolation region EI2 in plan view. Accordingly, it is possible to prevent the occurrence of movement of electrons to or from the photodiode of another pixel adjacent to the pixel PE (electron crosstalk). That is, since the isolation region EI1 is formed to extend from the lower surface of the interlayer insulating film IL1 to the upper surface of the insulating film IF1 and the isolation region EI2 is formed to extend from the upper surface of the interlayer insulating film IL2 to the lower surface of the insulating film IF1, it is possible to prevent the electrons generated in each of the semiconductor substrate SB1 and the semiconductor substrate SB2 in the pixel PE from moving to another pixel.

When the first back surface of the semiconductor substrate SB1 and the second back surface of the semiconductor substrate SB2 are caused to face each other and joined together, it can also be considered to form no insulating film between the semiconductor substrates SB1 and SB2 and directly join together the semiconductor substrates SB1 and SB2. However, in this case, even when a p-type semiconductor region is present between the photodiodes PD1 and PD2, electrons may move between the semiconductor substrates SB1 and SB2 to result in electron crosstalk. In the present first embodiment, the photodiodes PD1 and the photodiodes PD2 are isolated from each other in the vertical direction by the insulating film IF1. As a result, even when the first back surface of the semiconductor substrate SB1 and the second back surface of the semiconductor substrate SB2 are caused to face each other and joined together, it is possible to prevent electrons from moving between the photodiodes PD1 and PD2.

Thus, the photodiode PD1 is surrounded by the isolation region EI1, the interlayer insulting film IL1, and the insulating film IF1, while the photodiode PD2 is surrounded by the isolation region EI2, the interlayer insulating film IL2, and the insulating film IF1. This can prevent electrons from moving between the pixels and moving in the vertical direction. Accordingly, compared to the case where the pixels are isolated from each other only by the p-type semiconductor regions around the photodiodes as in the comparative example described using FIGS. 41 to 43, the occurrence of electron crosstalk can more reliably be prevented to allow an improvement in the performance of the solid-state imaging element.

In addition, since the semiconductor substrate SB1 and the semiconductor substrate SB2 are isolated from each other by the insulating film IF1, in each of the pixel region PER and the peripheral circuit region CR, respective potentials in the semiconductor substrate SB1 and the semiconductor substrate SB2 can individually be controlled. Moreover, since the semiconductor substrate SB1 and the semiconductor substrate SB2 are isolated from each other by the insulating film IF1, it is possible to suppress the occurrence of noise resulting from interference occurring between the respective peripheral circuits of the semiconductor substrate SB1 and the semiconductor substrate SB2.

In the manufacturing process of the solid-state imaging element in the present first embodiment, after the semiconductor substrate SB1 including elements such as the photodiode PD1 and the transistor Q1 and the multi-layer wiring layer over the elements is provided and the semiconductor substrate SB2 including elements such as the photodiode PD2 and the transistor Q2 and the multi-layer wiring layer over the elements is provided, the substrates are joined together. Accordingly, after the first semiconductor wafer and the second semiconductor wafer are joined together, it is unnecessary to perform the step of forming semiconductor elements in each of the semiconductor substrates SB1 and SB2 and the step of forming the multi-layer wiring layers.

That is, in the foregoing comparative example, every time the step of producing elements or wiring layers is performed on each of the upper and lower silicon layers (silicon substrates or epitaxial layers), it is necessary to re-bond a supporting substrate thereto, resulting in a complicated manufacturing process. However, in the present first embodiment, the semiconductor wafers in each of which the elements and the wiring layers are formed are joined together. This can reduce the number of the steps of bonding and removing the supporting substrates. Therefore, it is possible herein to simplify the manufacturing process of the solid-state imaging element and reduce the manufacturing cost of the solid-state imaging element.

Note that, in the description given in the present first embodiment, the isolation regions EI1 and EI2 each having the STI structure are formed. However, each of the isolation regions EI1 and EI2 may also have a DTI (Deep Trench Isolation) structure. That is, e.g., in the manufacturing process of the first semiconductor wafer, the isolation region EI1 is not formed, but the photodiode PD1, the transfer transistor TX, and the transistor Q1 each shown in FIG. 6 are formed. Then, an interlayer insulating film is formed to cover the elements. Subsequently, a trench extending through the interlayer insulating film to reach a point midway of the depth of the semiconductor substrate SB1 is formed, and then an insulating film such as a silicon oxide film is embedded in the trench to allow the isolation region EI1 having a deep DTI structure to be formed.

### First Modification of First Embodiment

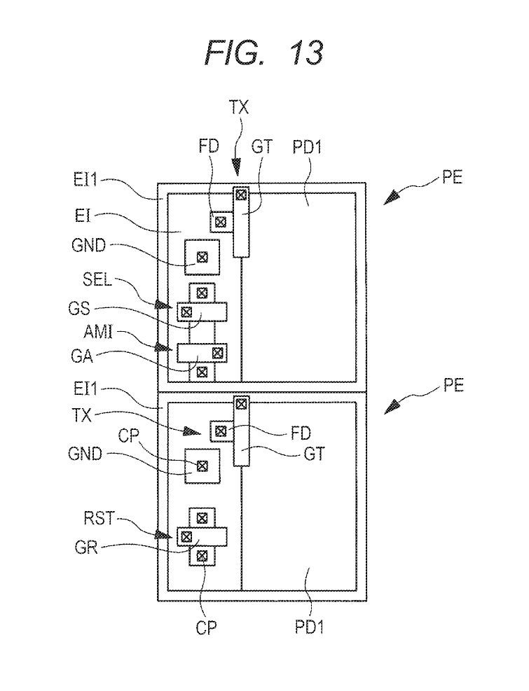

FIG. 13 shows a plan view of a solid-state imaging element in a first modification of the present first embodiment. Similarly to FIG. 2, FIG. 13 shows a two-dimensional layout of each of the pixels but, in FIG. 13, two pixels are shown side by side.

As shown in FIG. 13, in the same manner as in the structure shown in FIG. 2, each of the pixels PE includes the photodiode PD1, the transfer transistor TX, and the grounded region GND in the region surrounded by the isolation region EII. However, the structure shown in FIG. 13 is different from the structure shown in FIG. 2 in that the selection transistor SEL and the amplification transistor AMI are formed only in one of the two pixels PE adjacent to each other, while the reset transistor RST is formed only in the other pixel PE. In the structure shown herein, the floating diffusion capacitive portion FD and the gate electrode GA of one of the pixels PE are electrically coupled to the floating diffusion capacitive portion FD and the source region of the reset transistor RST of the other pixel PE via wires (not shown).

In the present first modification, the adjacent two pixels PE share peripheral transistors. This can widen the region where the photodiode PD1 is formed in each of the pixels PE. Accordingly, it is possible to improve the performance of the solid-state imaging element.

### Second Modification of First Embodiment

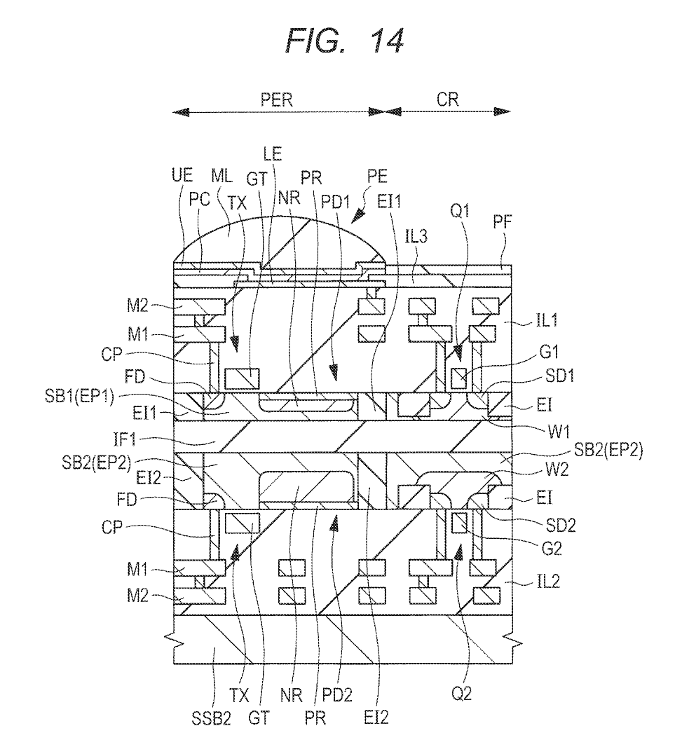

FIG. 14 shows a cross-sectional view of a solid-state imaging element in a second modification of the present first embodiment. FIG. 14 is a cross-sectional view corresponding to FIG. 4. In the description given herein, a light receiving element made of a photoelectric conversion film is further formed over the two stacked photodiodes in addition thereto.

As shown in FIG. 14, the solid-state imaging element in the present second modification has the photoelectric conversion film PC over the interlayer insulating film IL1 and immediately above each of the photodiodes PD1 and PD2. In other words, the photodiodes PD1 and PD2 and the photoelectric conversion film PC are formed at positions overlapping each other in plan view. In each of the pixels PE, the one photoelectric conversion film PC is formed immediately below the microlens ML. The lower surface of the photoelectric conversion film PC is in contact with a lower electrode LE, and the photoelectric conversion film PC is electrically coupled to the wires M2 in the interlayer insulating film IL1 via the lower electrode and vias. The upper surface of the photoelectric conversion film PC is covered with an upper electrode UE in contact therewith. The photoelectric conversion film PC and the passivation film PF are formed herein adjacent to each other, and the passivation film PF does not cover the upper surface of the upper electrode UE. However, it may also be possible that a portion of the passivation film PF covers the upper surface of the upper electrode UE.

Over the interlayer insulating film IL1, an interlayer insulating film IL3 is formed, and the side surfaces and a portion of the upper surface of the lower electrode LE are covered with the interlayer insulating film IL3. Another portion of the upper surface of the lower electrode LE is in contact with the lower surface of the photoelectric conversion film PC in the opening of the interlayer insulating film IL3. The photoelectric conversion film PC and the upper electrode UE are formed over the interlayer insulating film IL3 and immediately below the microlens ML. In the peripheral circuit region CR, the lower electrode LE, the photoelectric conversion film PC, and the upper electrode UE are not formed.

The photoelectric conversion film PC is a photoelectric conversion element (photoelectric conversion portion or light receiving element). In the present second modification, light in a first wavelength region is detected by the photodiode PD2, light in a second wavelength region is detected by the photodiode PD1, and light in a third wavelength region is detected by the photoelectric conversion film PC. For example, the respective wavelengths of the light in the first wavelength region, the light in the second wavelength region, and the light in the third wavelength region are progressively shorter in this order. For example, the lowermost photodiode PD2 detects red light, the middle photodiode PD1 detects blue light, and the uppermost photoelectric conversion film PC detects green light. This allows even the one pixel PE to photoelectrically convert each of the red light, the blue light, and the green light.

The photoelectric conversion film PC is made of a material having the property of absorbing the light in the third wavelength region (such as, e.g., an inorganic photoelectric conversion film, an organic photoelectric conversion film, or a quantum film). The photoelectric conversion film PC is formed of an organic photoelectric conversion material containing a rhodamine-based pigment, a merocyanine-based pigment, quinacridone, or the like. The photoelectric conversion film PC absorbs light in a specified wavelength region which is included in incident light and converts the absorbed light to electrons. The photoelectric conversion film PC is interposed between the upper electrode UE and the lower electrode LE in the vertical direction.

The lower electrode LE and the upper electrode UE are each formed of a material which transmits the light in the first wavelength region and the light in the second wavelength region. The lower electrode LE and the upper electrode UE are each made of a light transmissive material such as, e.g., an ITO (indium tin oxide) film or an IZO (indium zinc oxide) film. The interlayer insulating film IL3 is made of, e.g., a silicon oxide film. Thus, the present first embodiment is also applicable to the solid-state imaging element in which the three photoelectric conversion portions are formed in stacked relation in each of pixels.

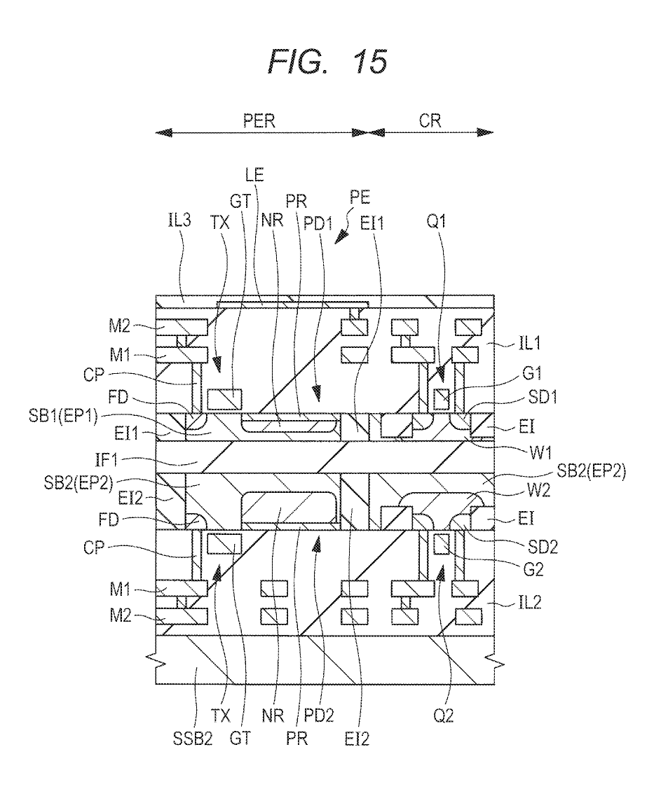

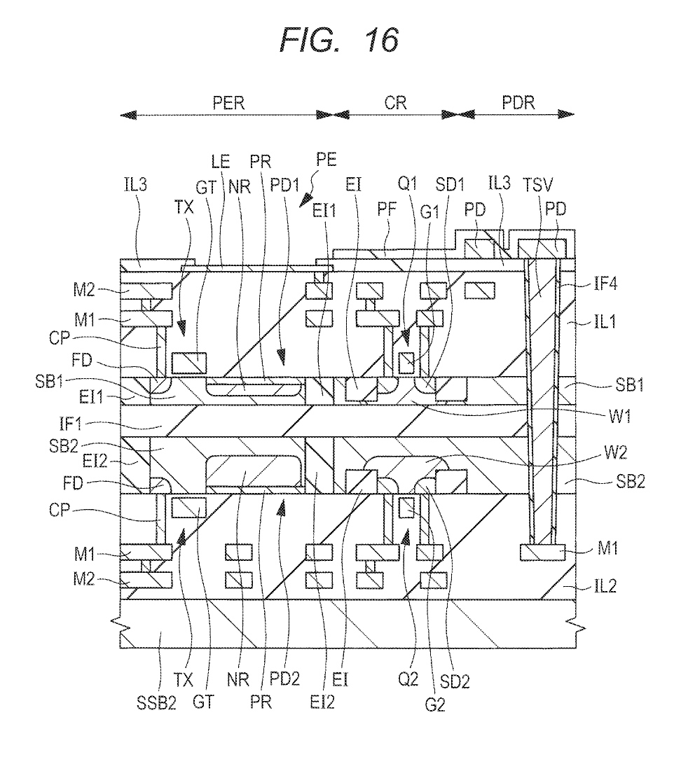

Using FIGS. 15 to 17, the following will describe a method of manufacturing the solid imaging element in the present second modification. FIGS. 15 to 17 are cross-sectional views of the solid-state imaging element in the present second modification during the manufacturing process thereof. Note that FIG. 16 shows the pad region PDR.

First, the same steps as the steps described using FIGS. 5 to 11 are performed to join together the first semiconductor wafer and the second semiconductor wafer and expose the upper surface of the interlayer insulating film IL1.

Next, as shown in FIG. 15, in the pixel region PER, a via is formed to be embedded in the via hole formed in the upper surface of the interlayer insulating film IL1 and coupled to the upper surface of the wire M2. Subsequently, over the interlayer insulating film IL1 and the via, a metal film is formed by, e.g., a sputtering method. Then, using a photolithographic technique and an etching method, the metal film is processed to form the lower electrode LE made of the metal film in the pixel region PER. The lower electrode LE is made of, e.g., an ITO film, and the lower surface of the lower electrode LE is coupled to the upper surface of the foregoing via. The lower electrode LE is formed immediately above each of the photodiodes PD1 and PD2. The lower electrode LE can be formed by, e.g., a sputtering method. Subsequently, using, e.g., a CVD method, the interlayer insulating film IL3 covering the lower electrode LE is formed over the interlayer insulating film IL1. The interlayer insulating film IL3 is made of, e.g., a silicon oxide film.

Next, as shown in FIG. 16, the same steps as the steps of forming the through via TSV, the pads PD, and the passivation film PF described using FIG. 12 are performed. Thus, the through via TSV is formed to extend through the interlayer insulating films IL3 and IL1, the semiconductor substrate SB1, the insulating film IF1, and the semiconductor substrate SB2 and reach a point midway of the depth of the interlayer insulating film IL2, and the pads PD and the passivation film PF are formed over the interlayer insulating film IL3. Then, using a photolithographic technique and an etching method, the passivation film PF is removed from the pixel region PER.

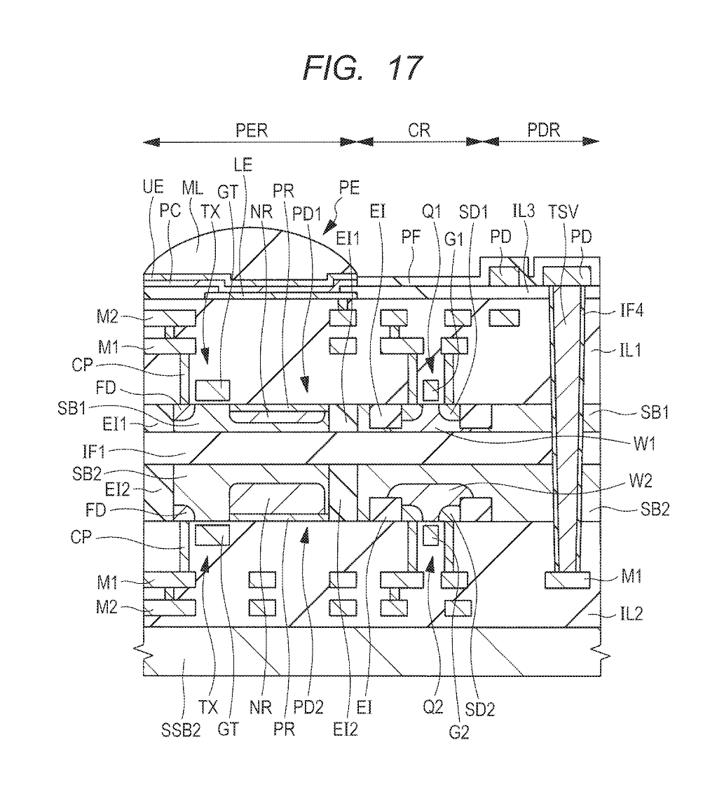

Next, as shown in FIG. 17, using a photolithographic technique and an etching method, a portion of the interlayer insulating film IL3 located in the pixel region PER is opened to thus expose a portion of the upper surface of the lower electrode LE immediately above each of the photodiodes PD1 and PD2. Subsequently, the photoelectric conversion film PC and the upper electrode UE are formed in this order over the interlayer insulating film IL3. Then, by patterning the upper electrode UE and the photoelectric conversion film PC, the upper electrode UE and the photoelectric conversion film PC are left over each of the photodiodes PD1 and PD2. A portion of the lower surface of the photoelectric conversion film PC is coupled to the upper surface of the lower electrode LE. The upper electrode UE can be formed by, e.g., a sputtering method.

Subsequently, the microlens ML is formed so as to cover the lower electrode LE, the photoelectric conversion film PC, and the upper electrode UE. Then, the multi-layer wafer is singulated by dicing to generally complete the solid-state imaging elements in the present second modification. Thus, the present first embodiment is also applicable to the method of manufacturing the solid-state imaging element in which the three photoelectric conversion portions are formed in stacked relation in each of the pixels.

### Third Modification of First Embodiment

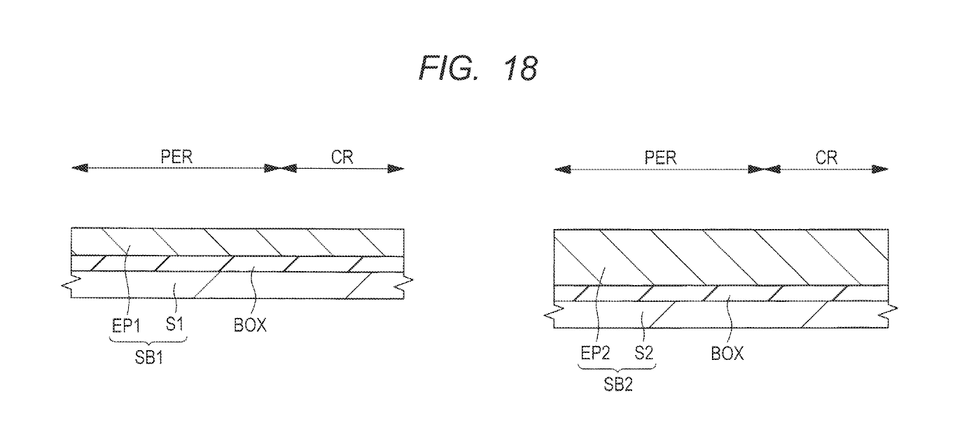

The following will describe a method of manufacturing a solid-state imaging element in a third modification of the present first embodiment. FIGS. 18 to 21 are cross-sectional views of the solid-state imaging element in the present third modification during the manufacturing process thereof. In the case described herein, each of the first semiconductor substrate and the second semiconductor substrate is provided as a SOI (Silicon On Insulator) substrate, and the first and second semiconductor substrates are joined together.

First, as shown in FIG. 18, in the same manner as in the step described using FIG. 5, the first semiconductor substrate SB1 and the second semiconductor substrate SB2 are provided. In the structure in FIG. 18, unlike in the structure in FIG. 5, the semiconductor substrate SB1 has an insulating film (buried oxide film) BOX between the substrate S1 and the epitaxial layer EP1, while the semiconductor substrate SB2 has the insulating film (buried oxide film) BOX between the substrate S2 and the epitaxial layer EP2. That is, each of the semiconductor substrates SB1 and SB2 is the SOI substrate, and each of the epitaxial layers EP1 and EP2 is a SOI layer.

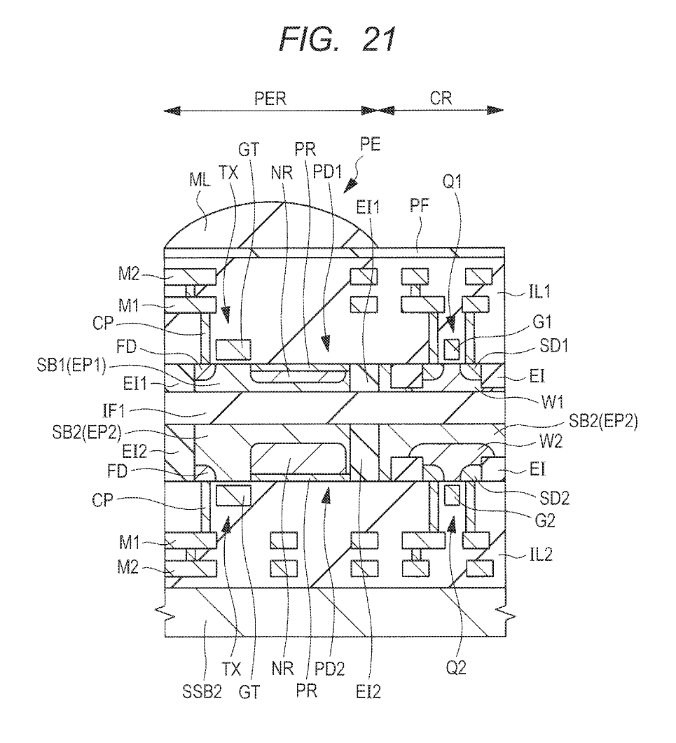

In the present third modification, the thickness of the epitaxial layer EP2 is larger than the thickness of the epitaxial layer EP1. The epitaxial layer EP1 is formed thinner in accordance with light in the second wavelength region (shorter-wavelength visible light) to be photoelectrically converted by the photodiode PD1 (see FIG. 21) formed in the epitaxial layer EP1. The epitaxial layer EP2 is formed thicker in accordance with light in the first wavelength region (shorter-wavelength visible light) to be photoelectrically converted by the photodiode PD2 (see FIG. 21) formed in the epitaxial layer EP2.

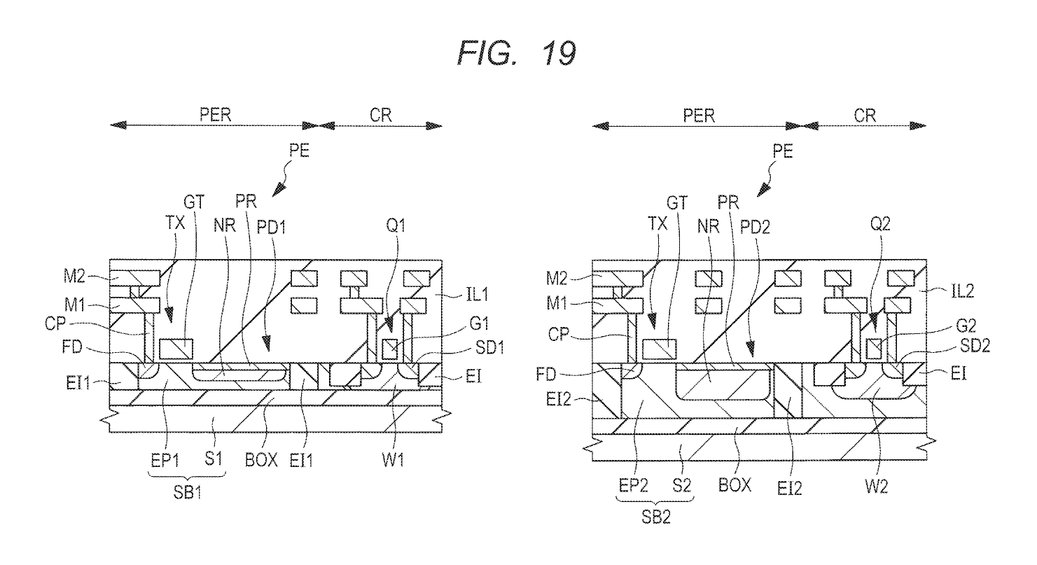

Next, as shown in FIG. 19, in the same manner as in the step described using FIG. 6, the individual elements and the multi-layer wiring layers are formed. The isolation region EI1 is formed herein to extend through the epitaxial layer EP1. That is, the lower surface of the isolation region EI1 reaches the upper surface of the insulating film BOX. Likewise, the isolation region EI2 is formed to extend through the epitaxial layer EP2. Since the thickness of the epitaxial layer EP2 is larger than the thickness of the epitaxial layer EP1, the isolation region EI2 is formed deeper than the isolation region EI1.

The photodiode PD1 is formed in the epitaxial layer EP1, and the n-type semiconductor region NR included in the photodiode PD1 does not reach the upper surface of the insulating film BOX. Likewise, the photodiode PD2 is formed in the epitaxial layer EP2, and the n-type semiconductor region NR included in the photodiode PD2 does not reach the upper surface of the insulating film BOX.

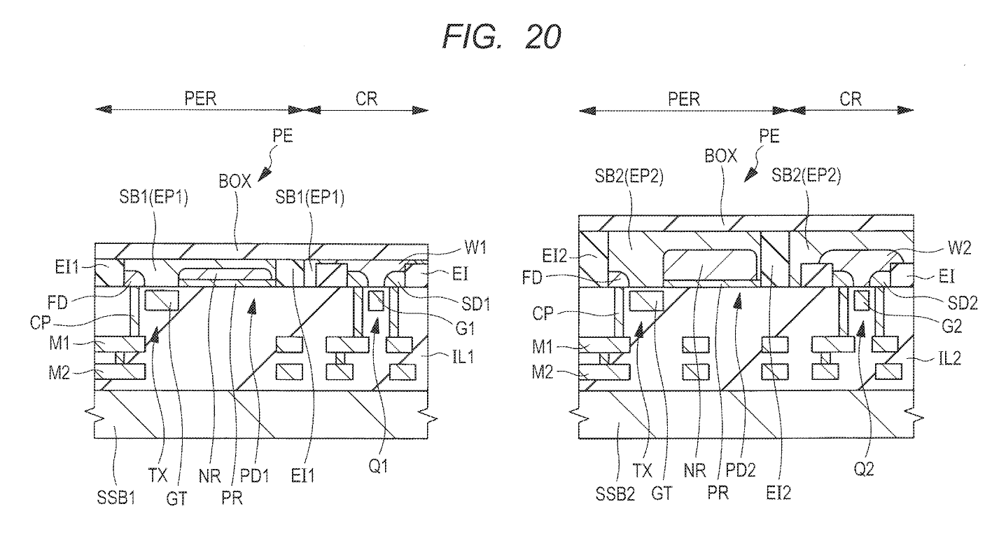

Next, as shown in FIG. 20, in the same manner as in the step described using FIGS. 7 and 8, each of the semiconductor substrates to which supporting substrates are bonded is vertically inverted, and then the first back surface of the semiconductor substrate SB1 and the second back surface of the semiconductor substrate SB2 are polished by, e.g., a CMP method. The substrates S1 and S2 are polished herein until the upper surfaces of the insulating films BOX are exposed to be thus removed. At this time, since each of the insulating films BOX functions as a stopper film in the polishing step, the controllability of the amount of polishing can be improved. That is, it is possible to control the respective amounts of retreat of the first back surface of the semiconductor substrate SB1 and the second back surface of the semiconductor substrate SB2.

Next, as shown in FIG. 21, using, e.g., a wet etching method, the insulating films BOX are removed from the respective back surfaces of the first semiconductor wafer and the second semiconductor wafer to thus expose the respective back surfaces (upper surfaces) of the epitaxial layers EP1 and EP2 and the isolation regions EI1 and EI2. Then, the same steps as the steps described using FIGS. 9 to 12 are performed to thus generally complete the solid-state imaging element in the present third modification. That is, after the insulating films IF2 and IF3 (see FIG. 9) are formed herein to cover the respective back surfaces of the first semiconductor wafer and the second semiconductor wafer, the respective back surfaces of the first semiconductor wafer and the second semiconductor wafer are joined together to form the insulating film IF1. Subsequently, over the interlayer insulating film IL′, the passivation film PF and the microlens ML are formed.

However, it may also be possible to join together the first semiconductor wafer and the second semiconductor wafer without removing the insulating films BOX shown in FIG. 20 and forming the insulating films IF2 and IF3. By doing so, the insulating films BOX over the respective back surfaces of the first semiconductor wafer and the second semiconductor wafer are bonded together to form the insulating film IF1. In this case, since the step of removing the insulating films BOX and the step of forming the insulating films IF2 and IF3 can be omitted, the manufacturing cost of the solid-state imaging element can be reduced.

Similarly to the present third modification, the present first embodiment is applicable to a solid-state imaging element using SOI substrates. By using the SOI substrates, the effect of improving controllability in the step (see FIG. 20) of thinning the first semiconductor wafer and the second semiconductor wafer can be obtained herein.

### Second Embodiment

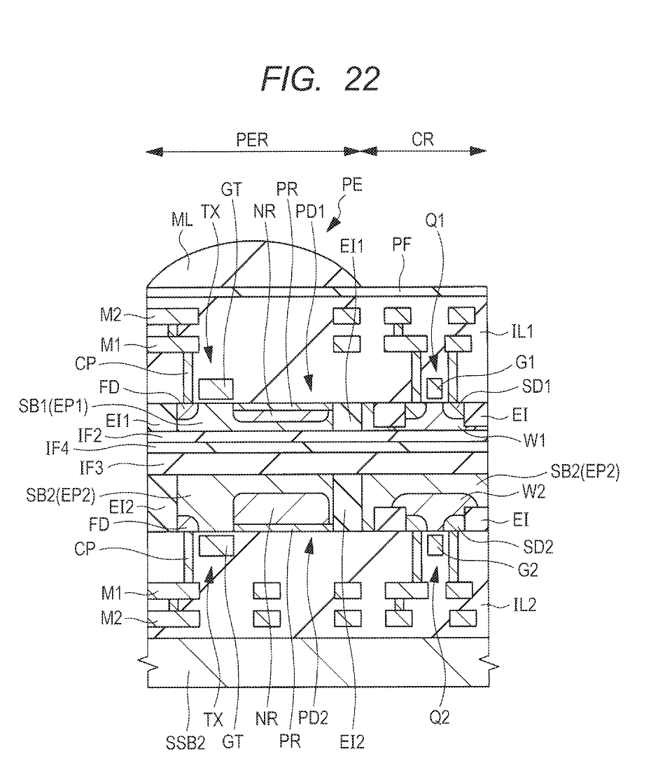

Using FIG. 22, the following will describe a structure of a solid-state imaging element in the present second embodiment. FIG. 22 is a cross-sectional view showing the solid-state imaging element in the present second embodiment. In the description given herein, a film in which negative charge is fixed is formed between the first semiconductor wafer and the second semiconductor wafer to prevent a dark current from being generated.

As shown in FIG. 20, the solid-state imaging element in the present second embodiment has the same structure as that of the solid-state imaging element in the foregoing first embodiment except for a structure between the semiconductor substrates SB1 and SB2. In the present second embodiment, between the upper surface (second back surface) of the semiconductor substrate SB2 and the lower surface (first back surface) of the semiconductor substrate SB1, the insulating film IF3, an insulating film IF4, and the insulating film IF2 are formed in this order with distance from the semiconductor substrate SB2. The upper surface (second back surface) of the semiconductor substrate SB2 is in contact with the insulating film IF3, while the lower surface (first back surface) of the semiconductor substrate SB1 is in contact with the insulating film IF2. Each of the insulating films IF2 and IF3 is made of, e.g., a silicon oxide film, a silicon nitride film, a silicon carbonitride film, or a silicon carbide film. Actually, the insulating film IF3 has a multi-layer structure including two films, and the insulating film IF3 is thicker than the insulating film IF2.

The insulating film IF4 is a film (film having negative charge) in which negative charge is fixed, and is made of, e.g., a HfO (hafnium oxide) film.

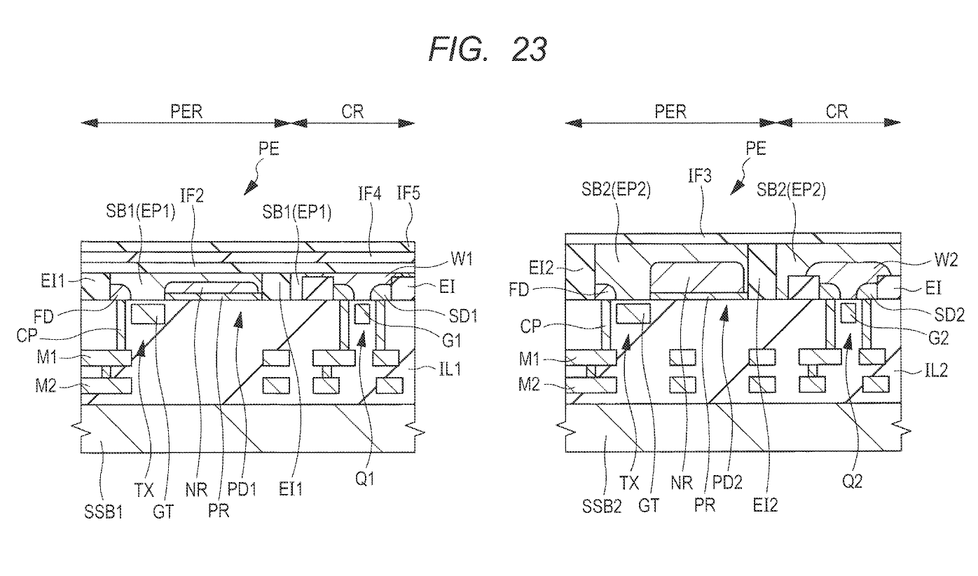

Using FIG. 23, the following will describe a method of manufacturing the solid-state imaging element in the present second embodiment. FIG. 23 is a cross-sectional view of the solid-state imaging element in the present second embodiment. First, the steps described using FIGS. 5 to 8 are performed herein.

Next, as shown in FIG. 23, the insulating film IF2, the insulating film IF4, and an insulating film IF5 are formed in this order so as to cover the first back surface of the semiconductor substrate SB1, while the insulating film IF3 is formed so as to cover the second back surface of the semiconductor substrate SB2. The insulating film IF4 is made of, e.g., a HfO film, while the insulating film IF5 is made of, e.g., a silicon oxide film. The insulating films IF4 and IF5 can be formed by, e.g., a CVD method.

Subsequently, the same steps as the steps described using FIGS. 10 to 12 are performed to generally complete the solid-state imaging element shown in FIG. 22. That is, the insulating film IF5 exposed at the back surface of the first semiconductor wafer and the insulating film IF3 exposed at the back surface of the second semiconductor wafer are joined together to form a multi-layer wafer. In FIG. 22, only the insulating film IF3 is shown on the assumption that the insulating film IF5 is integrated with the insulating film IF3. That is, the insulating film IF3 having a multi-layer structure including the two insulating films is thicker than the insulating film IF2.

Note that, in the description of the case illustrated in FIG. 23, the insulating film IF4 is deposited over the first back surface of the first semiconductor substrate SB1. However, it may also be possible to deposit only the insulating film IF2 over the first back surface of the first semiconductor substrate SB1 and deposit the insulating film IF4 and the insulating film IF5 over the second back surface of the second semiconductor substrate SB2 via the insulating film IF3. In this case, in the completed solid-state imaging element, the thickness of the insulating film IF2 over the insulating film IF4 is larger than that of the insulating film IF3.

In the present second embodiment, the photodiodes PD1 and PD2 are each isolated from another pixel by the isolation regions EI1 and EI2, and the first semiconductor wafer and the second semiconductor wafer in each of which the elements and the wiring layers are formed are joined together to form the multi-layer wafer. This allows the same effects as obtained from the foregoing first embodiment to be obtained.

In the solid-state imaging element in the present second embodiment, between the semiconductor substrate SB1 in which the photodiode PD1 is formed and the semiconductor substrate SB2 in which the photodiode PD2 is formed, the insulating film IF4 having the negative fixed charge is formed via the insulating film IF2 or IF3. Since the insulating film IF4 has the negative charge, in the semiconductor substrate SB1 adjacent to the insulating film IF4 via the insulating film IF2, positive charge (holes) is induced. The holes are generated in the semiconductor substrate SB1 located in the vicinity of the first back surface closer to the insulating film IF4. Likewise, in the semiconductor substrate SB2 adjacent to the insulating film IF4 via the insulating film IF3, positive charge (holes) is induced. The holes are generated in the semiconductor substrate SB2 located in the vicinity of the second back surface closer to the insulating film IF4.

In each of the silicon layers having the photodiodes, electrons are likely to be generated at the interface where the silicon layer and the insulating film are in contact with each other, and a problem arises in that, due to the presence of the electrons, a dark current is generated. The dark current is generated by the electrons generated in the pixel not illuminated with light in the pixel region of the solid-state imaging element. Accordingly, the generation of the dark current degrades the imaging performance of the solid-state imaging element.

In the solid-state imaging element in the present second embodiment, it is possible to eliminate the electrons generated at the interface between the semiconductor substrate SB1 and the insulating film IF2 using the holes induced at the first back surface of the semiconductor substrate SB1 by the negative charge of the insulating film IF4. Likewise, it is possible to eliminate the electrons generated at the interface between the semiconductor substrate SB2 and the insulating film IF3 using the holes induced at the second back surface of the semiconductor substrate SB2 by the negative charge of the insulating film IF4. This can prevent the generation of the dark current and thus improve the performance of the solid-state imaging element.

Note that the insulating films IF2 and IF3 shown in FIG. need not necessarily be formed. Also, the photoelectric conversion film PC (see FIG. 14) described in the second modification of the foregoing first embodiment may also be applied to the present second embodiment.

### First Modification of Second Embodiment

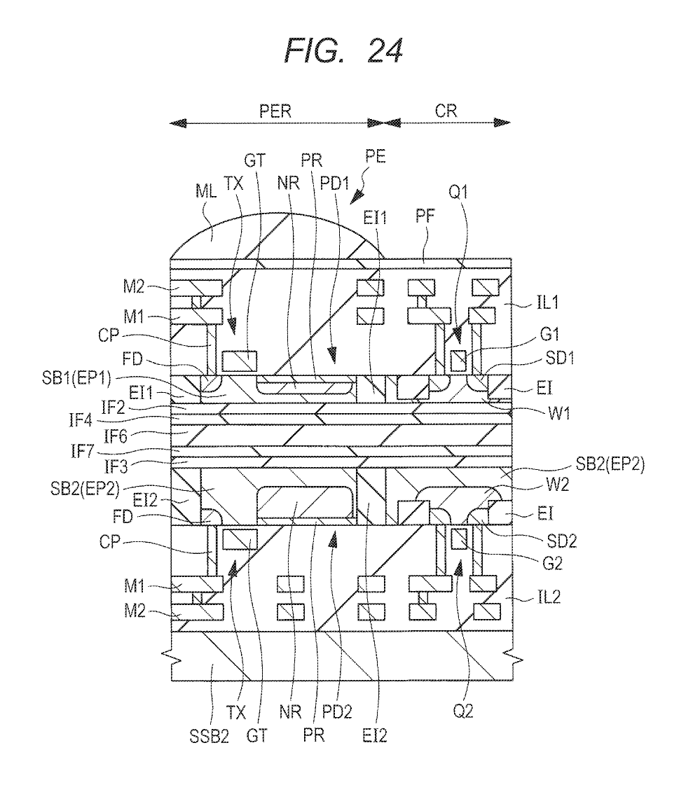

Using FIG. 24, the following will describe the structure of a solid-state imaging element in the first modification of the present second embodiment. FIG. 24 is a cross-sectional view showing the solid-state imaging element in the present first modification. In the description given herein, two films in each of which negative charge is fixed are formed in stacked relation between the first semiconductor wafer and the second semiconductor wafer to thus prevent the generation of a dark current.

As shown in FIG. 24, the solid-state imaging element in the present first modification has the same structure as that of the solid-state imaging element shown in FIG. 22 except for the structure between the semiconductor substrates SB1 and SB2. Between the upper surface (second back surface) of the semiconductor substrate SB2 and the lower surface (first back surface) of the semiconductor substrate SB1, the insulating film IF3, an insulating film IF7, an insulating film IF6, the insulating film IF4, and the insulating film IF2 are formed in this order with distance from the semiconductor substrate SB2. The upper surface (second back surface) of the semiconductor substrate SB2 is in contact with the insulating film IF3, while the lower surface (first back surface) of the semiconductor substrate SB1 is in contact with the insulating film IF2. Each of the insulating films IF2, IF3, and IF6 is made of, e.g., a silicon oxide film, a silicon nitride film, a silicon carbonitride film, or a silicon carbide film. Actually, the insulating film IF6 has a multi-layer structure including two films and is thicker than each of the insulating films IF2 and IF3.

Each of the insulating films IF4 and IF7 is a film in which negative charge is fixed, and is made of, e.g., a HfO (hafnium oxide) film. That is, in the solid-state imaging element shown in FIG. 22, only the one insulating film IF4 in which negative charge is fixed is formed, but the two insulating films IF4 and IF7 in each of which negative charge is fixed are formed herein in stacked relation via the insulating film IF6.

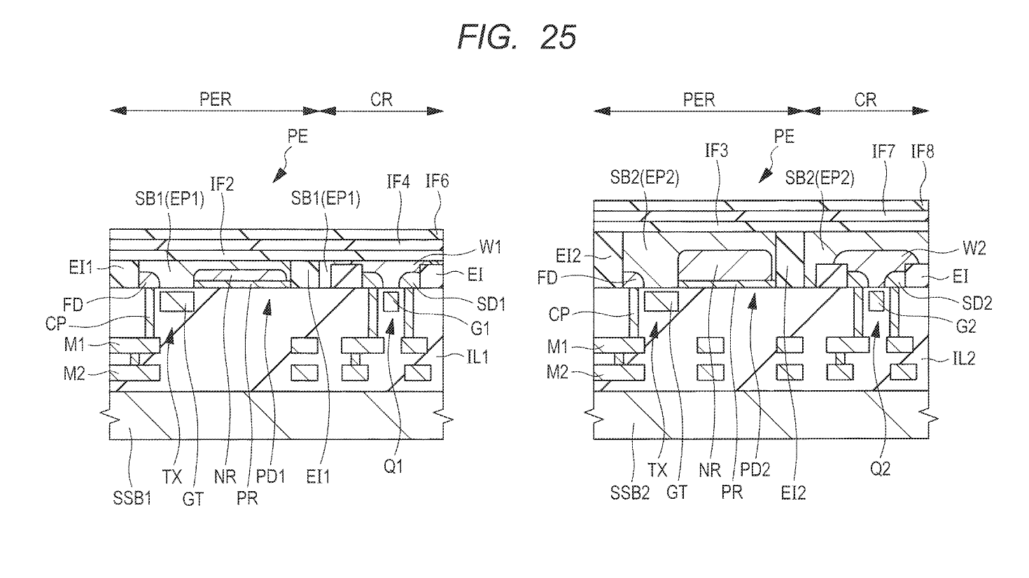

The following will describe a method of manufacturing the solid-state imaging element in the present first modification. FIG. 25 is a cross-sectional view of the solid-state imaging element in the present first modification during the manufacturing process thereof. First, the steps described using FIGS. 5 to 8 are performed herein.

Next, as shown in FIG. 25, the insulating film IF2, the insulating film IF4, and the insulating film IF6 are formed in this order so as to cover the first back surface of the semiconductor substrate SB1, while the insulating film IF3, the insulating film IF7, and the insulating film IF8 are formed in this order so as to cover the second back surface of the semiconductor substrate SB2. That is, after the insulating film IF2 is formed, the insulating film IF4 and the insulating film IF6 are formed in this order so as to cover the exposed surface of the insulating film IF2. On the other hand, after the insulating film IF3 is formed, the insulating films IF7 and the insulating film IF8 are formed in this order so as to cover the exposed surface of the insulating film IF3.

Each of the insulating films IF4 and IF7 is made of, e.g., a HfO film, while each of the insulating films IF6 and IF8 is made of, e.g., a silicon oxide film. The insulating films IF4, IF6, IF7, and IF8 can be formed by, e.g., a CVD method.

Then, the same steps as the steps described using FIGS. 10 to 12 are performed to generally complete the solid-state imaging element shown in FIG. 24. That is, in the present first modification, the insulating film IF6 exposed at the back surface of the first semiconductor wafer and the insulating film IF8 exposed at the back surface of the second semiconductor wafer are joined together to form a multi-layer wafer. In FIG. 24, only the insulating film IF6 is shown on the assumption that the insulating film IF8 is integrated with the insulating film IF6. That is, the insulating film IF6 having a multi-layer structure including the two insulating films is thicker than each of the insulating films IF2 and IF3.

In the present first modification, the same effects as obtained from the foregoing first embodiment can be obtained.

Under the first back surface of the semiconductor substrate SB1, the insulating film IF4 having the negative fixed charge is formed via the insulating film IF2 while, over the second back surface of the semiconductor substrate SB2, the insulating film IF7 having the negative fixed charge is formed via the insulating film IF3. This can prevent a dark current from being generated in each of the pixels PE.

In addition, in the present first modification, it is easy to provide the insulating films IF2 and IF3 with equal thicknesses. This is because, when the first semiconductor wafer and the second semiconductor wafer which are provided in the step described using FIG. 25 are joined together, the insulating films IF6 and IF8 are coupled to each other in facing relation, while the insulating film IF2 in contact with the semiconductor substrate SB1 and the insulating film IF3 in contact with the semiconductor substrate SB2 are not coupled to each other in facing relation. Therefore, it is possible to prevent either one of the insulating films IF2 and IF3 from being thickened by the joining together of the two wafers.

When there is a difference between the thickness of the insulating film IF2 and the thickness of the insulating film IF3, the effect of suppressing a dark current obtained by forming the insulating films IF4 and IF7 differs between the lower photodiode PD2 and the upper photodiode PD1. By contrast, in the present first modification, the insulating films IF2 and IF3 can be formed to have equal thicknesses. This allows each of the lower photodiode PD2 and the upper photodiode PD1 to obtain the same effect of suppressing a dark current.

Since it is possible to prevent either one of the insulating films IF2 and IF3 from being thickened, it is not necessary to thicken the thinner one of the insulating films IF2 and IF3 in accordance with the other thicker one of the insulating films IF2 and IF3 so as to provide each of the upper and lower photodiodes PD1 and PD2 with an equal effect of suppressing a dark current. That is, since both of the insulating films IF2 and IF3 can be thinned, the effect of suppressing a dark current can more remarkably be obtained. Note that the photoelectric conversion film PC (see FIG. 14) described in the second modification of the foregoing first embodiment may also be applied to the present first modification.

### Second Modification of Second Embodiment

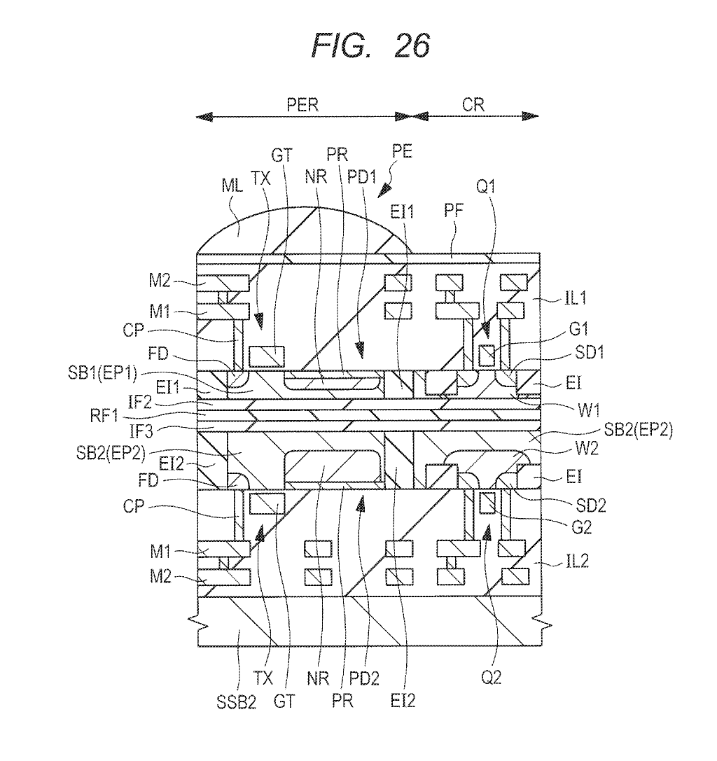

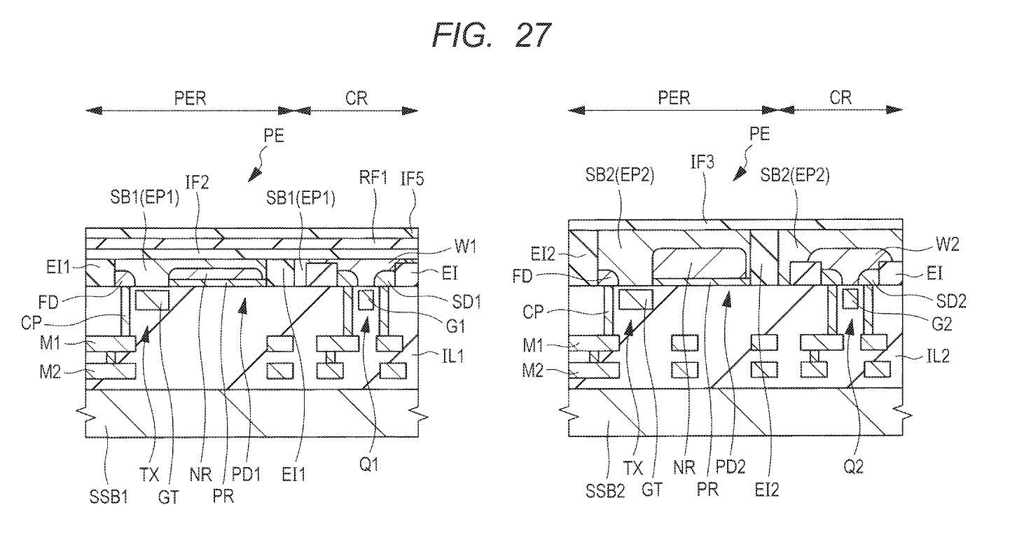

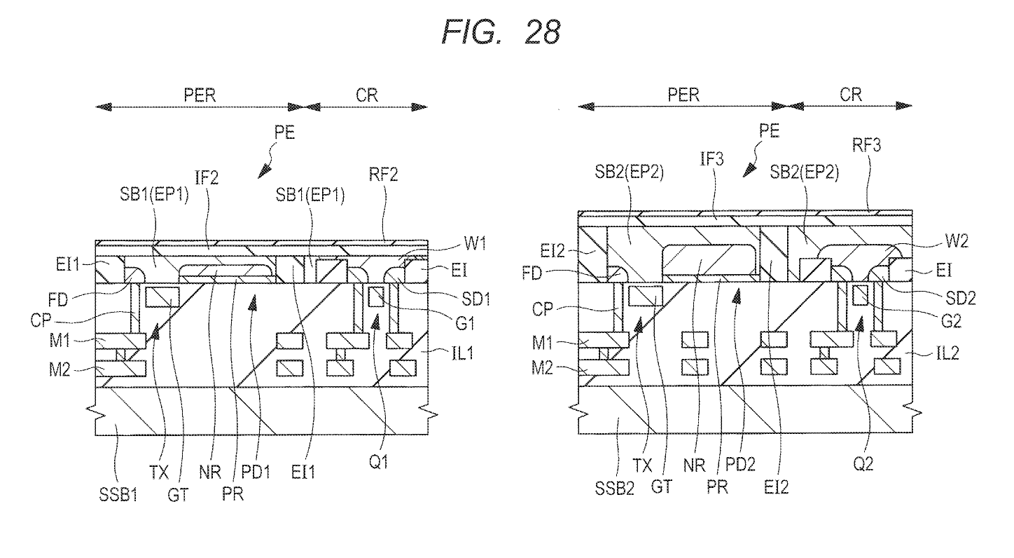

Using FIG. 26, a description will be given of a structure of a solid-state imaging element in a second modification of the present second embodiment. Also, using FIGS. 27 and 28, a description will be given of a method of manufacturing the solid-state imaging element in the second modification of the present second embodiment. FIG. 26 is a cross-sectional view showing the solid-state imaging element in the present second modification. FIGS. 27 and 28 are cross-sectional views of the solid-state imaging element in the present second modification during the manufacturing process thereof. In the present second modification, between the first semiconductor wafer and the second semiconductor wafer, a film which reflects light at a shorter wavelength and transmits light at a longer wavelength is formed.

The solid-state imaging element in the present second modification shown in FIG. 26 is different from the solid-state imaging element shown in FIG. 22 in that, between the insulating films IF2 and IF3, not the insulating film IF4 (see FIG. 22) having the negative fixed charge, but a reflection film RF1 made of, e.g., silicon or silicon nitride is formed. The structure of the solid-state imaging element in the present second modification is otherwise the same as that of the solid-state imaging element shown in FIG. 22.

As shown in FIG. 27, such a solid-state imaging element can be manufactured by forming, not the insulating film IF4 having the negative fixed charge, but the reflection film RF1 made of, e.g., silicon or silicon nitride in the step described using FIG. 23. The reflection film RF1 can be formed by, e.g., a CVD method. That is, in the step shown in FIG. 27, the insulating film IF2, the reflection film RF1, and the insulating film IF5 are formed in this order over the semiconductor substrate SB1, while the insulating film IF3 is formed over the semiconductor substrate SB2. Then, the first semiconductor wafer and the second semiconductor wafer are joined together. In this case, the insulating film IF3 shown in FIG. 26 is formed thicker than the insulating film IF2.

However, it may also be possible to form respective reflection films over the semiconductor substrates SB1 and SB2 via insulating films and then join the reflection films to each other. In that case, in the manufacturing process of the solid-state imaging element, the steps described using FIGS. 5 to 8 are performed first. Then, as shown in FIG. 28, the insulating film IF2 and a reflection film RF2 are formed in this order over the semiconductor substrate SB1, while the insulating film IF3 and a reflection film RF3 are formed in this order over the semiconductor substrate SB2.

Then, the same steps as the steps described using FIGS. 10 to 12 are performed to generally complete the solid-state imaging element shown in FIG. 26. That is, in the present second modification, the reflection film RF2 exposed at the back surface of the first semiconductor wafer and the reflection film RF3 exposed at the back surface of the second semiconductor wafer are joined together to form a multi-layer wafer. The reflection film RF2 and the reflection film RF3 are integrated herein with each other to form the reflection film RF1. That is, the reflection film RF1 has a multi-layer structure including the two films.

In the present second modification, the same effect as obtained from the foregoing first embodiment can be obtained.

The reflection film RF1 reflects light at a shorter wavelength to be detected by the photodiode PD1 over the reflection film RF1 and transmits light at a longer wavelength to be detected by the photodiode PD2 under the reflection film RF1. A portion of the light at a shorter wavelength, which is included in the light that has passed through the microlens ML from over the semiconductor substrate SB1 and illuminated the semiconductor substrate SB1, is photoelectrically converted by the photodiode PD1. On the other hand, another portion of the light at the shorter wavelength passes through the photodiode PD1 to reach the insulating film IF2. The light at the shorter wavelength that has reached the insulating film IF2 is reflected at the boundary between the insulating film IF2 and the insulating film IF4 toward the photodiode PD1 and photoelectrically converted by the photodiode PD1. Accordingly, it is possible to improve sensitivity in the photodiode PD1.

On the other hand, the light at a longer wavelength, which is included in the light that has passed through the microlens ML from over the semiconductor substrate SB1 and illuminated the semiconductor substrate SB1, passes through the reflection film RF1, reaches the photodiode PD2, and is photoelectrically converted by the photodiode PD2. Therefore, it is possible to prevent sensitivity in the photodiode PD2 from deteriorating due to the formation of the reflection film RF1. In addition, the photoelectric conversion of the light at the shorter wavelength in the photodiode PD2 allows an improvement in color separation performance.

Note that the insulating films IF2 and IF3 shown in FIG. 26 need not necessarily be formed. In addition, the photoelectric conversion film PC (see FIG. 14) described in the second modification of the foregoing first embodiment may also be applied to the present second modification of the second embodiment.

### Third Modification of Second Embodiment

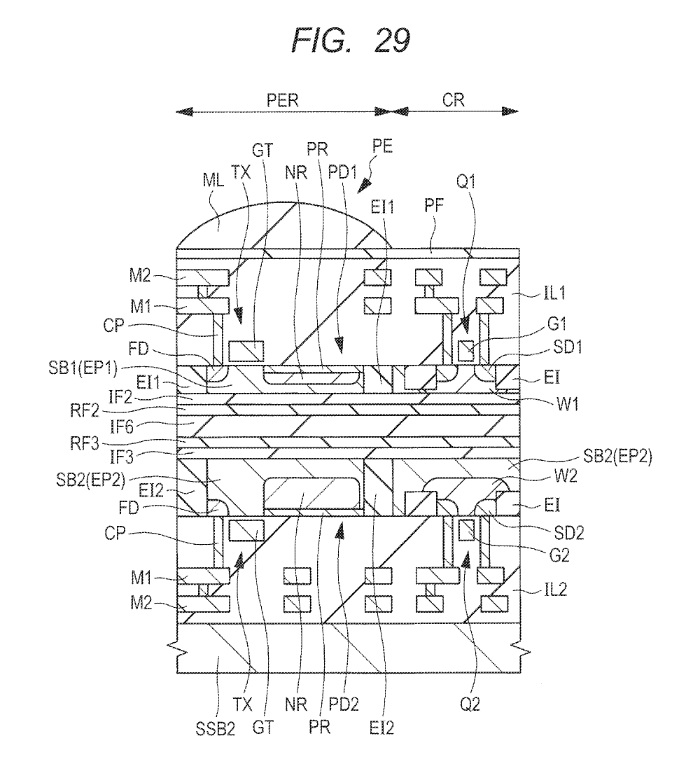

Using FIG. 29, a description will be given of a structure of a solid-state imaging element in a third modification of the present second embodiment. Also, using FIG. 30, a description will be given of a method of manufacturing the solid-state imaging element in the third modification of the present second embodiment. FIG. 29 is a cross-sectional view showing the solid-state imaging element in the present third modification. FIG. 30 is a cross-sectional view of the solid-state imaging element in the present third modification during the manufacturing process thereof. In the present third modification, between the first semiconductor wafer and the second semiconductor wafer, films each of which reflects light at a shorter wavelength and transmits light at a longer wavelength are formed in two stacked layers.

The solid-state imaging element in the present third modification shown in FIG. 29 is different from the solid-state imaging element shown in FIG. 24 in that, between the insulating films IF2 and IF3, not the insulating films IF4 and IF7 (see FIG. 24) each having the negative fixed charge, but the reflection films RF2 and RF3 made of, e.g., silicon or silicon nitride are formed. The structure of the solid-state imaging element in the present third modification is otherwise the same as that of the solid-state imaging element shown in FIG. 24. That is, over the semiconductor substrate SB2, the insulating film IF3, the reflection film RF3, the insulating film IF6, the reflection film RF2, the insulating film IF2, and the semiconductor substrate SB1 are disposed in this order.

As shown in FIG. 30, such a solid-state imaging element can be manufactured by forming, not the insulating films IF4 and IF7 each having the negative fixed charge, but the reflection films RF2 and RF3 each made of, e.g., silicon or silicon nitride in the step described in FIG. 25. The reflection films RF2 and RF3 can be formed by, e.g., a CVD method. That is, in the step shown in FIG. 30, the insulating film IF2, the reflection film RF2, and the insulating film IF6 are formed in this order over the semiconductor substrate SB1, while the insulating film IF3, the reflection film RF3, and the insulating film IF8 are formed over the semiconductor substrate SB2. Then, the first semiconductor wafer and the second semiconductor wafer are joined together. In this case, the insulating film IF6 shown in FIG. 29 is formed thicker than each of the insulating films IF2 and IF3.

Each of the reflection films RF2 and RF3 reflects light at a shorter wavelength to be detected by the photodiode PD1 over the reflection films RF2 and RF3 and transmits light at a longer wavelength to be detected by the photodiode PD2 under the reflection films RF2 and RF3. In the present third modification, when light is incident on the solid-state imaging element, the light at the shorter wavelength can be reflected at each of the boundary between the insulating film IF2 and the reflection film RF2 and the boundary between the insulating film IF6 and the reflection film RF3. This allows the effects of the foregoing second modification of the present second embodiment to be more remarkably obtained.

In addition, by forming the plurality of reflection films, a multi-layer film having optimum reflection performance and an optimum transmission property for the wavelength light to be detected can be formed between the first semiconductor substrate and the second semiconductor substrate. That is, the characteristics of the solid-state imaging element are easily adjusted.

Note that the photoelectric conversion film PC (see FIG. 14) described in the second modification of the foregoing first embodiment may also be applied to the present third modification.

### Third Embodiment

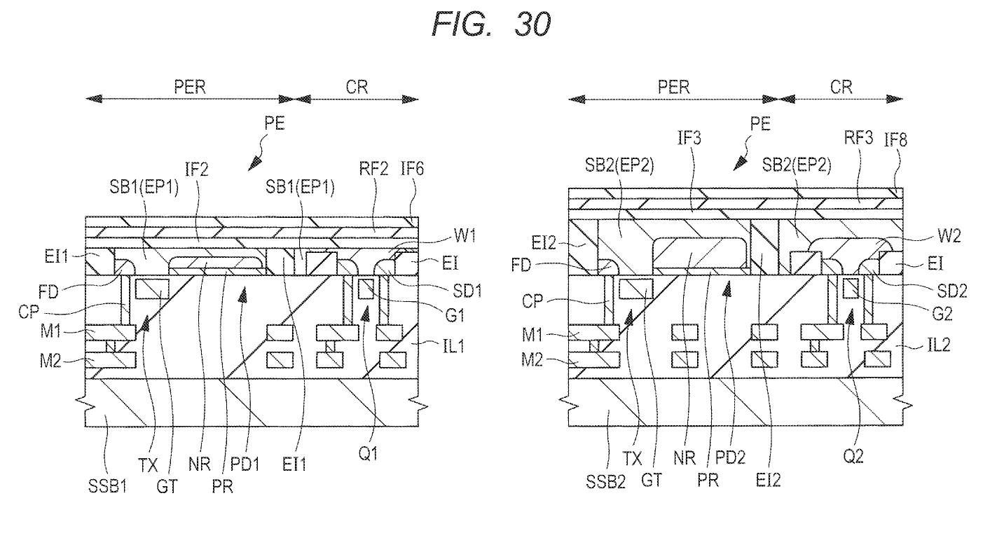

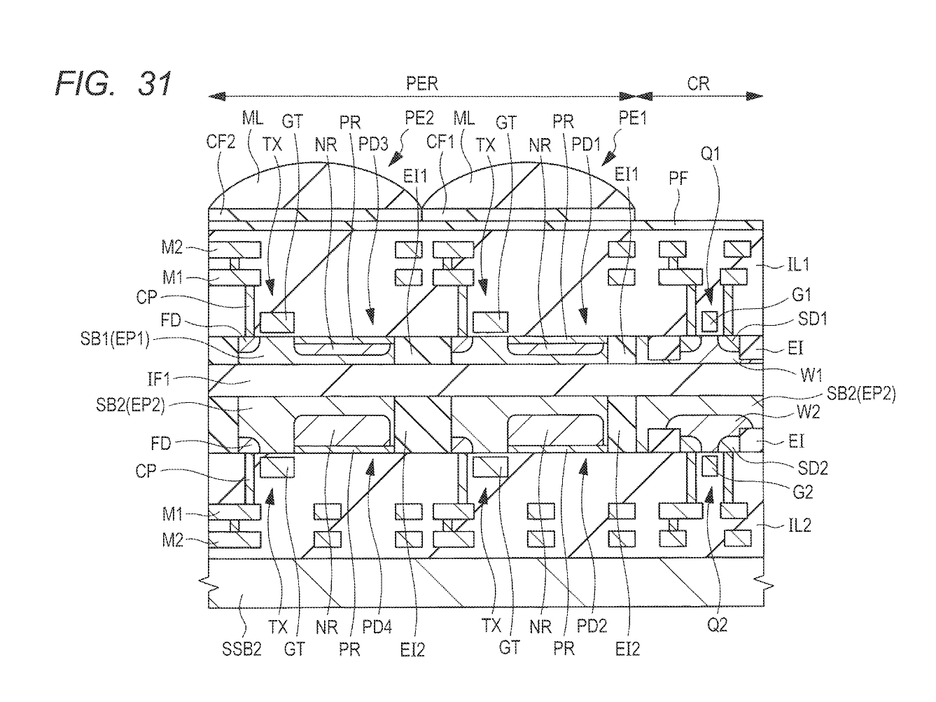

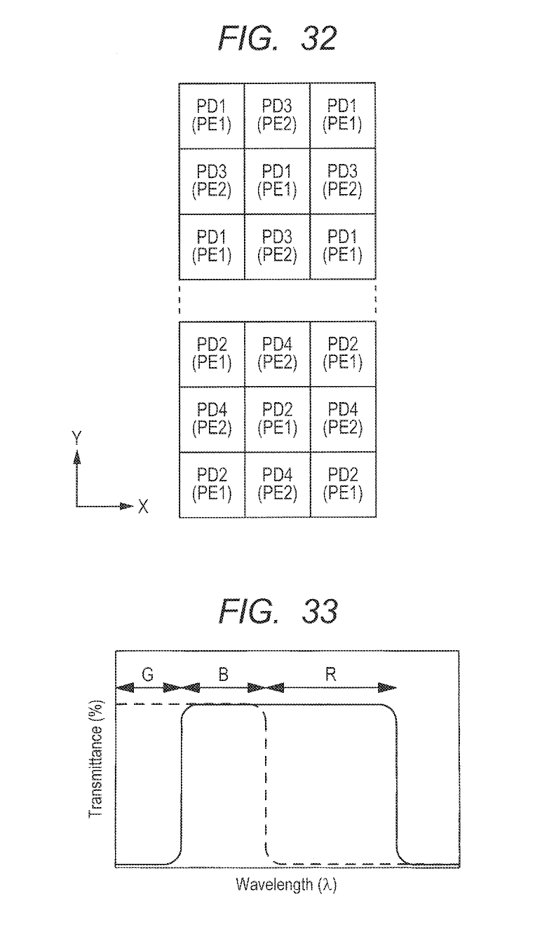

Using FIGS. 31 and 32, the following will describe a structure of a solid-state imaging element in the present third embodiment. FIG. 31 is a cross-sectional view showing the solid-state imaging element in the present third embodiment. In FIG. 31, two pixels PE1 and PE2 adjacent to each other in the pixel array region PER and the peripheral circuit region CR are shown. FIG. 32 is a plan view showing the solid-state imaging element in the present third embodiment. In FIG. 32, a two-dimensional layout of the upper-layer photodiodes in nine pixels arranged in the form of an array and a two-dimensional layout of the lower-layer photodiodes in the nine pixels arranged in the form of an array are shown side by side. In the description given herein, in a multi-layer image sensor in which the first semiconductor wafer and the second semiconductor wafer are stacked, light at four wavelengths is detected using two adjacent pixels.

As shown in FIG. 31, the solid-state imaging element in the present third embodiment has the same structure as that of the solid-state imaging element in the foregoing first embodiment except that, between the passivation film PF and the microlens ML, a color filter CF1 or CF2 is formed. The pixels PE1 and PE2 are disposed adjacent to each other. Immediately below the microlens ML of the pixel PE1, the color filter CF1 is formed while, immediately below the microlens ML of the pixel PE2, the color filter CF2 is formed.

The pixel PE1 includes the photodiode PD1 and the photodiode PD2 under the photodiode PD1. The pixel PE2 includes a photodiode PD3 and a photodiode PD4 under the photodiode PD3. The photodiodes PD1 and PD2 and the color filter CF1 overlap each other in plan view. The photodiodes PD3 and PD4 and the color filter CF2 overlap each other in plan view.

As shown in FIG. 32, in the pixel region PER (see FIG. 1 and FIG. 31), the pixels PE1 and the pixels PE2 are alternately arranged in the X-direction and the Y-direction. In FIG. 32, the arrangement of the upper photodiodes PD1 and PD3 formed in the semiconductor substrate SB1 (see FIG. 31) is shown in the upper part, while the arrangement of the lower photodiodes PD2 and PD4 formed in the semiconductor substrate SB2 (see FIG. 31) is shown in the lower part. That is, the nine pixels PE1 and PE2 shown in the upper part of FIG. 32 and the nine pixels PE1 and PE2 shown in the lower part of FIG. 32 actually overlap each other in plan view. The photodiodes PD1 and PD3 are alternately arranged in the X-direction and the Y-direction, while the photodiodes PD2 and PD4 are alternately arranged in the X-direction and the Y-direction.

In the present third embodiment, the same effects as obtained from the foregoing first embodiment can be obtained.

Each of the photodiodes PD2 is a light receiving portion which photoelectrically converts red light. Each of the photodiodes PD1 and PD4 is a light receiving portion which photoelectrically converts green light. Each of the photodiodes PD3 is a light receiving portion which photoelectrically converts blue light. Of the green light, light at a longer wavelength is detected by the photodiode PD1 and light at a shorter wavelength is detected by the photodiode PD3. That is, the photodiodes PD3, PD4, PD1, and PD2 receive light at wavelengths which are progressively longer in this order. Specifically, the photodiode PD3 detects light in a shortest wavelength region which is included in visible light, while the photodiode PD2 detects light in a longest wavelength region which is included in the visible light.

Such color separation performance can be implemented by forming the color filters CF1 and CF2 having different transmittances in the pixels PE1 and PE2 shown in FIG. 31. In FIG. 33, the relationships between the wavelength (abscissa axis) of light and the transmittances (ordinate axis) of the color filters CF1 and CF2 are represented by graphs. In FIG. 33, the graph representing the transmittance of the color filter CF1 is shown by the solid line, while the graph representing the transmittance of the color filter CF2 is shown by the broken line.

As shown in FIG. 33, the color filter CF2 is made of a material which transmits light in a blue wavelength region B and light in a green wavelength region G, but does not transmit light in a red wavelength region R. The color filter CF1 is made of a material which does not transmit the light in the blue wavelength region B, but transmits the light in the green wavelength region G and the light in the red wavelength region R. In other words, in the color filter CF2, the transmittances of the light in the blue wavelength region B and the light in the green wavelength region G are higher than the transmittance of the light in the red wavelength region R. On the other hand, in the color filter CF1, the transmittances of the light in the red wavelength region R and the light in the green wavelength region G are higher than the transmittance of the light in the blue wavelength region B.

Accordingly, immediately below the color filter CF2 shown in FIG. 31, the photodiode PD3 can detect blue light, while the photodiode PD4 can detect green light. Also, immediately below the color filter CF1 shown in FIG. 31, the photodiode PD1 can detect green light, while the photodiode PD2 can detect red light. That is, the color filter CF1 transmits light at a wavelength longer than that of the light transmitted by the color filter CF2. Each of the color filters CF1 and CF2 is made of, e.g., an organic film and made of, e.g., a photosensitive material containing a pigment.

In a solid-state imaging element not having stacked photodiodes but including only one photodiode in each of pixels, a portion (Bayer arrangement) which individually photoelectrically converts each of red light, green light in a longer wavelength region, green light in a shorter wavelength region, and blue light needs to be formed of four pixels arranged in plan view, resulting in the problem of degradation of the sensitivity performance of the solid-state imaging element. By contrast, in the present third embodiment, the color filters CF1 and CF2 which transmit light at different wavelengths are provided respectively in the pair of adjacent pixels PE1 and PE2 to allow the pair of pixels PE1 and PE2 to detect each of red visible light, blue visible light, and green visible light. Consequently, it is possible to increase the light reception area of each of the pixels in plan view and thus improve the sensitivity performance of the solid-state imaging element.

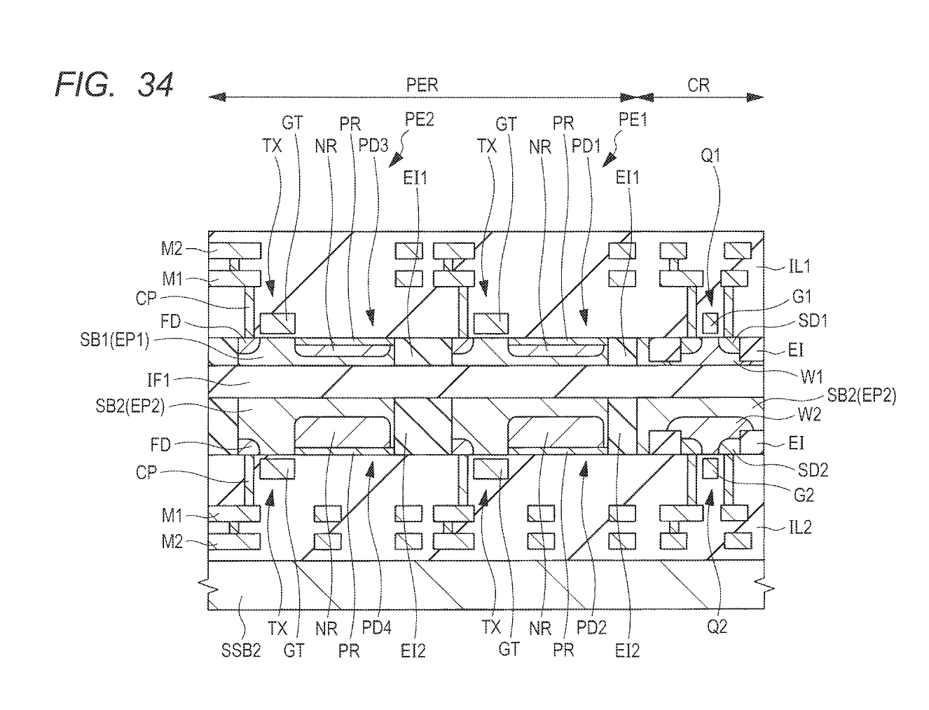

Using FIG. 34, the following will describe a method of manufacturing the solid-state imaging element in the present third embodiment. FIG. 34 is a cross-sectional view of the solid-state imaging element in the present third embodiment during the manufacturing process thereof. FIG. 34 shows the area of the pixel region PER where the two pixels are formed and the peripheral circuit region CR. FIG. 34 is a cross-sectional view during the step corresponding to the step described using FIG. 11. The method of manufacturing the solid-state imaging element in the present third embodiment is the same as in the foregoing first embodiment except that the color filters are formed.

First, the steps described using FIGS. 5 to 11 are performed herein. That is, the first semiconductor wafer including the photodiodes PD1 and PD3 adjacent to each other in the lateral direction and the second semiconductor wafer including the photodiodes PD2 and PD4 adjacent to each other in the lateral direction are provided, and the respective back surfaces of the wafers are joined together. Then, the supporting substrate SSB1 (see FIG. 10) is removed to allow the structure shown in FIG. 34 to be obtained. In the upper-layer semiconductor substrate SB1 of the pixel PE1, the photodiode PD1 is formed while, in the lower-layer semiconductor substrate SB2 of the pixel PE1, the photodiode PD2 is formed. Also, in the upper-layer semiconductor substrate SB1 of the pixel PE2, the photodiode PD3 is formed while, in the lower-layer semiconductor substrate SB2 of the pixel PE2, the photodiode PD4 is formed.

In the same manner as in the step described using FIG. 12, the through via TSV (not shown), the pad PD (not shown), and the passivation film PF are formed. Subsequently, immediately above the photodiodes PD1 and PD2 of the pixel PE1, the color filter CF1 is formed over the passivation film PF. Subsequently, immediately above the photodiodes PD3 and PD4 of the pixel PE2, the color filter CF2 is formed over the passivation film PF. Each of the color filters CF1 and CF2 is a pattern made of, e.g., an organic film.

Subsequently, immediately above the color filter CF1 of the pixel PE1 and immediately above the color filter DF2 of the pixel PE2, the respective microlenses ML are formed. Then, a multi-layer wafer including the first semiconductor wafer and the second semiconductor wafer is cut by dicing to be singulated. In this manner, the solid-state imaging element shown in FIG. 31 is obtained. By the foregoing process, the solid-state imaging element in the present third embodiment is generally completed.

Note that the photoelectric conversion film PC (see FIG. 14) described in the second modification of the foregoing first embodiment may also be applied to the present third embodiment.

### First Modification of Third Embodiment

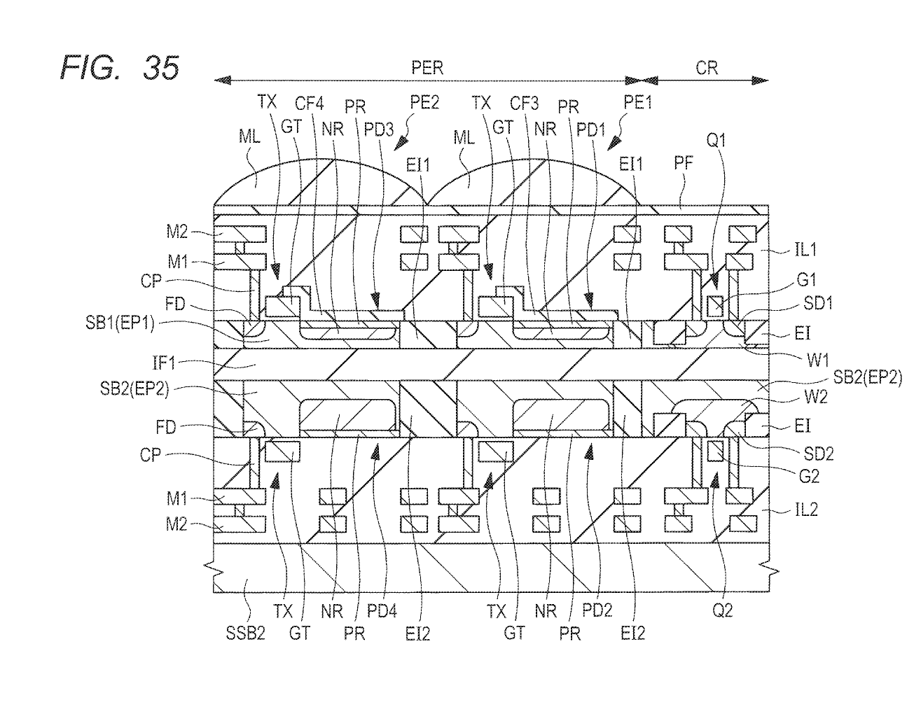

Using FIG. 35, the following will describe a structure of a solid-state imaging element in a first modification of the present third embodiment. FIG. 35 is a cross-sectional view showing the solid-state imaging element in the present first modification. In the description given herein, the color filters are formed not between the upper-layer wiring layers and the microlenses, but between the upper-layer photodiodes and the upper-layer wiring layers.

As shown in FIG. 35, the solid-state imaging element in the present first modification has the same structure as that of the solid-state imaging element shown in FIG. 31 except that no color filter is provided over the passivation film PF, but color filter CF3 and CF4 are formed between the semiconductor substrate SB1 and the interlayer insulating film IL1. That is, immediately above the photodiode PD1, the color filter CF3 covering the upper surface of the photodiode PD1 is formed under the interlayer insulating film IL1. Also, immediately above the photodiode PD3, the color filter CF4 covering the upper surface of the photodiode PD3 is formed under the interlayer insulating film IL1. The color filter CF3 is a film which, e.g., transmits light in the red and green wavelength regions and blocks blue light. The color filter CF4 is a film which, e.g., transmits blue light and green light and blocks red light.

Each of the color filters CF3 and CF4 is made of a film in which, e.g., over the semiconductor substrate SB1 and the gate electrode GT, a silicon oxide film, a silicon nitride film, a silicon oxide film, and a silicon nitride film are stacked in this order. That is, each of the color filters CF3 and CF4 is made of a multi-layer film including the silicon oxide films and the silicon nitride films. Each of the color filters CF3 and FG4 is a film which allows the wavelength region of the light transmitted thereby to be adjusted by changing the ratio between the silicon oxide films and the silicon nitride films.

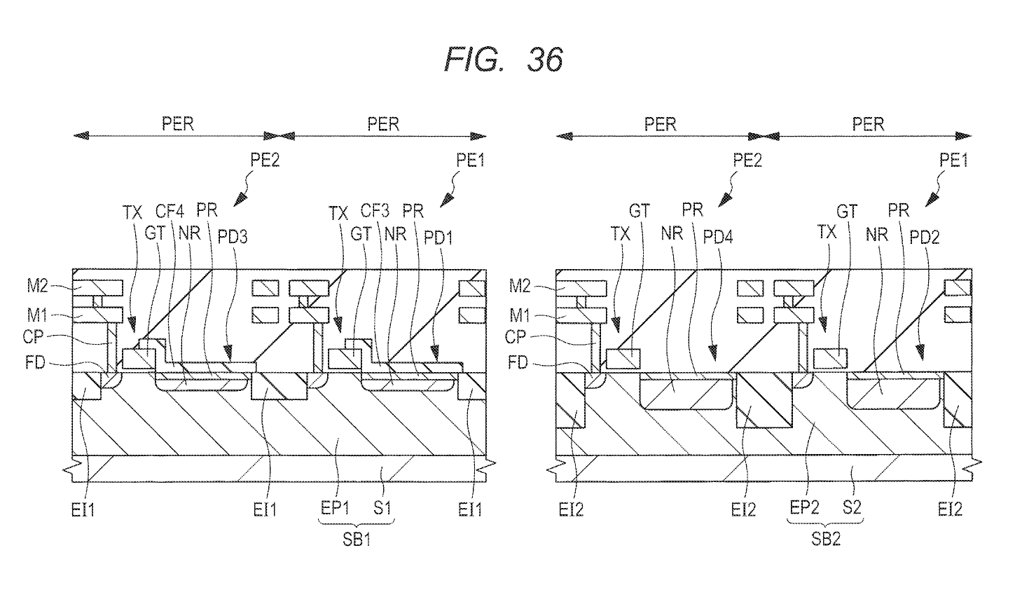

In the manufacturing process of such a solid-state imaging element, as shown in FIG. 36, the photodiodes PD1 and PD3, the transistor Q1 (see FIG. 6), and the transfer transistor TX are formed in the vicinity of the upper surface of the semiconductor substrate SB1, in the same manner as in the step described using FIG. 6. FIG. 36 is a cross-sectional view of the solid-state imaging element in the present first modification during the manufacturing process thereof. Note that, in FIG. 36, the illustration of the peripheral circuit region CR is omitted.

Then, the color filter CF3 covering the photodiode PD1 and the color filter CF4 covering the photodiode PD3 are formed. Subsequently, over the semiconductor substrate SB1, wiring layers are formed. That is, e.g., in the pixel PE1, the multi-layer film including the silicon oxide films and the silicon nitride films which are alternately stacked over each of the photodiode PD1 and the gate electrode GT is formed and then processed to form the color filter CF3 made of the multi-layer film. Subsequently, in the pixel PE2, the multi-layer film including the silicon oxide films and the silicon nitride films which are alternately stacked over each of the photodiode PD3 and the gate electrode GT is formed and then processed to form the color filter CF4 made of the multi-layer film. Then, over each of the first main surface of the semiconductor substrate SB1 and the color filters CF3 and CF4, the wiring layers including the interlayer insulating film IL1 are formed. Thus, the structure shown in FIG. 36 is obtained.

Next, the same steps as the steps described using FIGS. 7 to 12 are performed to generally complete the solid-state imaging element in the present first modification shown in FIG. 35.

In the same manner as in the solid-state imaging element described using FIG. 31, in the present first modification, the photodiode PD2 detects red light, the photodiode PD1 detects green light at a relatively long wavelength, the photodiode PD4 detects green light at a relatively short wavelength, and the photodiode PD3 detects blue light. In the present first modification, the same effects as obtained from the solid-state imaging element and the manufacturing method thereof which are described using FIGS. 31 to 34 can be obtained.

Each of the color filters CF3 and CF4 has resistance to heat higher than that of each of the color filters CF1 and CF2 shown in FIG. 31. Accordingly, when the solid-state imaging element in the present first modification is used in a high-temperature environment, it is possible to prevent the color filters CF3 and CF4 from deteriorating.

### Second Modification of Third Embodiment

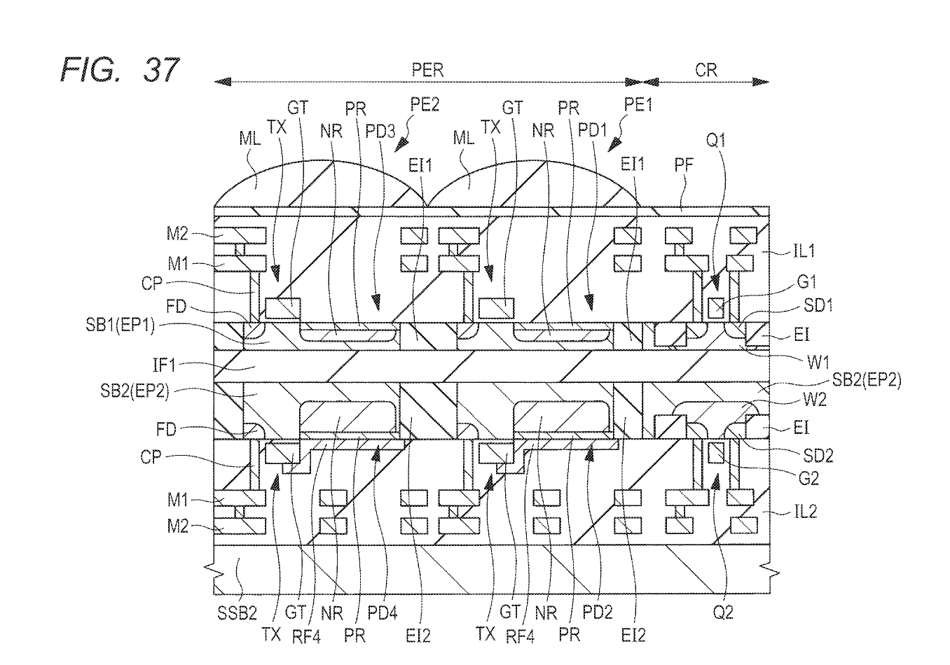

Using FIG. 37, the following will describe a structure of a solid-state imaging element in a second modification of the present third embodiment. FIG. 37 is a cross-sectional view showing the solid-state imaging element in the present second modification. In the description given herein, the color filters described using FIG. 31 are provided, and reflection films are further formed under the lower-layer photodiodes.

As shown in FIG. 37, between the lower-layer semiconductor substrate SB2 and the interlayer insulating film IL2 under the semiconductor substrate SB2, reflection films RF4 each made of, e.g., a W (tungsten) film or the like are formed. The respective reflection films RF4 of the pixels PE1 and PE2 cover the respective lower surfaces of the photodiodes PD2 and PD4, i.e., the second main surface of the semiconductor substrate SB2 and cover respective portions of the lower surfaces of the gate electrodes GT under the semiconductor substrate SB2. The reflection films RF4 are formed above the interlayer insulating film IL2 and the wires M1 and M2 in the interlayer insulating film IL2.

Each of the reflection films RF4 is a conductive film in a floating state which is not electrically coupled to the photodiode PD2, the gate electrode GT, or the like. The reflection film RF4 reflects the light in the wavelength region which is photoelectrically converted by the photodiode PD1 and the light in the wavelength region which is photoelectrically converted by the photodiode PD2.

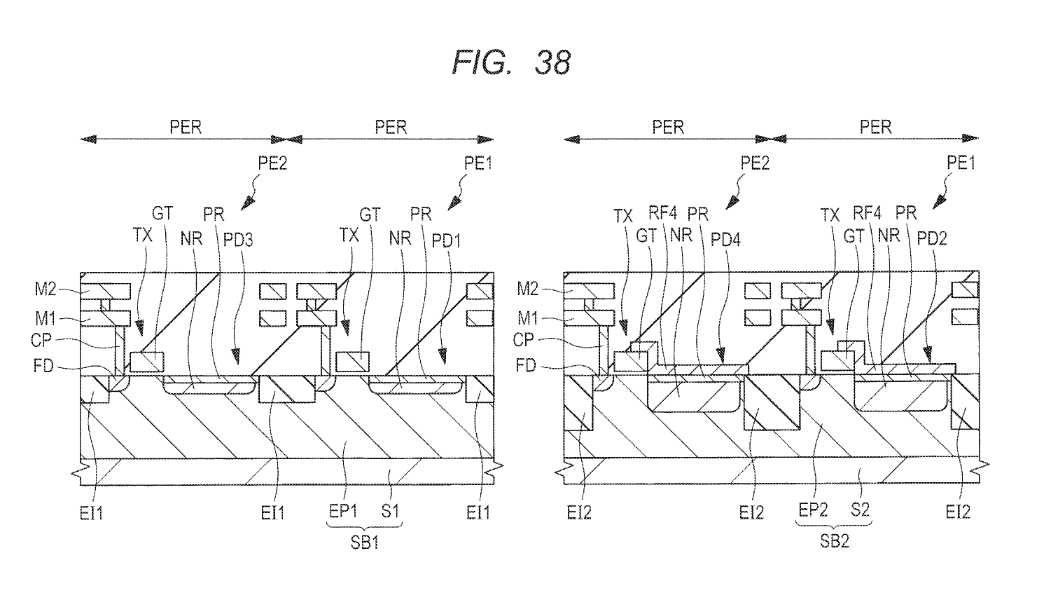

In the manufacturing process of such a solid-state imaging element, as shown in FIG. 38, the photodiodes PD2 and PD4, the transistor Q2 (see FIG. 6), and the transfer transistor TX are formed in the vicinity of the upper surface of the semiconductor substrate SB2, in the same manner as in the step described using FIG. 6. FIG. 38 is a cross-sectional view of the solid-state imaging element in the present second modification during the manufacturing process thereof. Note that, in FIG. 38, the illustration of the peripheral circuit region CR is omitted.

Then, the respective reflection films RF4 covering the photodiodes PD2 and PD4 are formed by, e.g., a sputtering method and, subsequently, wiring layers are formed over the semiconductor substrate SB2. That is, e.g., a tungsten film is formed to cover the photodiodes PD2 and PD4 and the gate electrodes GT and then processed to form the respective reflection films RF4 in the pixels PE1 and PE2. Then, over the second main surface of the semiconductor substrate SB2 and the reflection films RF4, wiring layers including the interlayer insulating film IL2 are formed. Thus, the structure shown in FIG. 38 is obtained.

Next, the same steps as the steps described using FIGS. 7 to 11 and 34 are performed to generally complete the solid-state imaging element in the present second modification shown in FIG. 37.

In the same manner as in the solid-state imaging element described using FIG. 31, in the present second modification, the photodiode PD2 detects red light, the photodiode PD1 detects green light at a relatively long wavelength, the photodiode PD4 detects green light at a relatively short wavelength, and the photodiode PD3 detects blue light.

In the present second modification, the same effects as obtained from the solid-state imaging element and the manufacturing method thereof which are described using FIGS. 31 to 34 can be obtained. In the present second modification, the reflection films RF4 are further formed to reflect the light emitted from over the solid-state imaging element via the microlenses ML and transmitted by the photodiodes PD1 and PD4. By collecting the reflected light using each of the photodiodes, it is possible to improve the sensitivity performance of the solid-state imaging element.

Note that it may also be possible form the reflection films RF4 in the present second modification in the solid-state imaging element in the first modification shown in FIG. 35 without providing the color filters CF1 and CF2 shown in FIG. 37.

### Third Modification of Third Embodiment

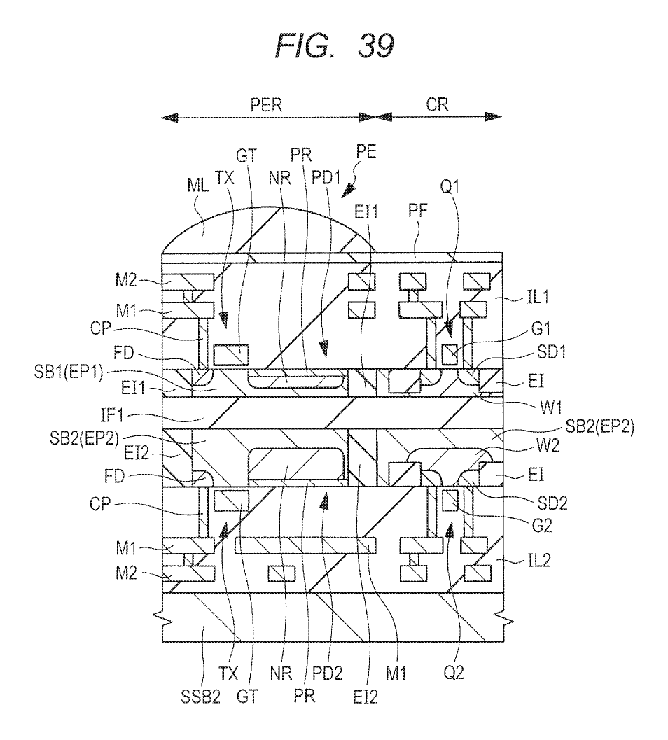

Using FIG. 39, the following will describe a structure of a solid-state imaging element in a third modification of the present third embodiment. FIG. 39 is a cross-sectional view showing the solid-state imaging element in the present third modification. In the description given herein, the wire of the second semiconductor wafer is used as a reflection film.

As shown in FIG. 39, the structure of the solid-state imaging element in the present third modification is the same as the structure of the solid-state imaging element shown in FIG. 31 except for the layout of the wires in the interlayer insulating film IL2. In the third modification, the wire M1 immediately below the photodiode PD2 is formed laterally wider so as to overlap the entire photodiode PD2 in plan view. In other words, the entire lower surface of the photodiode PD2 overlaps the wire M1 in plan view. Note that, in the interlayer insulating film IL2, not the wire M1, but the wire M2 may also be formed so as to overlap the photodiode PD2. The wires M1 and M2 are films which reflect the light in the wavelength region which is photoelectrically converted by the photodiode PD1 and the light in the wavelength region which is photoelectrically converted by the photodiode PD2.

In the present third modification, the wire M1 or M2 under the photodiode PD2 is used as the reflection film to allow an improvement in the sensitivity performance of the solid-state imaging element.

### Fourth Modification of Third Embodiment

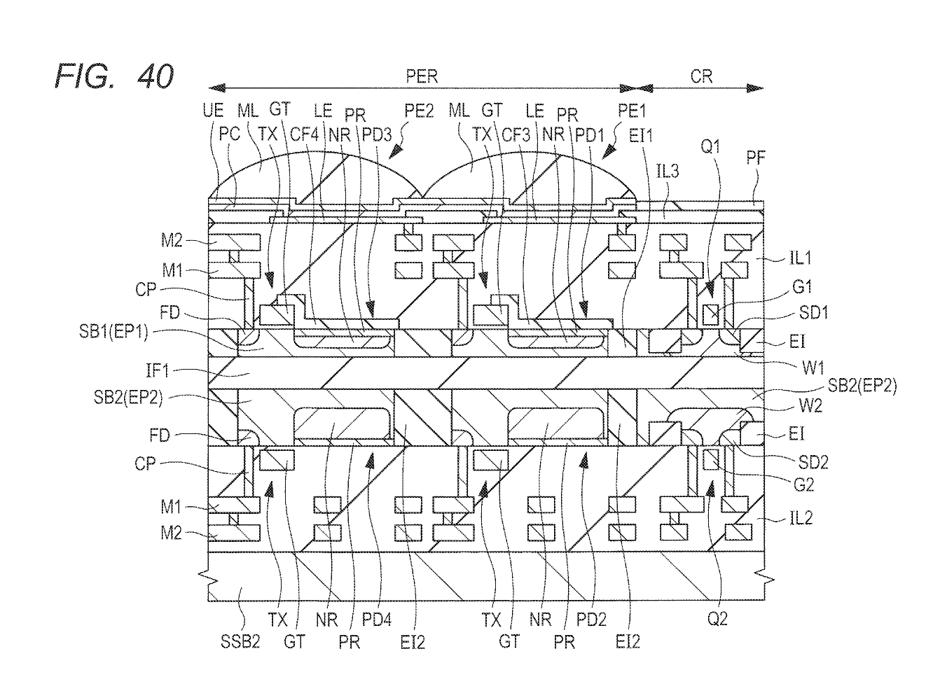

Using FIG. 40, the following will describe a structure of a solid-state imaging element in a fourth modification of the present third embodiment. FIG. 40 is a cross-sectional view showing the solid-state imaging element in the present fourth modification. In the structure described herein, the second modification of the foregoing first embodiment and the second modification of the present third embodiment are combined with each other.

As shown in FIG. 40, the solid-state imaging element in the present fourth modification includes the color filters CF3 and CF4 covering the respective upper portions of the photodiodes PD1 and PD3. Each of the color filters CF3 and CF4 has the same configuration as that described using FIG. 35. The solid-state imaging element in the present fourth modification includes the lower electrode LE, the photoelectric conversion film PC, and the upper electrode UE each described in the second modification of the foregoing first embodiment.

In the same manner as in the slid-state imaging element described using FIG. 35, the photodiode PD2 detects red light, the photodiode PD1 detects green light in a longer wavelength region, the photodiode PD4 detects green light in a shorter wavelength region, and the photodiode PD3 detects blue light. In addition, in the present fourth modification, the photoelectric conversion film PC as the photoelectric conversion portion (light receiving element) is provided in each of the pixels PE1 and PE2. The lower electrode LE, the photoelectric conversion film PC, and the upper electrode UE of each of the pixels PE1 and PE2 are integrated with each other and electrically coupled to each other. In the present fourth modification, the photoelectric conversion film PC detects light in wavelength regions other than red, blue, and green wavelength regions through photoelectric conversion. For example, the photoelectric conversion film PC detects light having a wavelength longer than that of red light such as infrared light.

In the present fourth modification, the large number of photoelectric conversion portions are formed to allow the wavelength region of the light to be photoelectrically converted to be further widened. In addition, it is also possible to divide the wavelength region of detected light into smaller regions.

While the invention achieved by the present inventors has been specifically described heretofore on the basis of the embodiments thereof, the present invention is not limited to the foregoing embodiments. It will be appreciated that various changes and modifications can be made in the invention within the scope not departing from the gist thereof.

The following is provided as additional description of parts of the content of the description of the foregoing embodiments.

(Note 1)

A solid-state imaging element, including:

a plurality of pixels arranged in plan view;

a first semiconductor substrate and a second semiconductor substrate which are stacked;

a first insulating film which is interposed between the first semiconductor substrate and the second semiconductor substrate and in contact with a lower surface of the first semiconductor substrate and with an upper surface of the second semiconductor substrate;

a first light receiving element which is formed in the first semiconductor substrate in each of the pixels;

a second light receiving element which is formed in the second semiconductor substrate in each of the pixels;

a first isolation region which extends through the first semiconductor substrate from an upper surface thereof to the lower surface thereof to isolate the respective first light receiving elements formed in the pixels adjacent to each other; and

a second isolation region which extends through the second semiconductor substrate from the upper surface thereof to a lower surface thereof to isolate the respective second light receiving elements formed in the pixels adjacent to each other.

(Note 2)

The solid-state imaging element according to (Note 1), further including:

a third isolation region formed in the upper surface of the first semiconductor substrate to be spaced apart from the first insulating film; and

a fourth isolation region formed in the lower surface of the second semiconductor substrate to be spaced apart from the first insulating film.

(Note 3)

The solid-state imaging element according to (Note 1),

in which the second light receiving element photoelectrically converts light at a wavelength longer than that of light photoelectrically converted by the first light receiving element.

(Note 4)

The solid-state imaging element according to (Note 1), in which the first insulating film includes a third insulating film, a fourth insulating film having negative charge, a sixth insulating film, a seventh insulating film having negative charge, and a second insulating film which are formed in this order over the second semiconductor substrate, and

in which a thickness of the sixth insulating film is larger than each of respective thicknesses of the second insulating film and the third insulating film.

(Note 5)

The solid-state imaging element according to (Note 1), further including:

a second reflection film formed immediately below the second light receiving element to reflect light in a first wavelength region which is photoelectrically converted by the first light receiving element and light in a second wavelength region which is photoelectrically converted by the second light receiving element.

(Note 6)

A method of manufacturing a solid-state imaging element including a plurality of pixels arranged in plan view, the method including the steps of:

(a) providing a first semiconductor substrate having a first main surface and a first back surface opposite to the first main surface and including a plurality of first light receiving elements formed in the first main surface and a first isolation region formed in the first main surface to isolate the first light receiving elements from each other;

(b) providing a second semiconductor substrate having a second main surface and a second back surface opposite to the second main surface and including a plurality of second light receiving elements formed in the second main surface and a second isolation region formed in the second main surface to isolate the second light receiving elements from each other;

(c) polishing the first back surface of the first semiconductor substrate to expose the first isolation region;

(d) polishing the second back surface of the second semiconductor substrate to expose the second isolation region;

(e) after the step (c), forming a second insulating film which is in contact with the first back surface of the first semiconductor substrate and with the first isolation region and covers the first back surface;

(f) after the step (d), forming a third insulating film which is in contact with the second back surface of the second semiconductor substrate and with the second isolation region and covers the second back surface; and

(g) causing the first back surface and the second back surface to face each other and joining together the first semiconductor substrate and the second semiconductor substrate to form a first insulating film including the second insulating film and the third insulating film,

in which each of the pixels includes the second light receiving element and the first light receiving element over the second light receiving element.

(Note 7)

The method of manufacturing the solid-state imaging element according to (Note 6),

in which, in the step (a), the first semiconductor substrate including a first substrate, a ninth insulating film over the first substrate, and a first semiconductor layer over the ninth insulating film and including the first light receiving elements formed in the first main surface as an upper surface of the first semiconductor layer and the first isolation region extending through the first semiconductor substrate from the first main surface to a lower surface of the first semiconductor layer is provided,

in which, in the step (b), the second semiconductor substrate including a second substrate, a tenth insulating film over the second substrate, and a second semiconductor layer over the tenth insulating film and including the second light receiving elements formed in the second main surface as an upper surface of the second semiconductor layer and the second isolation region extending through the second semiconductor substrate from the second main surface to a lower surface of the second semiconductor layer is provided,

in which, in the step (c), the first back surface of the first semiconductor substrate is polished to remove the first substrate, and then the ninth insulating film is removed to expose the first isolation region, and

in which, in the step (d), the second back surface of the second semiconductor substrate is polished to remove the second substrate, and then the tenth insulating film is removed to expose the second isolation region.

(Note 8)

The method of manufacturing the solid-state imaging element according to (Note 6), further including the steps of:

(g3) before the step (g), forming a fourth insulating film having negative charge and a sixth insulating film in this order so as to cover an exposed lower surface of the second insulating film; and

(g4) before the step (g), forming a seventh insulating film having negative charge and an eighth insulating film in this order so as to cover an exposed lower surface of the third insulating film,

in which, in the step (g), the first semiconductor substrate and the second semiconductor substrate are joined together to form the first insulating film including the second insulating film, the third insulating film, the fourth insulating film, the sixth insulating film, the seventh insulating film, and the eighth insulating film.

What is claimed is:

1. A solid-state imaging element, comprising:
a plurality of pixels arranged in plan view;
a first semiconductor substrate and a second semiconductor substrate which are stacked;
a first insulating film which is interposed between the first semiconductor substrate and the second semiconductor substrate and in contact with a lower surface of the first semiconductor substrate and with an upper surface of the second semiconductor substrate;
a first light receiving element which is formed in the first semiconductor substrate in each of the pixels;
a second light receiving element which is formed in the second semiconductor substrate in each of the pixels;
a first isolation region which extends through the first semiconductor substrate from an upper surface thereof to the lower surface thereof to isolate the respective first light receiving elements formed in the pixels adjacent to each other; and
a second isolation region which extends through the second semiconductor substrate from the upper surface thereof to a lower surface thereof to isolate the respective second light receiving elements formed in the pixels adjacent to each other.

2. The solid-state imaging element according to claim 1,
wherein a lower surface of the first isolation region and an upper surface of the second isolation region are in contact with the first insulating film.

3. The solid-state imaging element according to claim 2, further comprising:
a first interlayer insulating film which is formed over the first semiconductor substrate to cover respective upper surfaces of the first light receiving elements;
a plurality of first wires which are formed in the first interlayer insulating film;
a second interlayer insulating film which is formed under the second semiconductor substrate to cover respective lower surfaces of the second light receiving elements; and
a plurality of second wires which are formed in the second interlayer insulating film,
wherein an upper surface of the first isolation region is in contact with the first interlayer insulating film, while a lower surface of the second isolation region is in contact with the second interlayer insulating film.

4. The solid-state imaging element according to claim 1,
wherein respective thicknesses of the first semiconductor substrate and the first isolation region are smaller than each of respective thicknesses of the second semiconductor substrate and the second isolation region.

5. The solid-state imaging element according to claim 1, further comprising:
a third light receiving element including a photoelectric conversion film formed over the first semiconductor substrate in each of the pixels.

6. The solid-state imaging element according to claim 1, wherein the first insulating film includes:
a fourth insulating film having negative charge;
a second insulating film interposed between the fourth insulating film and the first semiconductor substrate; and
a third insulating film interposed between the fourth insulating film and the second semiconductor substrate.

7. The solid-state imaging element according to claim 1,
wherein the first light receiving element photoelectrically converts light in a first wavelength region, while the second light receiving element photoelectrically converts light in a second wavelength region where a wavelength is longer than in the first wavelength region, and
wherein the first insulating film includes:
a first reflection film which reflects the light in the first wavelength region and transmits the light in the second wavelength region;
a second insulating film interposed between the first reflection film and the first semiconductor substrate; and
a third insulating film interposed between the first reflection film and the second semiconductor substrate.

8. The solid-state imaging element according to claim 1,
wherein, among the pixels, the first pixel and the second pixel are adjacent to each other,
wherein the first light receiving element of the first pixel photoelectrically converts light in a first wavelength region,
wherein the second light receiving element of the first pixel photoelectrically converts light in a second wavelength region,
wherein the first light receiving element of the second pixel photoelectrically converts light in a third wavelength region, and
wherein the second light receiving element of the second pixel photoelectrically converts light in a fourth wavelength region,
the solid-state imaging element further comprising:
a first color filter formed over the first light receiving element of the first pixel so as to overlap the first light receiving element and the second light receiving element of the first pixel in plan view; and
a second color filter formed over the first light receiving element of the second pixel so as to overlap the first light receiving element and the second light receiving element of the second pixel in plan view,
wherein, in the first color filter, respective transmittances of the light in the first wavelength region and the light in the second wavelength region are higher than a transmittance of the light in the fourth wavelength region,
wherein, in the second color filter, respective transmittances of the light in the third wavelength region and the light in the fourth wavelength region are higher than the transmittance of the light in the first wavelength region, and
wherein respective wavelengths in the first wavelength region, the second wavelength region, the third wavelength region, and the fourth wavelength region are progressively longer in this order.

9. A method of manufacturing a solid-state imaging element including a plurality of pixels arranged in plan view, the method comprising the steps of:
(a) providing a first semiconductor substrate having a first main surface and a first back surface opposite to the first main surface and including a plurality of first light receiving elements formed in the first main surface and a first isolation region formed in the first main surface to isolate the first light receiving elements from each other;
(b) providing a second semiconductor substrate having a second main surface and a second back surface opposite to the second main surface and including a plurality of second light receiving elements formed in the second main surface and a second isolation region formed in the second main surface to isolate the second light receiving elements from each other;
(c) polishing the first back surface of the first semiconductor substrate to expose the first isolation region;
(d) polishing the second back surface of the second semiconductor substrate to expose the second isolation region;
(e) after the step (c), forming a second insulating film which is in contact with the first back surface of the first semiconductor substrate and with the first isolation region and covers the first back surface;
(f) after the step (d), forming a third insulating film which is in contact with the second back surface of the second semiconductor substrate and with the second isolation region and covers the second back surface; and
(g) causing the first back surface and the second back surface to face each other and joining together the first semiconductor substrate and the second semiconductor substrate to form a first insulating film including the second insulating film and the third insulating film,
wherein each of the pixels includes the second light receiving element and the first light receiving element over the second light receiving element.

10. The method of manufacturing the solid-state imaging element according to claim 9, further comprising the steps of:
(a1) after the step (a) and before the step (c), forming a first interlayer insulating film internally including a first wire and covering respective upper surfaces of the first light receiving elements over the first main surface of the first semiconductor substrate; and
(b1) after the step (b) and before the step (d), forming a second interlayer insulating film internally including a second wire and covering respective upper surfaces of the second light receiving elements over the first main surface of the first semiconductor substrate.

11. The method of manufacturing the solid-state imaging element according to claim 9,
wherein, after the steps (c) and (d), respective thicknesses of the first semiconductor substrate and the first isolation region are smaller than each of respective thicknesses of the second semiconductor substrate and the second isolation region.

12. The method of manufacturing the solid-state imaging element according to claim 10, further comprising the step of:
(h) after the step (g), forming a third light receiving element made of a photoelectric conversion film over the first interlayer insulating film and immediately above each of the first light receiving elements.

13. The method of manufacturing the solid-state imaging element according to claim 9, further comprising the step of:
(g1) before the step (g), forming a fourth insulating film having negative charge and a fifth insulating film in this order so as to cover an exposed lower surface of the second insulating film or an exposed lower surface of the third insulating film,
wherein, in the step (g), the first semiconductor substrate and the second semiconductor substrate are joined together to form the first insulating film including the second insulating film, the third insulating film, the fourth insulating film, and the fifth insulating film.

14. The method of manufacturing the solid-state imaging element according to claim 9,
wherein the first light receiving element photoelectrically converts light in a first wavelength region, while the second light receiving element photoelectrically converts light in a second wavelength region where a wavelength is longer than in the first wavelength region,
the method further comprising the step of:
(g2) before the step (g), forming a first reflection film which reflects the light in the first wavelength region and transmits the light in the second wavelength region and a fifth insulating film in this order so as to cover an exposed lower surface of the second insulating film or an exposed lower surface of the third insulating film,
wherein, in the step (g), the first semiconductor substrate and the second semiconductor substrate are joined together to form the first insulating film including the second insulating film, the third insulating film, the first reflection film, and the fifth insulating film.

15. The method of manufacturing the solid-state imaging element according to claim 9,
wherein, among the pixels, the first pixel and the second pixel are adjacent to each other,
wherein the first light receiving element of the first pixel photoelectrically converts light in a first wavelength region,
wherein the second light receiving element of the first pixel photoelectrically converts light in a second wavelength region,
wherein the first light receiving element of the second pixel photoelectrically converts light in a third wavelength region, and
wherein the second light receiving element of the second pixel photoelectrically converts light in a fourth wavelength region,
the method further comprising the step of:
(i) after the step (g), forming a first color filter over the first light receiving element of the first pixel such that the first color filter overlaps the first light receiving element and the second light receiving element of the first pixel in plan view and forming a second color filter over the first light receiving element of the second pixel such that the second color filter overlaps the first light receiving element and the second light receiving element of the second pixel in plan view,
wherein, in the first color filter, respective transmittances of the light in the first wavelength region and the light in the second wavelength region are higher than a transmittance of the light in the fourth wavelength region,
wherein, in the second color filter, respective transmittances of each of the light in the third wavelength region and the light in the fourth wavelength region are higher than the transmittance of the light in the first wavelength region, and
wherein respective wavelengths in the first wavelength region, the second wavelength region, the third wavelength region, and the fourth wavelength region are progressively longer in this order.
